(19) United States
(12) Patent Application Publication
(10) Pub. No.: US 2021/0098713 A1
(43) Pub. Date: Apr. 1, 2021

(54) ORGANIC ELECTROLUMINESCENCE DEVICE

(71) Applicant: Samsung Display Co., Ltd., Yongin-si (KR)

(72) Inventors: Hyewon CHOI, Suwon-si (KR); Tsuyoshi Naijo, Suwon-si (KR); Yunjee Park, Chungcheongnam-do (KR); Sung-Soo Bae, Seoul (KR); Dongchan Lee, Sejong-si (KR)

(21) Appl. No.: 16/904,419

(22) Filed: Jun. 17, 2020

(30) Foreign Application Priority Data
Sep. 30, 2019 (KR) 10-2019-0120713

(51) Int. Cl. H01L 51/00; C09K 11/06

(52) U.S. Cl. CPC H01L 51/0072; H01L 51/0067; H01L 51/0058; H01L 51/0054; H01L 51/504; H01L 51/006; H01L 51/008; C09K 11/06; H01L 51/0071

(57) ABSTRACT

An organic electroluminescence device of the present embodiments includes a first electrode, a second electrode on the first electrode, and a first emission layer and a second emission layer, both between the first electrode and the second electrode, wherein the first emission layer includes a first host and a first dopant including an anthracene-based compound, the second emission layer includes a second host represented by Formula H-1 and a second dopant including an organometal compound, and the first emission layer and the second emission layer are adjacent to each other. The device of the present embodiments thereby shows high emission efficiency and long-life characteristics.

### CROSS-REFERENCE TO RELATED APPLICATION

This application claims priority to and the benefit of Korean Patent Application No. 10-2019-0120713, filed on Sep. 30, 2019, the entire content of which is hereby incorporated by reference.

### BACKGROUND

One or more aspects of embodiments of the present disclosure herein relate to an organic electroluminescence device, and more particularly, to an organic electroluminescence device including a plurality of emission layers.

Recently, the development of an organic electroluminescence display as an image display is being actively conducted. Different from a liquid crystal display, the organic electroluminescence display is a self-luminescent display in which holes and electrons respectively injected from a first electrode and a second electrode recombine in an emission layer, and a light-emitting material including an organic compound in the emission layer emits light to attain display of images.

In the application of an organic electroluminescence device to a display, the decrease of the driving voltage, and the increase of the emission efficiency and the life of the organic electroluminescence device are required (or desired), and developments of materials for an organic electroluminescence device capable of stably attaining these characteristics are being continuously required (or desired).

For example, recently, in an effort to accomplish an organic electroluminescence device with high efficiency, techniques of a double emission layer including a first emission layer and a second emission layer are being developed, and development of a material used in each emission layer is being conducted.

### SUMMARY

One or more aspects of embodiments of the present disclosure are directed toward an organic electroluminescence device showing excellent (or improved) life characteristics and emission efficiency.

An embodiment of the present disclosure provides an organic electroluminescence device, including a first electrode; a second electrode on the first electrode; and a first emission layer and a second emission layer, which are between the first electrode and the second electrode, wherein the first emission layer includes a first host and a first dopant including an anthracene-based compound, the second emission layer includes a second host represented by Formula H-1 and a second dopant which is different from the first dopant and includes an organometal compound, and the first emission layer and the second emission layer are adjacent to each other:

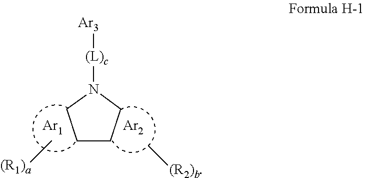

In Formula H-1, Ar₁ to Ar₃ may each independently be a substituted or unsubstituted aryl group of 6 to 60 carbon atoms for forming a ring, or a substituted or unsubstituted heteroaryl group of 2 to 60 carbon atoms for forming a ring, L may be a direct linkage, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring.

R₁ and R₂ may each independently be a hydrogen atom, a deuterium atom, a substituted or unsubstituted silyl group, a substituted or unsubstituted phosphine oxide group, a substituted or unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring, and any of Ri and R2 may be combined with an adjacent group to form a ring, and a to c may each independently be an integer of 0 to 2.

In an embodiment, the second host may be represented by Formula H-1a:

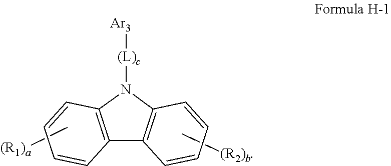

In Formula H-1a, Ar₃, R₁, R₂, L and a to c are the same as defined in Formula H-1.

In an embodiment, the first dopant may be represented by Formula D-1:

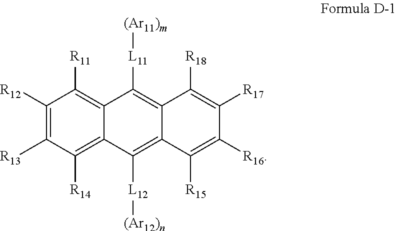

In Formula D-1, R₁₁ to R₁₈ may each independently be a hydrogen atom, a deuterium atom, a substituted or unsubstituted amine group, a substituted or unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring, L₁₁ and L₁₂ may each independently be a direct linkage, a substituted or unsubstituted amine group, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring, Ar₁₁ and Ar₁₂ may each independently be a substituted or unsubstituted alkenyl group of 2 to 30 carbon atoms, a substituted or unsubstituted silyl group, a substituted or unsubstituted selenium group, a substituted or unsubstituted amine group, a substituted or unsubstituted aryl group of 6 to 60 carbon atoms for forming a ring, or a substituted or unsubstituted heteroaryl group of 2 to 60 carbon atoms for forming a ring, and m and n may each independently be an integer of 0 to 3.

In an embodiment, the first dopant may be represented by any one of Formulae D-1a, D-1b or D-1c:

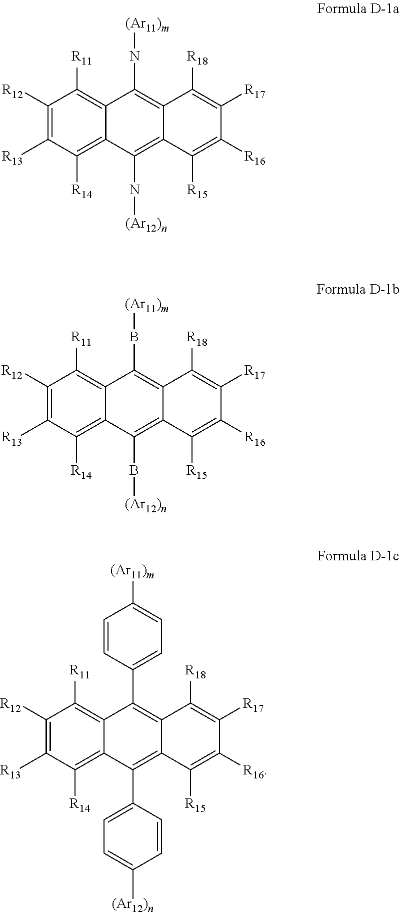

In Formulae D-1a, D-1b and D-1c, Ar₁₁, Ar₁₂, R₁₁ to R₁₈, m and n are the same as defined in Formula D-1.

In an embodiment, the second dopant may include iridium (Ir), platinum (Pt), palladium (Pd), or gold (Au).

In an embodiment, a lowest triplet excitation energy level (Ti level) of the first dopant may be about 2.0 eV or less.

In an embodiment, a thickness of the first emission layer may be from about 1 nm to about 10 nm.

In an embodiment, the second emission layer may be between the first emission layer and the first electrode.

In an embodiment, the first emission layer may be adjacent to the second emission layer.

In an embodiment, the first dopant may include at least one selected from compounds represented in Compound Group 1:

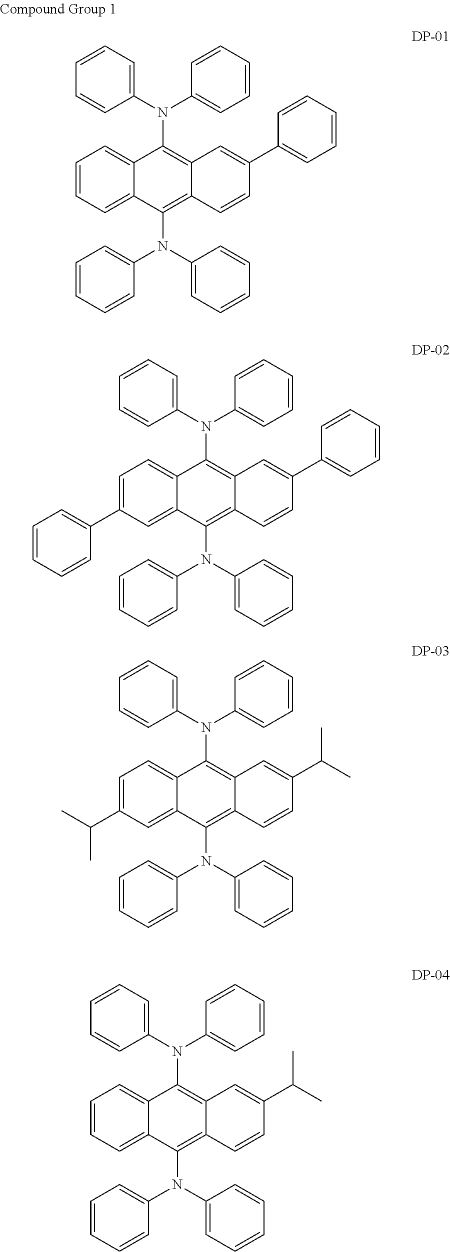

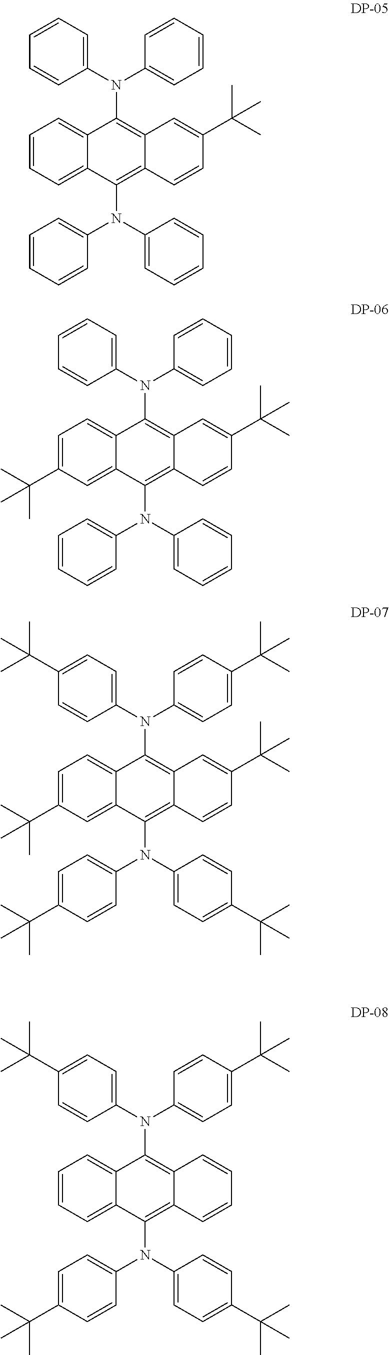

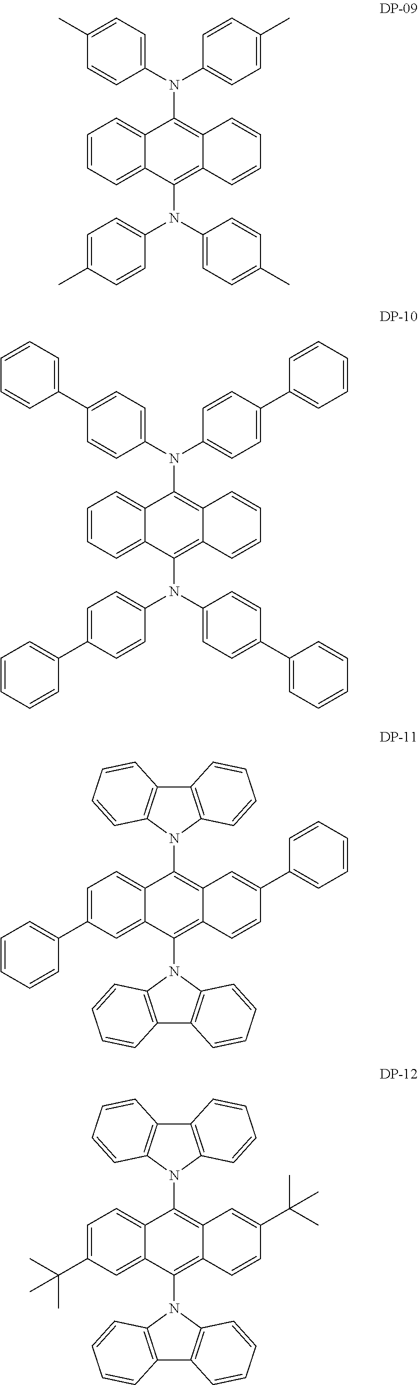

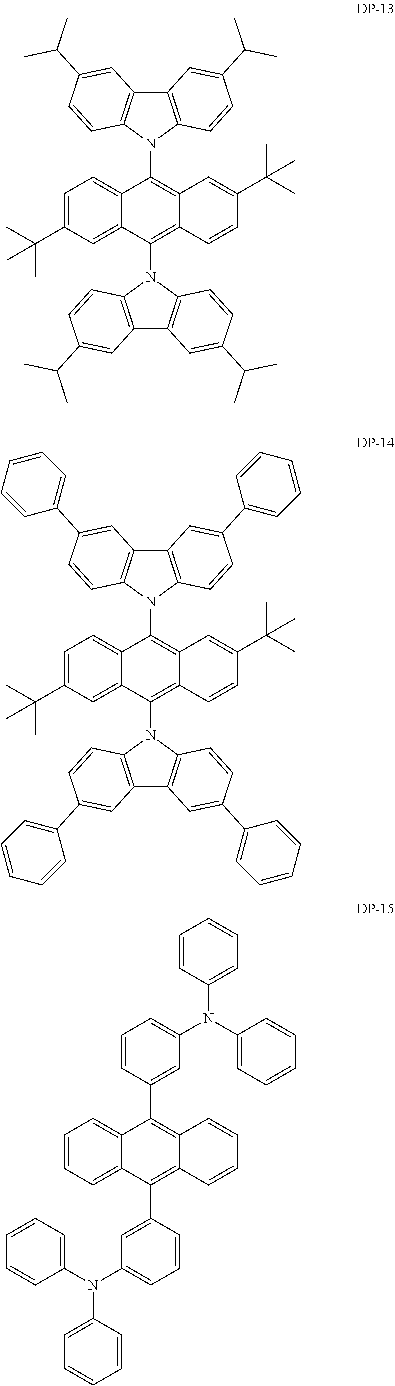 [SMILES: CC(C)c1ccc2c(c1)c1cc(C(C)C)ccc1n2-c1c2ccc(C(C)(C)C)cc2c(-n2c3ccc(C(C)C)cc3c3cc(C(C)C)ccc32)c2ccc(C(C)(C)C)cc12 ; CC(C)(C)c1ccc2c(-n3c4ccc(-c5ccccc5)cc4c4cc(-c5ccccc5)ccc43)c3cc(C(C)(C)C)ccc3c(-n3c4ccc(-c5ccccc5)cc4c4cc(-c5ccccc5)ccc43)c2c1 ; c1ccc(N(c2ccccc2)c2cccc(-c3c4ccccc4c(-c4cccc(N(c5ccccc5)c5ccccc5)c4)c4ccccc34)c2)cc1]

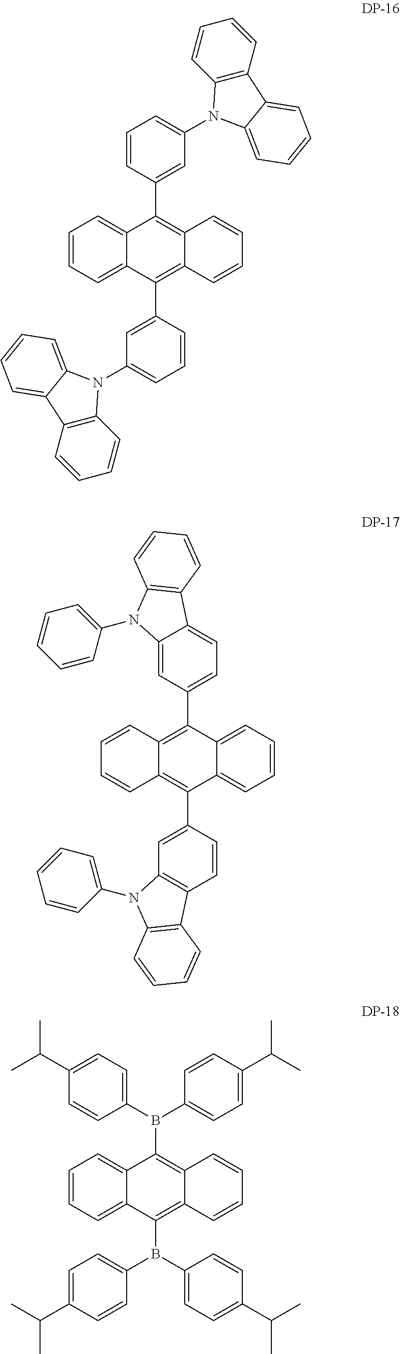 [SMILES: c1cc(-c2c3ccccc3c(-c3cccc(-n4c5ccccc5c5ccccc54)c3)c3ccccc23)cc(-n2c3ccccc3c3ccccc32)c1 ; c1ccc(-n2c3ccccc3c3ccc(-c4c5ccccc5c(-c5ccc6c7ccccc7n(-c7ccccc7)c6c5)c5ccccc45)cc32)cc1 ; CC(C)c1ccc(B(c2ccc(C(C)C)cc2)c2c3ccccc3c(B(c3ccc(C(C)C)cc3)c3ccc(C(C)C)cc3)c3ccccc23)cc1]

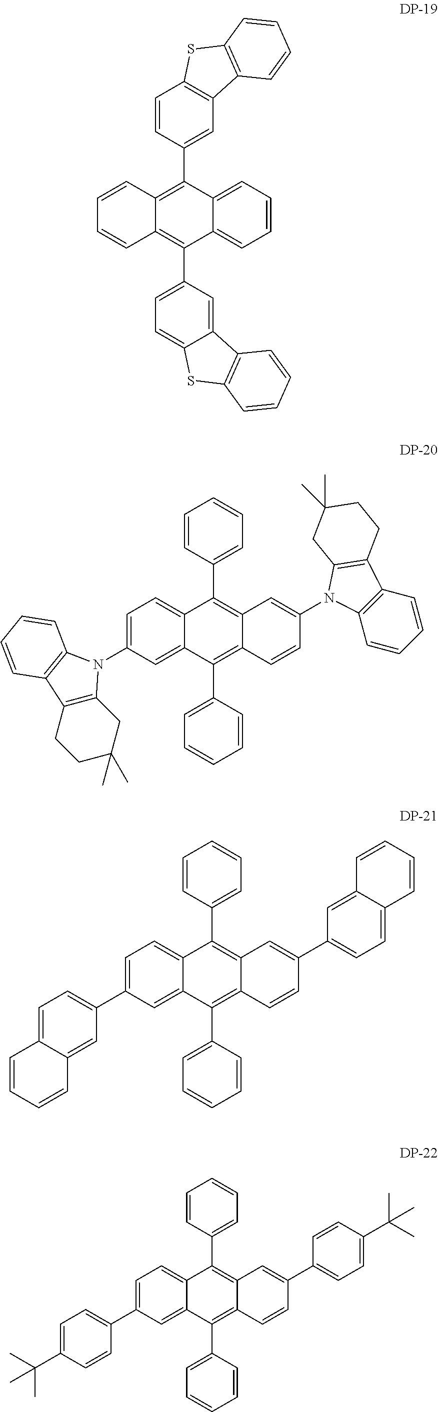

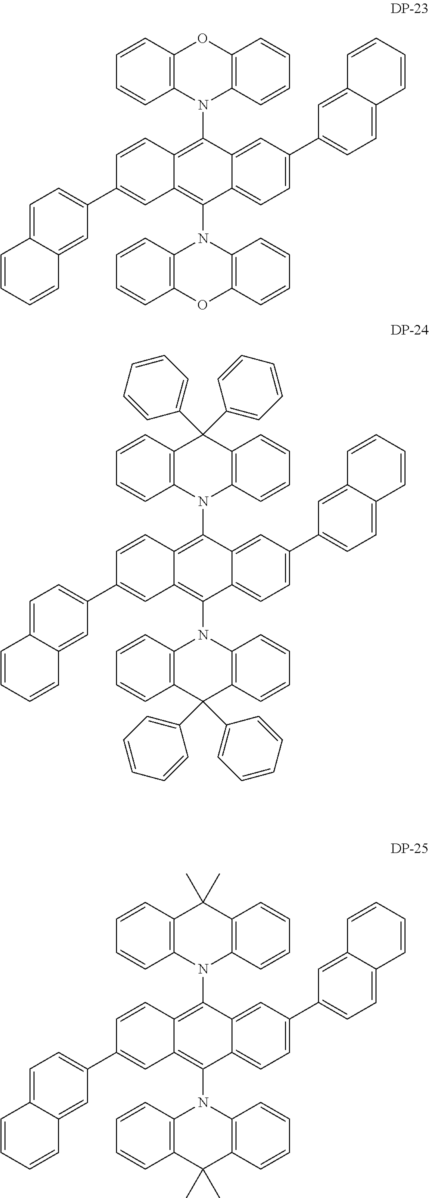 [SMILES: c1ccc2c(c1)Oc1ccccc1N2c1c2ccc(-c3ccc4ccccc4c3)cc2c(N2c3ccccc3Oc3ccccc32)c2ccc(-c3ccc4ccccc4c3)cc12 ; c1ccc(C2(c3ccccc3)c3ccccc3N(c3c4ccc(-c5ccc6ccccc6c5)cc4c(N4c5ccccc5C(c5ccccc5)(c5ccccc5)c5ccccc54)c4ccc(-c5ccc6ccccc6c5)cc34)c3ccccc32)cc1 ; CC1(C)c2ccccc2N(c2c3ccc(-c4ccc5ccccc5c4)cc3c(N3c4ccccc4C(C)(C)c4ccccc43)c3ccc(-c4ccc5ccccc5c4)cc23)c2ccccc21]

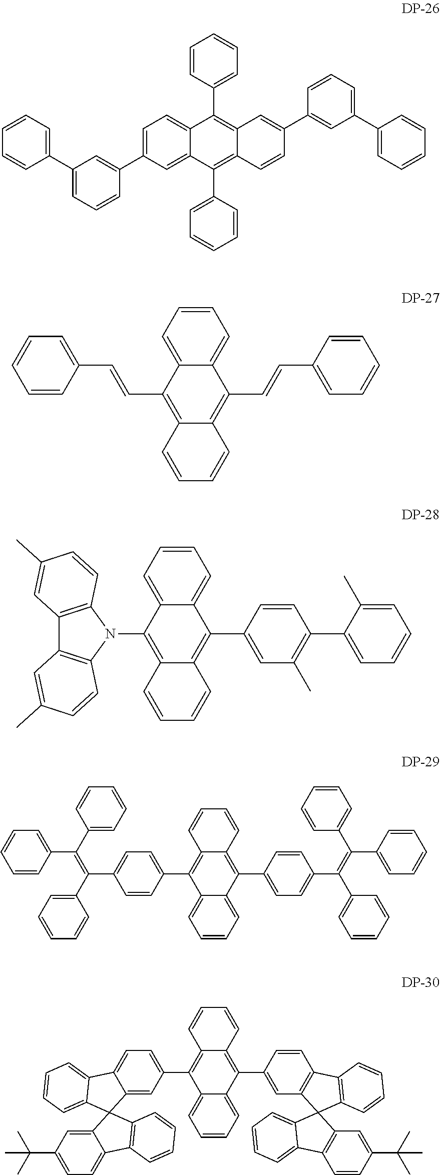

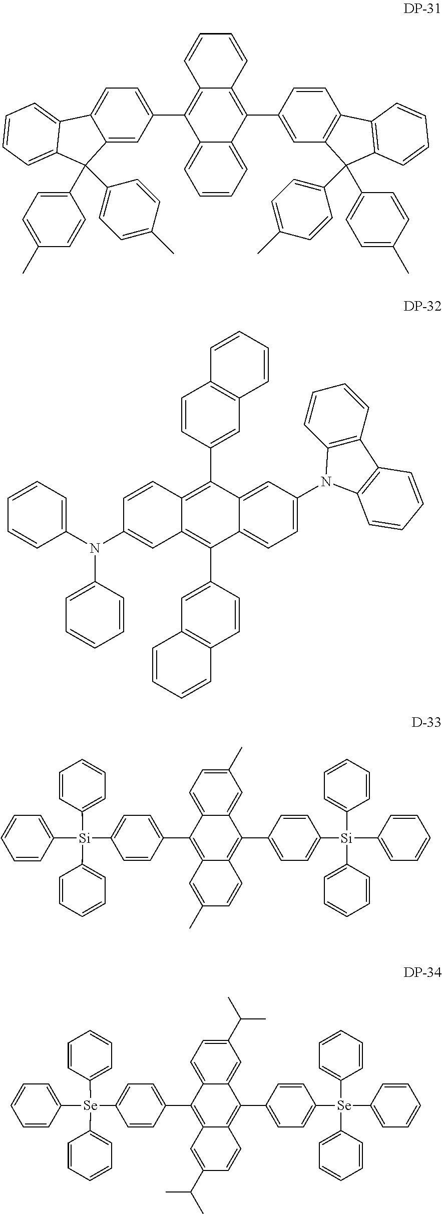

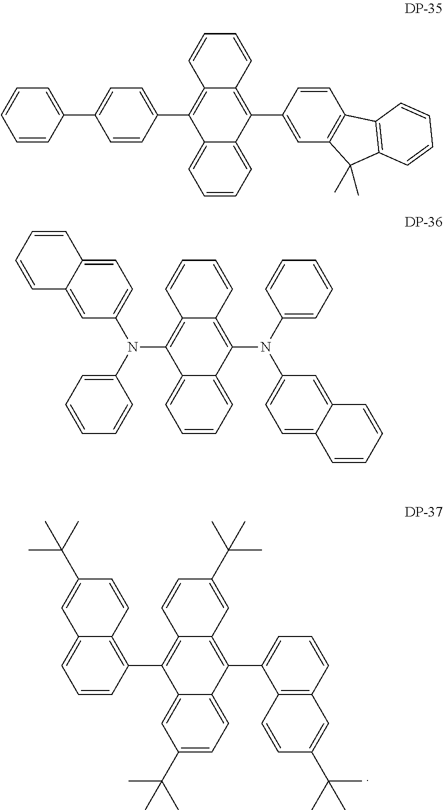

In an embodiment, the second host may include at least one selected from compounds represented in Compound Group 2:

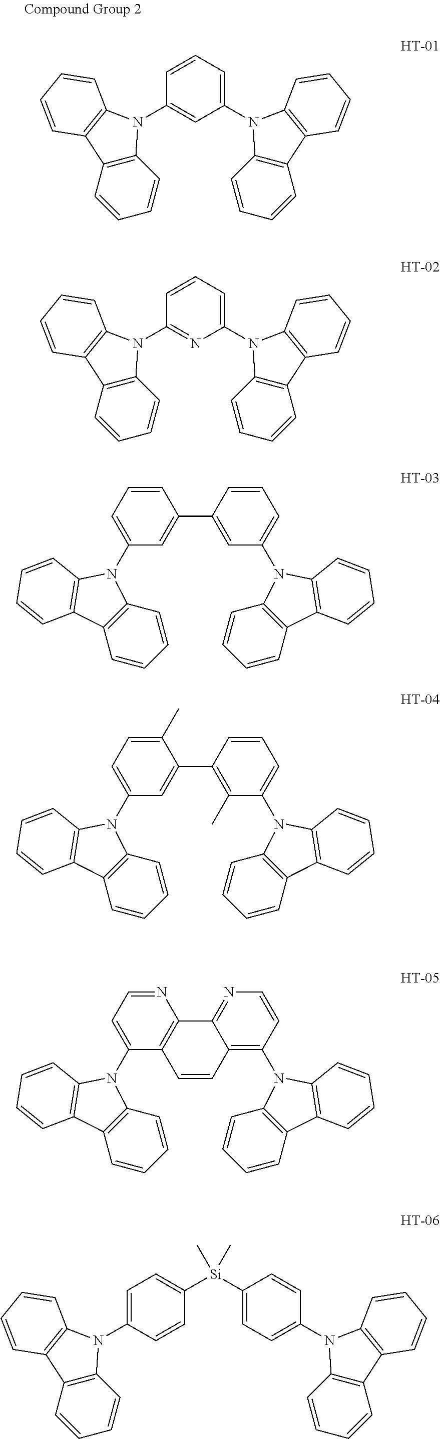 [SMILES: c1cc(-n2c3ccccc3c3ccccc32)cc(-n2c3ccccc3c3ccccc32)c1 ; c1cc(-n2c3ccccc3c3ccccc32)nc(-n2c3ccccc3c3ccccc32)c1 ; c1cc(-c2cccc(-n3c4ccccc4c4ccccc43)c2)cc(-n2c3ccccc3c3ccccc32)c1 ; Cc1ccc(-n2c3ccccc3c3ccccc32)cc1-c1cccc(-n2c3ccccc3c3ccccc32)c1C ; c1ccc2c(c1)c1ccccc1n2-c1ccnc2c1ccc1c(-n3c4ccccc4c4ccccc43)ccnc12 ; C[Si](C)(c1ccc(-n2c3ccccc3c3ccccc32)cc1)c1ccc(-n2c3ccccc3c3ccccc32)cc1]

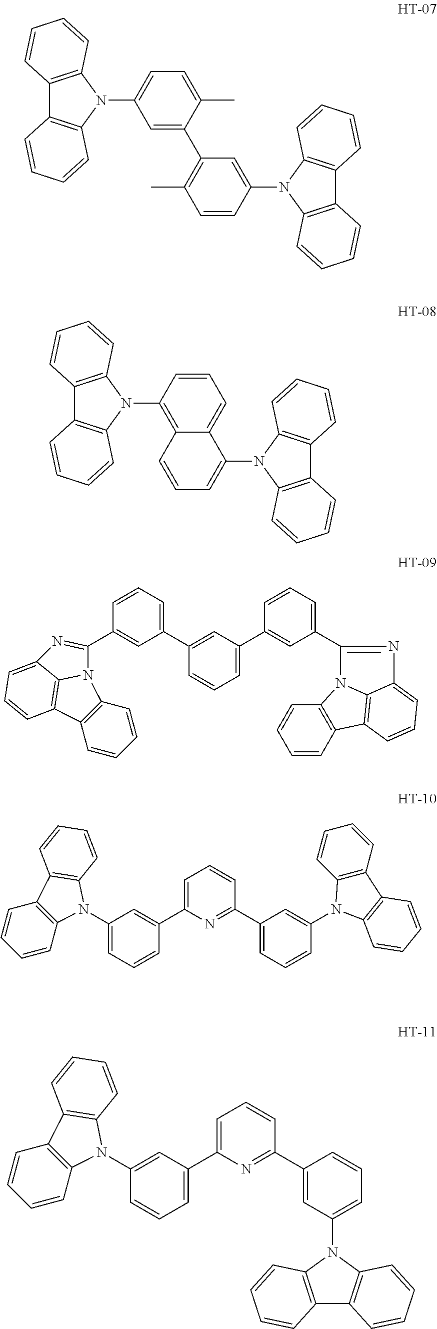

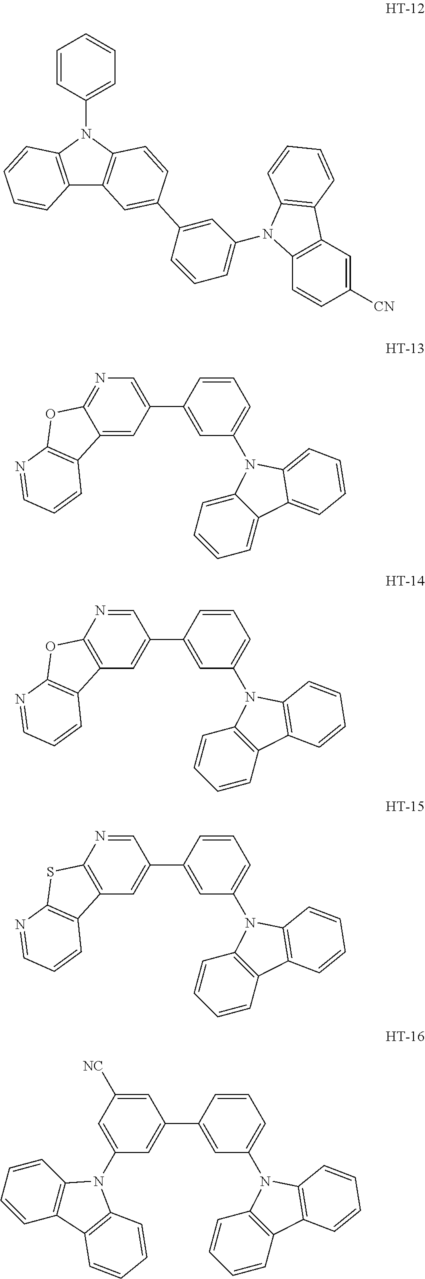 [SMILES: N#Cc1ccc2c(c1)c1ccccc1n2-c1cccc(-c2ccc3c(c2)c2ccccc2n3-c2ccccc2)c1 ; c1cc(-c2cnc3oc4ncccc4c3c2)cc(-n2c3ccccc3c3ccccc32)c1 ; c1cc(-c2cnc3oc4ncccc4c3c2)cc(-n2c3ccccc3c3ccccc32)c1 ; c1cc(-c2cnc3sc4ncccc4c3c2)cc(-n2c3ccccc3c3ccccc32)c1 ; N#Cc1cc(-c2cccc(-n3c4ccccc4c4ccccc43)c2)cc(-n2c3ccccc3c3ccccc32)c1]

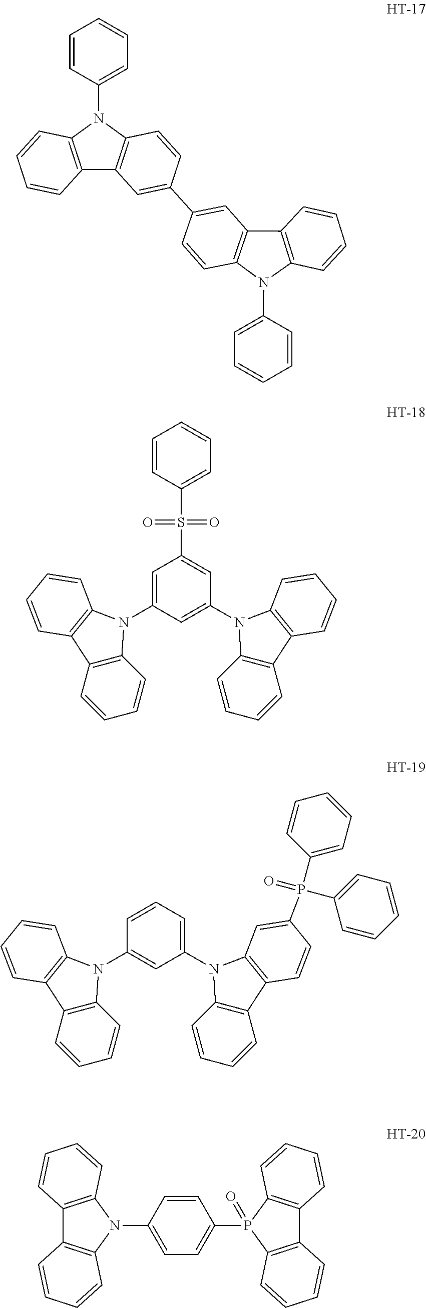 [SMILES: c1ccc(-n2c3ccccc3c3cc(-c4ccc5c(c4)c4ccccc4n5-c4ccccc4)ccc32)cc1 ; O=S(=O)(c1ccccc1)c1cc(-n2c3ccccc3c3ccccc32)cc(-n2c3ccccc3c3ccccc32)c1 ; O=P(c1ccccc1)(c1ccccc1)c1ccc2c3ccccc3n(-c3cccc(-n4c5ccccc5c5ccccc54)c3)c2c1 ; O=P1(c2ccc(-n3c4ccccc4c4ccccc43)cc2)c2ccccc2-c2ccccc21]

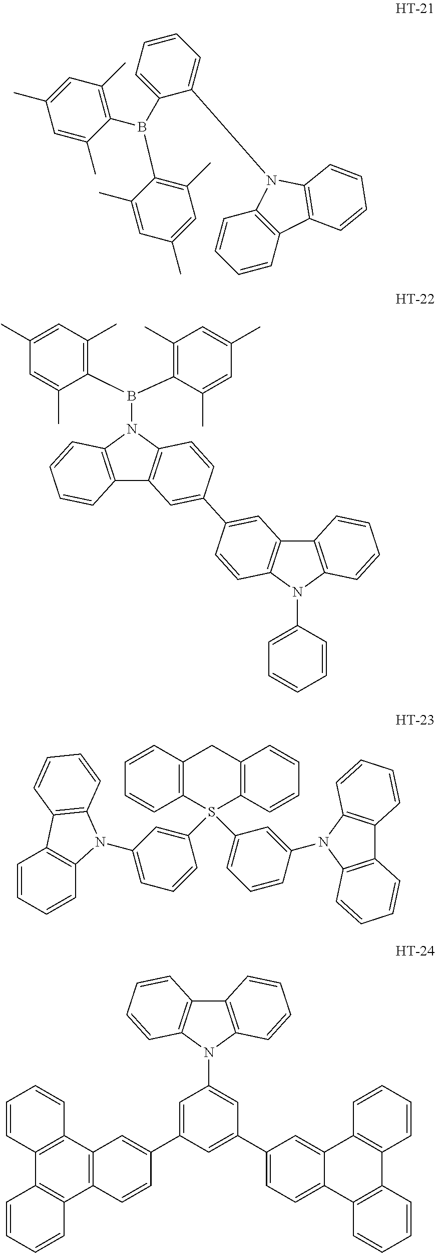 [SMILES: Cc1cc(C)c(B(c2ccccc2-n2c3ccccc3c3ccccc32)c2c(C)cc(C)cc2C)c(C)c1 ; Cc1cc(C)c(B(c2c(C)cc(C)cc2C)n2c3ccccc3c3cc(-c4ccc5c(c4)c4ccccc4n5-c4ccccc4)ccc32)c(C)c1 ; c1cc(-n2c3ccccc3c3ccccc32)cc(S2(c3cccc(-n4c5ccccc5c5ccccc54)c3)c3ccccc3Cc3ccccc32)c1 ; c1ccc2c(c1)c1ccccc1c1cc(-c3cc(-c4ccc5c6ccccc6c6ccccc6c5c4)cc(-n4c5ccccc5c5ccccc54)c3)ccc21]

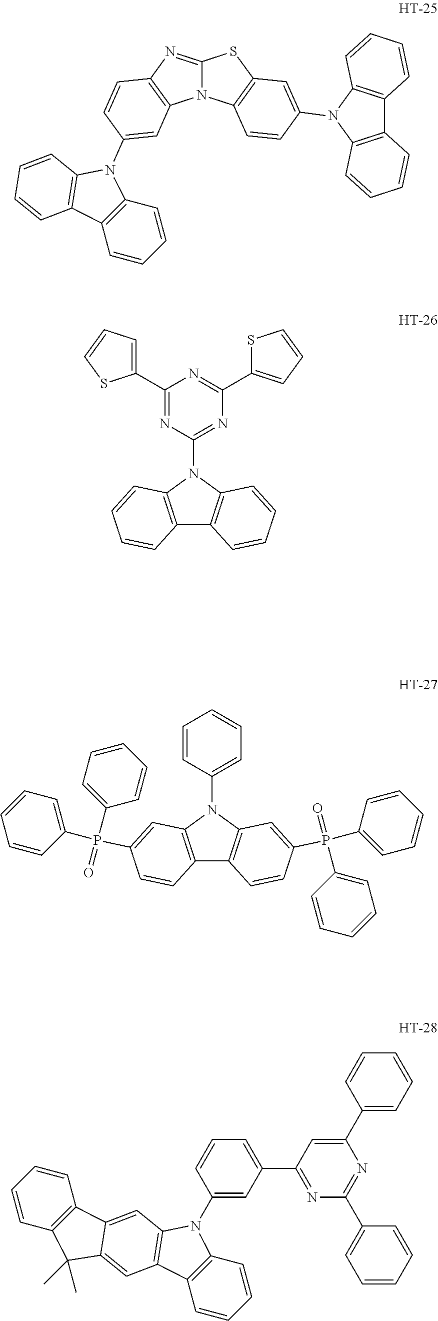 [SMILES: c1ccc2c(c1)c1ccccc1n2-c1ccc2c(c1)sc1nc3ccc(-n4c5ccccc5c5ccccc54)cc3n12 ; c1csc(-c2nc(-c3cccs3)nc(-n3c4ccccc4c4ccccc43)n2)c1 ; O=P(c1ccccc1)(c1ccccc1)c1ccc2c3ccc(P(=O)(c4ccccc4)c4ccccc4)cc3n(-c3ccccc3)c2c1 ; CC1(C)c2ccccc2-c2cc3c(cc21)c1ccccc1n3-c1cccc(-c2cc(-c3ccccc3)nc(-c3ccccc3)n2)c1]

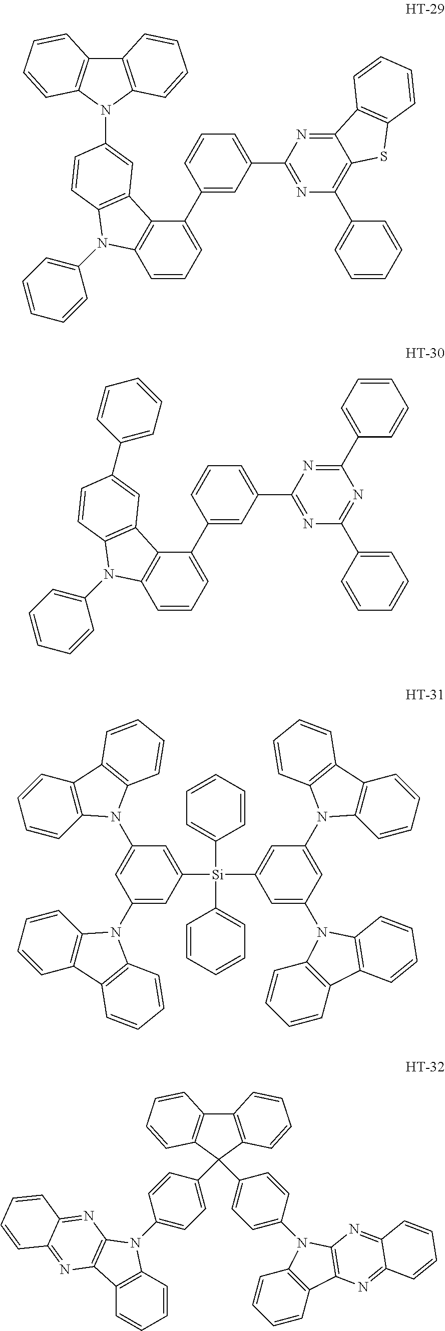 [SMILES: c1ccc(-c2nc(-c3cccc(-c4cccc5c4c4cc(-n6c7ccccc7c7ccccc76)ccc4n5-c4ccccc4)c3)nc3c2sc2ccccc23)cc1 ; c1ccc(-c2ccc3c(c2)c2c(-c4cccc(-c5nc(-c6ccccc6)nc(-c6ccccc6)n5)c4)cccc2n3-c2ccccc2)cc1 ; c1ccc([Si](c2ccccc2)(c2cc(-n3c4ccccc4c4ccccc43)cc(-n3c4ccccc4c4ccccc43)c2)c2cc(-n3c4ccccc4c4ccccc43)cc(-n3c4ccccc4c4ccccc43)c2)cc1 ; c1ccc2c(c1)-c1ccccc1C2(c1ccc(-n2c3ccccc3c3nc4ccccc4nc32)cc1)c1ccc(-n2c3ccccc3c3nc4ccccc4nc32)cc1]

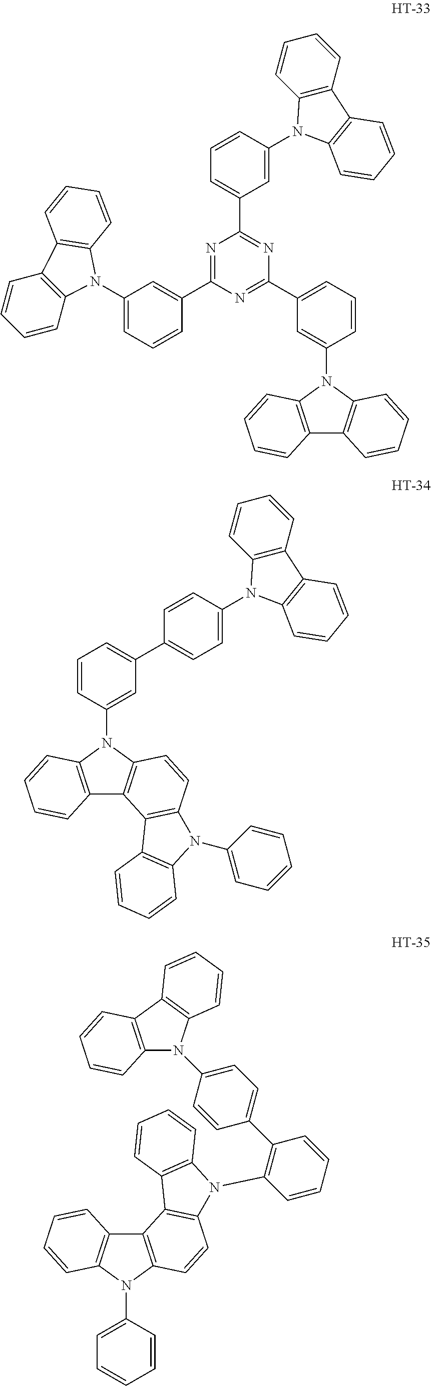

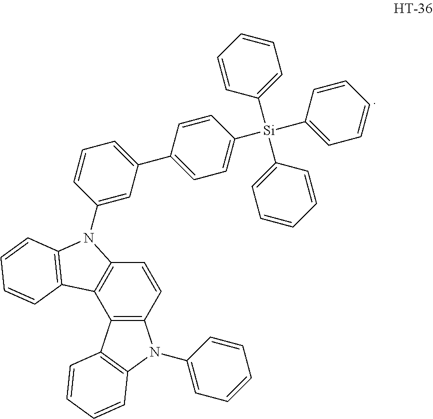 [SMILES: c1ccc(-n2c3ccccc3c3c4c5ccccc5n(-c5cccc(-c6ccc([Si](c7ccccc7)(c7ccccc7)c7ccccc7)cc6)c5)c4ccc32)cc1]

### BRIEF DESCRIPTION OF THE FIGURES

The accompanying drawings are included to provide a further understanding of the present disclosure and are incorporated in and constitute a part of this specification. The drawings illustrate example embodiments of the present disclosure and, together with the description, serve to explain principles of the present disclosure. In the drawings:

FIG. 1A and FIG. 1B are cross-sectional views schematically illustrating organic electroluminescence devices according to embodiments of the present disclosure;

FIG. 2 is a cross-sectional view schematically illustrating an organic electroluminescence device according to an embodiment of the present disclosure;

FIG. 3 is a cross-sectional view schematically illustrating an organic electroluminescence device according to an embodiment of the present disclosure; and

FIG. 4 is a cross-sectional view schematically illustrating an organic electroluminescence device according to an embodiment of the present disclosure.

### DETAILED DESCRIPTION

The present disclosure may have various modifications and may be embodied in different forms, and example embodiments will be explained in more detail with reference to the accompany drawings. The present disclosure may, however, be embodied in different forms and should not be construed as limited to the embodiments set forth herein. Rather, all modifications, equivalents, and substituents which are included in the spirit and technical scope of the present disclosure should be included in the present disclosure.

It will be understood that when an element (or region, layer, part, etc.) is referred to as being “on”, “connected to” or “coupled to” another element, it can be directly on, connected or coupled to the other element (with no third intervening elements therebetween) or one or more third intervening elements may be present.

Like reference numerals refer to like elements throughout. In addition, in the drawings, the thickness, the ratio, and the dimensions of constituent elements are exaggerated for effective explanation of technical contents.

The term “and/or” includes one or more combinations which may be defined by relevant elements. Expressions such as “at least one of,” “one of,” and “selected from,” when preceding a list of elements, modify the entire list of elements and do not modify the individual elements of the list. Further, the use of “may” when describing embodiments of the present disclosure refers to “one or more embodiments of the present disclosure.”

It will be understood that, although the terms first, second, etc. may be used herein to describe various elements, these elements should not be limited by these terms. These terms are only used to distinguish one element from another element. Thus, a first element could be termed a second element without departing from the teachings of the present disclosure. Similarly, a second element could be termed a first element. As used herein, the singular forms are intended to include the plural forms as well, unless the context clearly indicates otherwise.

In addition, the terms “below”, “beneath”, “on” and “above” are used for explaining the relation of elements shown in the drawings. The terms are relative concept and are explained based on the direction shown in the drawing.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be further understood that the terms “comprises,” “includes,” “including,” and/or “comprising,” when used in this specification, specify the presence of stated features, numerals, steps, operations, elements, parts, or the combination thereof, but do not preclude the presence or addition of one or more other features, numerals, steps, operations, elements, parts, or the combination thereof.

Hereinafter, the organic electroluminescence device according to an embodiment of the present disclosure will be explained with reference to attached drawings.

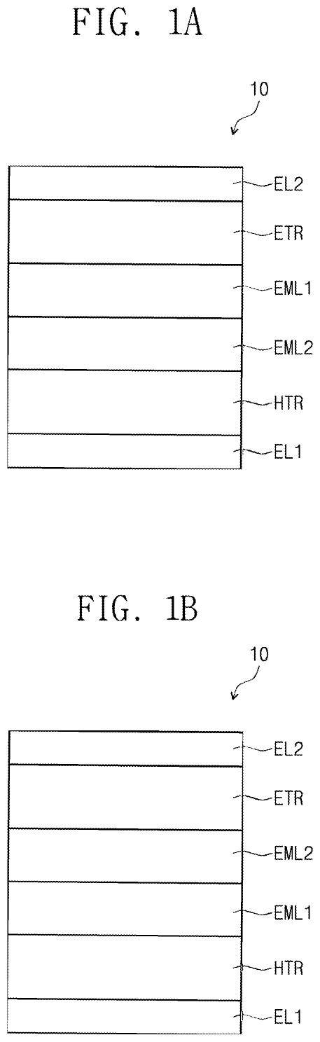

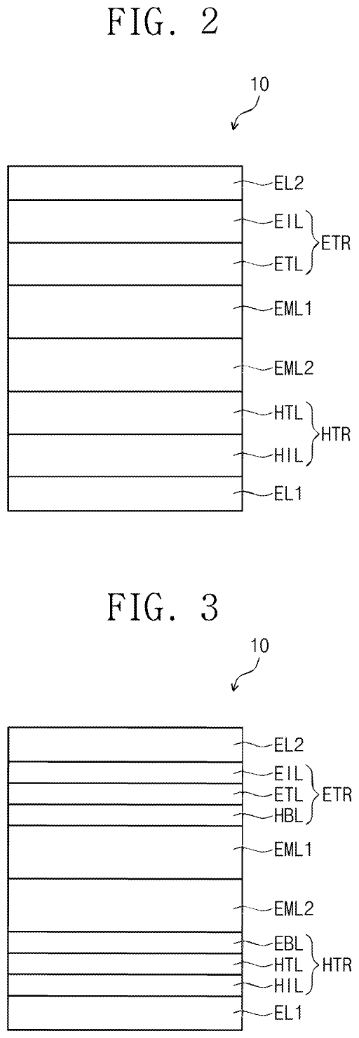

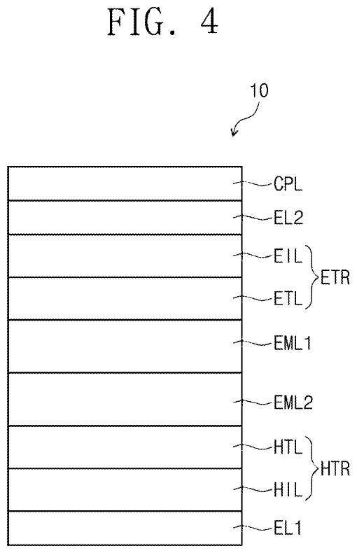

FIG. 1A, FIG. 1B, FIG. 2, FIG. 3 and FIG. 4 are cross-sectional views schematically showing organic electroluminescence devices according to example embodiments of the present disclosure. Referring to FIG. 1A to FIG. 4, in an organic electroluminescence device 10 of an embodiment, a first electrode EU and a second electrode EL2 are oppositely placed, and between the first electrode EU and the second electrode EL2, a first emission layer EML1 and a second emission layer EML2 may be provided. In the organic electroluminescence device 10 of an embodiment, the stacking order of the first emission layer EML1 and the second emission layer EML2 is not limited.

For example, as in FIG. 1A, the second emission layer EML2 may be formed between the first emission layer EML1 and the first electrode EL1. In some embodiments, as shown in FIG. 1B, the second emission layer EML2 may be formed between the first emission layer EML1 and the second electrode EL2. Hereinafter, in the description, the explanation will be based on an organic electroluminescence device 10 where the second emission layer EML2 is formed between the first emission layer EML1 and the first electrode EL1.

As shown in FIG. 1A to FIG. 4, the first emission layer EML1 and the second emission layer EML2 may be adjacent to each other in an embodiment. For example, the first emission layer EML1 may be adjacent to the second emission layer EML2. Hereinafter, in the description, the explanation will be based on an organic electroluminescence device 10 where the first emission layer EML1 is adjacent to the second emission layer EML2, but embodiments of the present disclosure are not limited thereto.

The organic electroluminescence device 10 of an embodiment may further include a plurality of functional layers between the first electrode EL1 and the second electrode EL2, in addition to the first emission layer EML1 and the second emission layer EML2. The plurality of the functional layers may include a hole transport region HTR and an electron transport region ETR. For example, the organic electroluminescence device 10 according to an embodiment may include a first electrode EL1, a hole transport region HTR, a second emission layer EML2, a first emission layer EML1, an electron transport region ETR, and a second electrode EL2, stacked one by one. In some embodiments, the organic electroluminescence device 10 of an embodiment may include a capping layer CPL on the second electrode EL2.

The organic electroluminescence device 10 of an embodiment may include one or more compounds of an embodiment, which will be explained in more detail later, in the first emission layer EML1 and the second emission layer EML2, which are provided between the first electrode EL1 and the second electrode EL2. However, an embodiment of the present disclosure is not limited thereto, and the organic electroluminescence device 10 of an embodiment may include the compound(s) in the hole transport region HTR and/or the electron transport region ETR, which are a plurality of the functional layers between the first electrode EL1 and the second electrode EL2, or may include the compound(s) in a capping layer CPL on the second electrode.

When compared with FIG. 1A, FIG. 2 shows the cross-sectional view of an organic electroluminescence device 10 of an embodiment, wherein a hole transport region HTR includes a hole injection layer HIL and a hole transport layer HTL, and an electron transport region ETR includes an electron injection layer EIL and an electron transport layer ETL. When compared with FIG. 1A, FIG. 3 shows the cross-sectional view of an organic electroluminescence device 10 of an embodiment, wherein a hole transport region HTR includes a hole injection layer HIL, a hole transport layer HTL, and an electron blocking layer EBL, and an electron transport region ETR includes an electron injection layer EIL, an electron transport layer ETL, and a hole blocking layer HBL. When compared with FIG. 2, FIG. 4 shows the cross-sectional view of an organic electroluminescence device 10 of an embodiment, including a capping layer CPL on a second electrode EL2.

The first electrode EL1 has conductivity. The first electrode EU may be formed using a metal alloy or any suitable conductive compound. The first electrode EL1 may be an anode. In some embodiments, the first electrode EL1 may be a pixel electrode. The first electrode EL1 may be a transmissive electrode, a transflective electrode, or a reflective electrode. If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EU is the transflective electrode or the reflective electrode, the first electrode EL1 may include Ag, Mg, Cu, Al, Pt, Pd, Au, Ni, Nd, Ir, Cr, Li, Ca, LiF/Ca, LiF/AI, Mo, Ti, a compound thereof, or a mixture thereof (for example, a mixture of Ag and Mg). In some embodiments, the first electrode EL1 may have a structure including a plurality of layers including a reflective layer or a transflective layer formed using any of the above materials, and a transmissive conductive layer formed using ITO, IZO, ZnO, and/or ITZO. For example, the first electrode EL1 may include a three-layer structure of ITO/Ag/ITO. However, an embodiment of the present disclosure is not limited thereto. The thickness of the first electrode EU may be from about 1,000 Å to about 10,000 Å, for example, from about 1,000 Å to about 3,000 Å.

The hole transport region HTR is provided on the first electrode EL1. The hole transport region HTR may include at least one of a hole injection layer HIL, a hole transport layer HTL, a hole buffer layer, or an electron blocking layer EBL. The thickness of the hole transport region HTR may be from about 50 Å to about 1,500 Å.

The hole transport region HTR may have a single layer formed using a single material, a single layer formed using a plurality of different materials, or a multilayer structure including a plurality of layers formed using a plurality of different materials.

For example, the hole transport region HTR may have the structure of a single layer of a hole injection layer HIL, or a hole transport layer HTL, and may have a structure of a single layer formed using a hole injection material and a hole transport material. In some embodiments, the hole transport region HTR may have a structure of a single layer formed using a plurality of different materials, or a structure laminated from the first electrode EL1 of hole injection layer HIL/hole transport layer HTL, hole injection layer H IL/hole transport layer HTL/hole buffer layer, hole injection layer HIL/hole buffer layer, hole transport layer HTL/hole buffer layer, or hole injection layer HIL/hole transport layer HTL/electron blocking layer EBL, without limitation.

The hole transport region HTR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

The hole injection layer HIL may include, for example, a phthalocyanine compound (such as copper phthalocyanine), N,N′-diphenyl-N,N′-bis-[4-(phenyl-m-tolyl-amino)-phenyl]-phenyl-4,4′-diamine (DNTPD), 4,4′,4″-[tris(3-methylphenyl)phenylamino] triphenylamine (m-MTDATA), 4,4′,4″-tris(N,N-diphenylamino)triphenylamine (TDATA), 4,4′,4″-tris{N,-2-naphthyl)-N-phenylamino}-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(1-naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], and/or dipyrazino[2,3-f:2′,3′-h]quinoxaline-2,3,6,7,10,11-hexacarbonitrile (HAT-CN).

The hole transport layer HTL may include, for example, carbazole derivatives (such as N-phenyl carbazole and/or polyvinyl carbazole), fluorene-based derivatives, N,N′-bis(3-methylphenyl)-N,N′-diphenyl-[1,1-biphenyl]-4,4′-diamine (TPD), triphenylamine-based derivatives (such as 4,4′,4″-tris(N-carbazolyl)triphenylamine (TCTA)), N,N′-di(1-naphthalene-1-yl)-N,N′-diphenyl-benzidine (NPB), 4,4′-cyclohexylidene bis[N,N-bis(4-methylphenyl)benzeneamine (TAPC), 4,4′-bis[N,N′-(3-tolyl)amino]-3,3′-dimethylbiphenyl (HMTPD), 1,3-bis(N-carbazolyl)benzene (mCP), etc.

The thickness of the hole transport region HTR may be from about 50 Å to about 10,000 Å, for example, from about 100 Å to about 5,000 Å. The thickness of the hole injection region HIL may be, for example, from about 30 Å to about 1,000 Å, and the thickness of the hole transport layer HTL may be from about 30 Å to about 1,000 Å. For example, the thickness of the electron blocking layer EBL may be from about 10 Å to about 1,000 Å. When the thicknesses of the hole transport region HTR, the hole injection layer HIL, the hole transport layer HTL, and the electron blocking layer EBL satisfy the above-described ranges, satisfactory (or suitable) hole transport properties may be achieved without substantial increase of a driving voltage.

The hole transport region HTR may further include a charge generating material, in addition to the above-described materials, to increase conductivity. The charge generating material may be dispersed uniformly or non-uniformly in the hole transport region HTR. The charge generating material may be, for example, a p-dopant. The p-dopant may be one of quinone derivatives, metal oxides, or cyano group-containing compounds, without limitation. Non-limiting examples of the p-dopant may include quinone derivatives (such as tetracyanoquinodimethane (TCNQ) and/or 2,3,5,6-tetrafluoro-7,7′,8,8′-tetracyanoquinodimethane (F4-TCNQ)), metal oxides (such as tungsten oxide and/or molybdenum oxide), and inorganic metal compounds (such as Cul and/or RbI).

As described above, the hole transport region HTR may further include at least one of a hole buffer layer or an electron blocking layer EBL, in addition to the hole injection layer HIL and the hole transport layer HTL. The hole buffer layer may compensate an optical resonance distance according to the wavelength of light emitted from emission layers EML1 and EML2, and may increase light emission efficiency. Materials which may be included in a hole transport region HTR may be used as materials included in a hole buffer layer. The electron blocking layer EBL may prevent or reduce the electron injection from the electron transport region ETR to the hole transport region HTR.

The first emission layer EML1 and the second emission layer EML2 are provided on the hole transport region HTR. The first emission layer EML1 and the second emission layer EML2 may each independently have a single layer formed using a single material, a single layer formed using a plurality of different materials, or a multilayer structure having a plurality of layers formed using a plurality of different materials.

In the organic electroluminescence device 10 of an embodiment, the first emission layer EML1 may include a first host and a first dopant. The first dopant may be a fluorescence dopant. The second emission layer EML2 may include a second host and a second dopant. The second dopant may be a phosphorescence dopant.

In the description, the term “substituted or unsubstituted” corresponds to a group that is unsubstituted or that is substituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkoxy group, a hydrocarbon ring group, an aryl group, and a heterocyclic group (e.g., a heterocycle). In addition, each of the exemplified substituents may itself be substituted or unsubstituted. For example, a biphenyl group may be interpreted as an aryl group or a phenyl group substituted with a phenyl group.

In the description, “atoms for forming a ring” may refer to ring-forming atoms.

In the description, the term “forming a ring via the combination with an adjacent group” may refer to forming a substituted or unsubstituted hydrocarbon ring, or a substituted or unsubstituted heterocycle via the combination of one group with an adjacent group. The hydrocarbon ring includes an aliphatic hydrocarbon ring and an aromatic hydrocarbon ring. The heterocycle includes an aliphatic heterocycle and an aromatic heterocycle. The ring formed by the combination with an adjacent group may be a monocyclic ring or a polycyclic ring. In addition, the ring formed via the combination with an adjacent group may be combined with another ring to form a spiro structure.

In the description, the term “adjacent group” may refer to a pair of substituent groups where the first substituent is connected to an atom which is directly connected to another atom substituted with the second substituent; a pair of substituent groups connected to the same atom; or a pair of substituent groups where the first substituent is sterically positioned at the nearest position to the second substituent. For example, in 1,2-dimethylbenzene, two methyl groups may be interpreted as “adjacent groups” to each other, and in 1,1-diethylcyclopentene, two ethyl groups may be interpreted as “adjacent groups” to each other.

In the description, the halogen atom may be a fluorine atom, a chlorine atom, a bromine atom and/or an iodine atom.

In the description, the alkyl may be a linear, branched or cyclic alkyl group. The carbon number of the alkyl may be 1 to 50, 1 to 30, 1 to 20, 1 to 10, or 1 to 6. Examples of the alkyl may include methyl, ethyl, n-propyl, isopropyl, n-butyl, s-butyl, t-butyl, i-butyl, 2-ethylbutyl, 3,3-dimethylbutyl, n-pentyl, i-pentyl, neopentyl, t-pentyl, cyclopentyl, 1-methylpentyl, 3-methylpentyl, 2-ethylpentyl, 4-methyl-2-pentyl, n-hexyl, 1-methylhexyl, 2-ethylhexyl, 2-butylhexyl, cyclohexyl, 4-methylcyclohexyl, 4-t-butylcyclohexyl, n-heptyl, 1-methylheptyl, 2,2-dimethylheptyl, 2-ethylheptyl, 2-butylheptyl, n-octyl, t-octyl, 2-ethyloctyl, 2-butyloctyl, 2-hexyloctyl, 3,7-dimethyloctyl, cyclooctyl, n-nonyl, n-decyl, adamantyl, 2-ethyldecyl, 2-butyldecyl, 2-hexyldecyl, 2-octyldecyl, n-undecyl, n-dodecyl, 2-ethyldodecyl, 2-butyldodecyl, 2-hexyldocecyl, 2-octyldodecyl, n-tridecyl, n-tetradecyl, n-pentadecyl, n-hexadecyl, 2-ethylhexadecyl, 2-butylhexadecyl, 2-hexylhexadecyl, 2-octylhexadecyl, n-heptadecyl, n-octadecyl, n-nonadecyl, n-eicosyl, 2-ethyleicosyl, 2-butyleicosyl, 2-hexyleicosyl, 2-octyleicosyl, n-henicosyl, n-docosyl, n-tricosyl, n-tetracosyl, n-pentacosyl, n-hexacosyl, n-heptacosyl, n-octacosyl, n-nonacosyl, n-triacontyl, etc., without limitation.

In the description, the alkenyl group may refer to a hydrocarbon group including one or more carbon double bonds in the middle and/or at the terminal ends of an alkyl group of 2 or more carbon atoms. The alkenyl group may be a linear chain or a branched chain. The carbon number is not specifically limited but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styrylvinyl group, etc., without limitation.

In the description, the alkynyl group may refer to a hydrocarbon group including one or more carbon triple bonds in the middle and/or at the terminal ends of an alkyl group of 2 or more carbon atoms. The alkynyl group may be a linear chain or a branched chain. The carbon number is not specifically limited but may be 2 to 30, 2 to 20, or 2 to 10. Examples of the alkynyl group may include an ethynyl group, a propynyl group, etc., without limitation.

In the description, the hydrocarbon ring group may refer to a functional group or substituent, which is derived from an aliphatic hydrocarbon ring, or a functional group or substituent derived from an aromatic hydrocarbon ring. The number of carbon atoms for forming a ring of the hydrocarbon ring may be 5 to 60, 5 to 30, or 5 to 20.

In the description, the aryl group refer to a functional group or substituent derived from an aromatic hydrocarbon ring. The aryl group may be a monocyclic aryl group or a polycyclic aryl group. The carbon number for forming a ring in the aryl group may be 6 to 30, 6 to 20, or 6 to 15. Examples of the aryl group may include phenyl, naphthyl, fluorenyl, anthracenyl, phenanthryl, biphenyl, terphenyl, quaterphenyl, quinqphenyl, sexiphenyl, triphenylenyl, pyrenyl, benzofluoranthenyl, chrysenyl, etc., without limitation.

In the description, the heterocyclic group (e.g., the heterocycle) refer to a functional group or substituent derived from a ring including one or more ring-forming heteroatoms selected from B, O, N, P, Si and S. The heterocyclic group includes an aliphatic heterocyclic group and an aromatic heterocyclic group. The aromatic heterocyclic group may be a heteroaryl group. The aliphatic heterocycle and the aromatic heterocycle may each independently be a monocycle or a polycycle.

If the heterocyclic group includes two or more heteroatoms, two or more heteroatoms may be the same or different. The carbon number for forming a ring of the heterocyclic group may be 2 to 30, 2 to 20, or 2 to 10.

In the description, the aliphatic heterocyclic group may be an oxirane group, a thiirane group, a pyrrolidine group, a piperidine group, a tetrahydrofuran group, a tetrahydrothiophene group, a thiane group, a tetrahydropyrane group, a 1,4-dioxane group, etc., without limitation.

In the description, examples of the heteroaryl group may include thiophene, furan, pyrrole, imidazole, triazole, pyridine, bipyridine, pyrimidine, triazine, triazole, acridine, pyridazine, pyrazine, quinoline, quinazoline, quinoxaline, phenoxazine, phthalazine, pyrido pyrimidine, pyrido pyrazine, pyrazino pyrazine, isoquinoline, indole, carbazole, N-arylcarbazole, N-heteroarylcarbazole, N-alkylcarbazole, benzoxazole, benzoimidazole, benzothiazole, benzocarbazole, benzothiophene, dibenzothiophene, thienothiophene, benzofuran, phenanthroline, thiazole, isooxazole, oxazole, oxadiazole, thiadiazole, phenothiazine, dibenzosilole, dibenzofuran, etc., without limitation.

In the description, the explanation for the aryl group may be applied to the arylene group, except that the arylene group is a divalent group. The explanation for the heteroaryl group may be applied to the heteroarylene group except that the heteroarylene group is a divalent group.

In the description, the silyl group includes an alkyl silyl group and/or an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., without limitation.

In the description, the boryl group includes an alkyl boryl group and/or an aryl boryl group. Examples of the boryl group include a trimethylboryl group, a triethylboryl group, a t-butyldimethylboryl group, a triphenylboryl group, a diphenylboryl group, a phenylboryl group, etc., without limitation.

In the description, the carbon number of the amine group is not specifically limited, but may be 1 to 30. The amine group may include an alkyl amine group, an aryl amine group, and/or a heteroaryl amine group. Examples of the amine group include a methylamine group, a dimethylamine group, a phenylamine group, a diphenylamine group, a naphthylamine group, a 9-methyl-anthracenylamine group, a triphenylamine group, etc., without limitation.

In the description, the oxy group may include an alkoxy group and/or an aryl oxy group. The alkoxy group may be a linear, branched or cyclic group. The carbon number of the alkoxy group is not specifically limited but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc. However, an embodiment of the present disclosure is not limited thereto.

In the description, the alkyl group in the alkyl thio group, alkyl sulfoxy group, alkyl aryl group, alkyl amino group, alkyl boryl group and alkyl silyl group is the same as the above-described alkyl group.

In the description, the aryl group in the aryl oxy group, aryl thio group, aryl sulfoxy group, aryl amino group, aryl boron group, aryl silyl group, aryl selenium group, and aryl alkyl group is the same as the above-described aryl group.

In the description, the direct linkage may refer to a single bond.

In the description, “

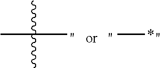

may refer to a connected position (e.g., a binding site).

The first host of the first emission layer EML1 of the organic electroluminescence device of an embodiment may employ any suitable host materials, without limitation. For example, at least one selected from bis[2-(diphenylphosphino)phenyl] ether oxide (DPEPO), 4,4′-bis(carbazol-9-yl)biphenyl (CBP), 1,3-bis(carbazol-9-yl)benzene (mCP), 2,8-bis(diphenylphosphoryl)dibenzo[b,d]furan (PPF), 4,4′,4″-tris(carbazol-9-yl)-triphenylamine (TCTA), 1,3,5-tris(1-phenyl-1H-benzo[d]imidazole-2-yl)benzene (TPBi), 1,3-di(9H-carbazol-9-yl)benzene, 3-(3-(9H-carbazol-9-yl)phenyl)benzofuro[2,3-b]pyridine, and 5-(3-(4,6-diphenyl-1,3,5-triazin-2-yl)phenyl)-3,9-diphenyl-9H-carbazole, may be included. However, an embodiment of the present disclosure is not limited thereto and, for example, tris(8-hydroxyquinolino)aluminum (Alq₃), poly(n-vinylcabazole) (PVK), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-Bis(triphenylsilyl)benzene (UGH2), hexaphenylcyclotrisiloxane (DPSiO₃), octaphenylcyclotetra siloxane (DPSiO4), etc., may be included as the host material.

In the organic electroluminescence device 10 of an embodiment, the first emission layer EML1 may include an anthracene-based compound as the first dopant. For example, the first dopant may include a compound represented by the following Formula D-1:

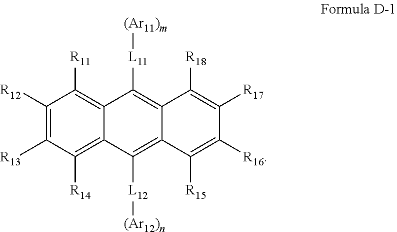

In Formula D-1, R₁₁ to R₁₈ may each independently be a hydrogen atom, a deuterium atom, a substituted or unsubstituted amine group, an unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring. For example, R₁₁ to R₁₈ may each independently be a hydrogen atom, a methyl group, an isopropyl group, a tert-butyl group, a substituted or unsubstituted amine group, a substituted or unsubstituted phenyl group, a naphthyl group, etc., but an embodiment of the present disclosure is not limited thereto.

L₁₁ and L₁₂ may each independently be a direct linkage, a substituted or unsubstituted amine group, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring. For example, L₁₁ and L₁₂ may each independently be a substituted amine group, a substituted or unsubstituted phenyl group, a substituted boryl group, or a substituted silyl group. In some embodiments, L₁₁ and L₁₂ may be a carbazole group. However, an embodiment of the present disclosure is not limited thereto.

Ar₁₁ and Ar₁₂ may each independently be a substituted or unsubstituted aryl group of 6 to 60 carbon atoms for forming a ring, or a substituted or unsubstituted heteroaryl group of 2 to 60 carbon atoms for forming a ring. For example, the aryl group may be a substituted or unsubstituted phenyl group, a substituted or unsubstituted aryl alkyl group, a substituted or unsubstituted aryl silyl group, a substituted or unsubstituted aryl amine group, and/or a substituted or unsubstituted aryl selenium group. For example, the heteroaryl group may be a substituted or unsubstituted carbazole group, a substituted or unsubstituted dibenzothiophene group, or a substituted or unsubstituted dibenzofuran group. However, an embodiment of the present disclosure is not limited thereto.

m and n may each independently be an integer of 0 to 3. For example, m and n may each independently be 0, 1, or 2. When m and n are each independently an integer of 2 or more, a plurality of Ar₁₁ groups and/or a plurality of Ar₁₂ groups may be the same or at least one thereof may be different.

The first dopant represented by Formula D-1 may be represented by any one of Formulae D-1a, D-1b or D-1c:

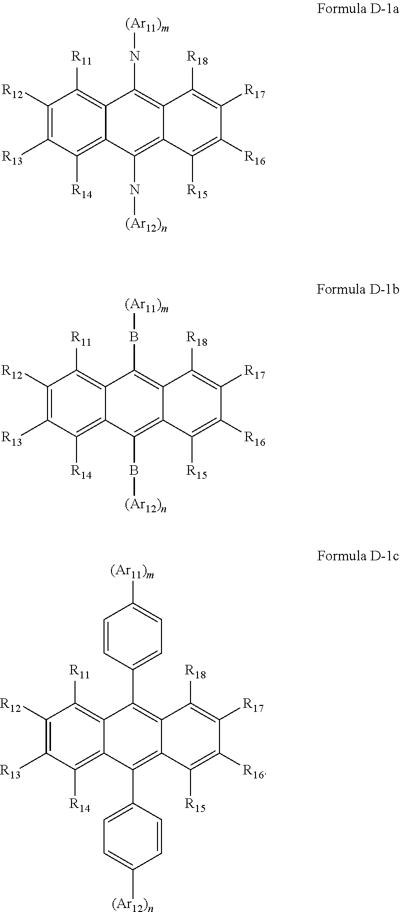

In Formulae D-1a to D-1c, the definitions provided in connection with Formula D-1 may be applied to R₁₁ to R₁₈, Ar₁₁, Ar₁₂, m and n.

In the organic electroluminescence device 10 of an embodiment, the second emission layer EML2 may include a compound represented by Formula H-1 as the second host:

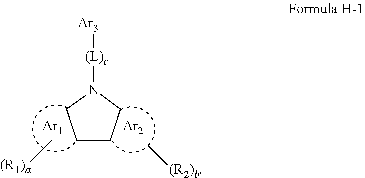

In Formula H-1, Ar₁ to Ar₃ may each independently be a substituted or unsubstituted aryl group of 6 to 30 carbon atoms for forming a ring, or a substituted or unsubstituted heteroaryl group of 2 to 60 carbon atoms for forming a ring. For example, Ar₁ and Ar₂ may each independently be a substituted or unsubstituted benzene ring or a substituted or unsubstituted pyrimidine ring. However, an embodiment of the present disclosure is not limited thereto. For example, Ar₃ may be a substituted or unsubstituted carbazole group, a substituted or unsubstituted phenyl group, a substituted or unsubstituted aryl silyl group, or a substituted or unsubstituted triazine group. However, an embodiment of the present disclosure is not limited thereto.

L may be a direct linkage, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring. For example, the substituted silyl group may be a silyl group substituted with a methyl group. The substituted boryl group may be a boryl group substituted with a mesitylene group. The substituted or unsubstituted arylene group may be a substituted or unsubstituted phenylene group. The substituted or unsubstituted heteroarylene group may be a substituted or unsubstituted pyridine group, or a substituted or unsubstituted triazine group. However, an embodiment of the present disclosure is not limited thereto. R₁ and R₂ may each independently be a hydrogen atom, a deuterium atom, a substituted or unsubstituted silyl group, a substituted or unsubstituted phosphine oxide group, a substituted or unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring, and any of R₁ and R₂ may be combined with an adjacent group to form a ring. For example, R₁ and R₂ may each independently be a substituted or unsubstituted carbazole group or a substituted or unsubstituted phenyl group. For example, when each of R₁ and R₂ is combined with an adjacent group to form a ring, R₁ may form a ring with L, which is adjacent to R₁. Here, when R₁ is N, and L is C, a ring such as

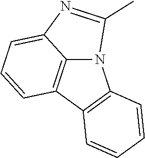 [SMILES: Cc1nc2cccc3c4ccccc4n1c23]

may be formed. However, an embodiment of the present disclosure is not limited thereto.

a to c may each independently be an integer of 0 to 2. For example, when a to c are each independently integers of 2 or more, a plurality of R₁ groups, a plurality of R₂ groups, and/or a plurality of L groups may be the same or at least one thereof may be different.

The second host represented by Formula H-1 may be represented by Formula H-1a:

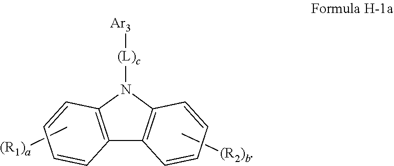

In Formula H-1a, the same definitions as those provided in connection with Formula H-1 may be applied to Ar₃, R₁, R₂, L and a to c.

The second dopant of the second emission layer EML2 of the organic electroluminescence device of an embodiment may be a phosphorescence emission dopant. The second dopant may include an organometal compound. For example, the second dopant may include iridium (Ir), platinum (Pt), palladium (Pd), or gold (Au).

However, an embodiment is not limited thereto, and the second dopant may use any suitable phosphorescence dopant material, without limitation. For example, the phosphorescence dopant may use a metal complex including iridium (Ir), platinum (Pt), palladium (Pd), osmium (Os), gold (Au), titanium (Ti), zirconium (Zr), hafnium (Hf), europium (Eu), terbium (Tb), or thulium (Tm). In some embodiments, iridium(III) bis(4,6-difluorophenylpyridinato-N, C2′ (Flrpic), bis(2,4-difluorophenylpyridinato)-tetrakis(1-pyrazolyl)borate iridium(III)) (Flr6), and/or platinum octaethyl porphyrin (PtOEP) may be used as the phosphorescence dopant. However, an embodiment of the present disclosure is not limited thereto.

The organic electroluminescence device 10 of an embodiment may include a first host and a first dopant represented by Formula D-1 in the first emission layer EML1. The first dopant may include anthracene derivative(s). The lowest triplet excitation energy level (T₁ level) of the first dopant may be about 2.0 eV or less.

The second emission layer EML2 may include a second host represented by Formula H-1 and a second dopant. The second dopant may be a phosphorescence dopant. The second emission layer EML2 according to an embodiment may emit green phosphorescence, but an embodiment of the present disclosure is not limited thereto.

In the organic electroluminescence device 10 of an embodiment, the first emission layer EML1 may be adjacent to the second emission layer EML2. For example, the first emission layer EML1 and the second emission layer EML2 may contact from each other. Due to the contact of the first emission layer EML1 and the second emission layer EML2, excitons produced in the emission layers EML1 and EML2 may move to each other.

For example, if the lowest triplet excitation energy level (T₁ level) of the first dopant is about 2.0 eV or less, excitons produced in the emission layers EML1 and EML2 may partially move to the T₁ level of the first dopant.

In an embodiment, the thickness of the first emission layer EML1 may be from about 1 nm to about 10 nm. For example, the thickness of the first emission layer EML1 may be about 3 nm. The thickness of the second emission layer EML2 may be from about 10 nm to about 100 nm. For example, the thickness of the second emission layer EML2 may be about 40 nm. By controlling the thickness of the first emission layer EML1 to be smaller than the thickness of the second emission layer EML2, the emission intensity of the first emission layer EML1 may be maintained as being weaker than that of the second emission layer EML2. Accordingly, the excitons moved to the first dopant of the first emission layer EML1 may not emit light in the first emission layer EML1 but may be trapped, and a layer substantially emitting light in the organic electroluminescence device 10 may become the second emission layer EML2. The organic electroluminescence device 10 of an embodiment may provide the first emission layer EML1 of a thin film adjacent to the second emission layer EML2, which substantially emits light, the concentration of the produced excitons may be suitably controlled, and accordingly, the deterioration of the overall organic electroluminescence device 10 may be prevented or reduced, and its life may be improved.

In an embodiment, the first dopant represented by Formula D-1 may be represented by any one selected from the compounds represented in Compound Group 1. The first emission layer EML1 may include at least one compound represented in Compound Group 1 as the first dopant material.

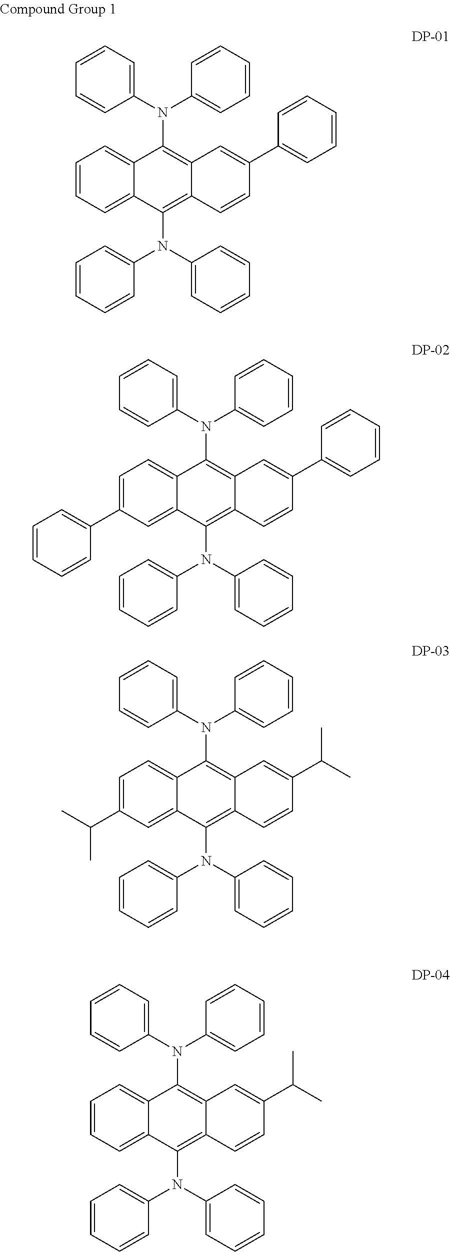

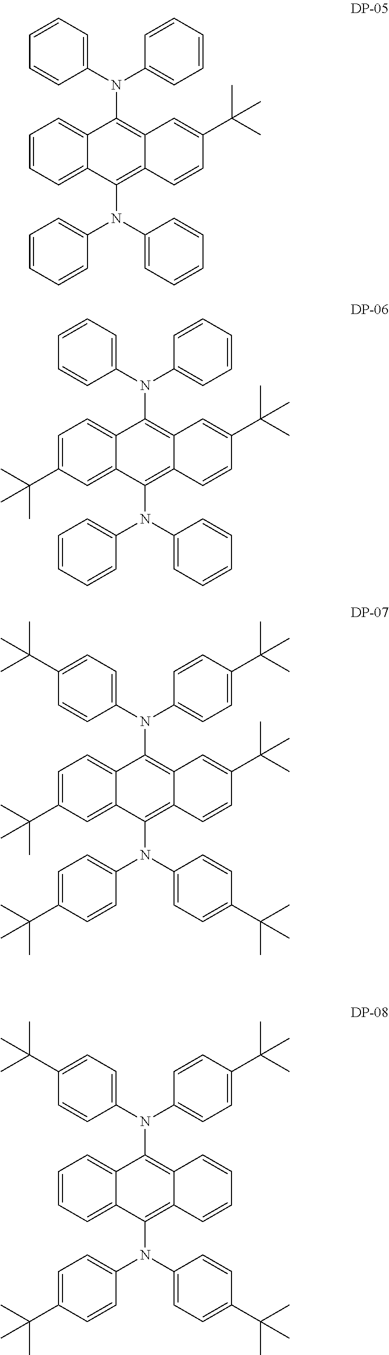

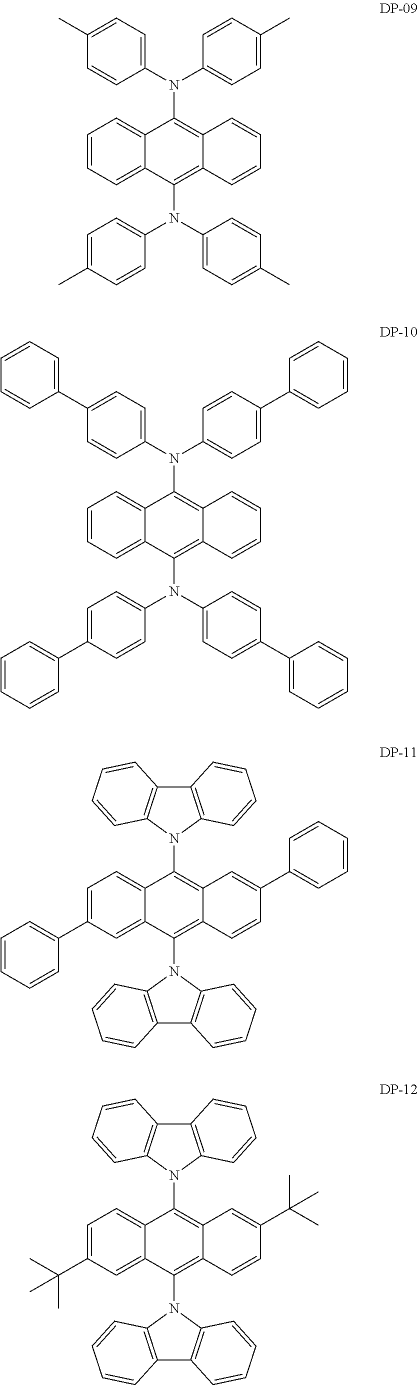

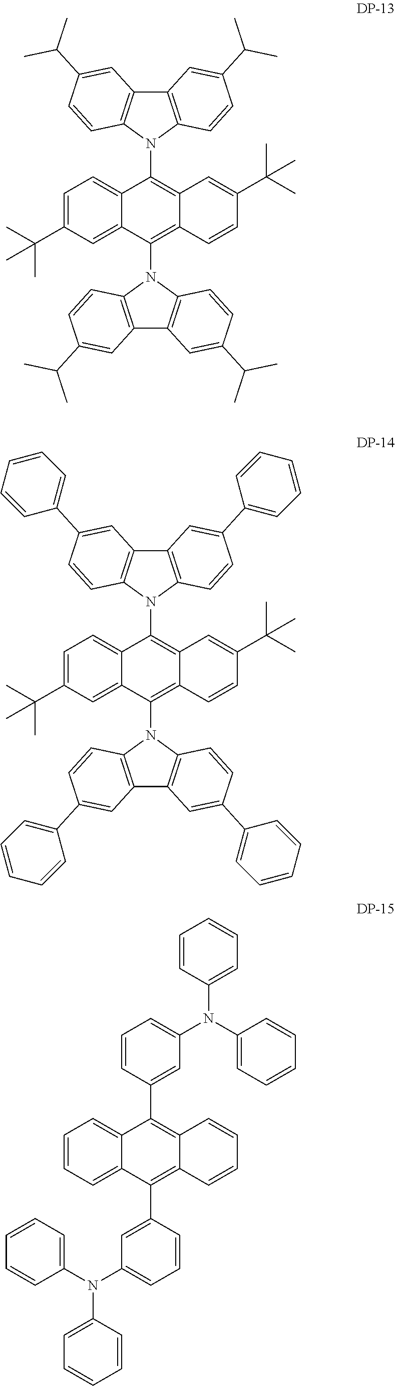 [SMILES: CC(C)c1ccc2c(c1)c1cc(C(C)C)ccc1n2-c1c2ccc(C(C)(C)C)cc2c(-n2c3ccc(C(C)C)cc3c3cc(C(C)C)ccc32)c2ccc(C(C)(C)C)cc12 ; CC(C)(C)c1ccc2c(-n3c4ccc(-c5ccccc5)cc4c4cc(-c5ccccc5)ccc43)c3cc(C(C)(C)C)ccc3c(-n3c4ccc(-c5ccccc5)cc4c4cc(-c5ccccc5)ccc43)c2c1 ; c1ccc(N(c2ccccc2)c2cccc(-c3c4ccccc4c(-c4cccc(N(c5ccccc5)c5ccccc5)c4)c4ccccc34)c2)cc1]

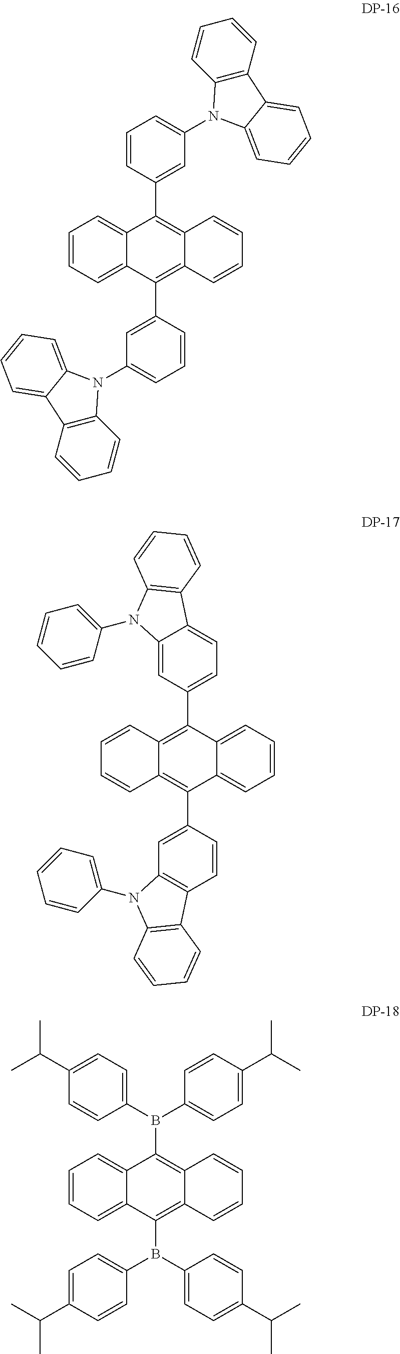 [SMILES: c1cc(-c2c3ccccc3c(-c3cccc(-n4c5ccccc5c5ccccc54)c3)c3ccccc23)cc(-n2c3ccccc3c3ccccc32)c1 ; c1ccc(-n2c3ccccc3c3ccc(-c4c5ccccc5c(-c5ccc6c7ccccc7n(-c7ccccc7)c6c5)c5ccccc45)cc32)cc1 ; CC(C)c1ccc(B(c2ccc(C(C)C)cc2)c2c3ccccc3c(B(c3ccc(C(C)C)cc3)c3ccc(C(C)C)cc3)c3ccccc23)cc1]

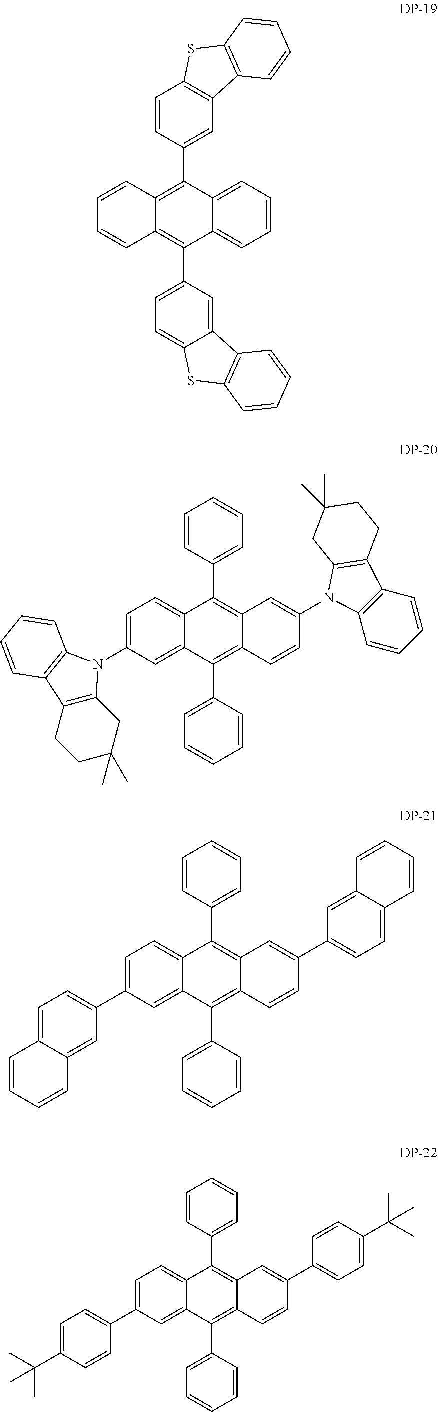

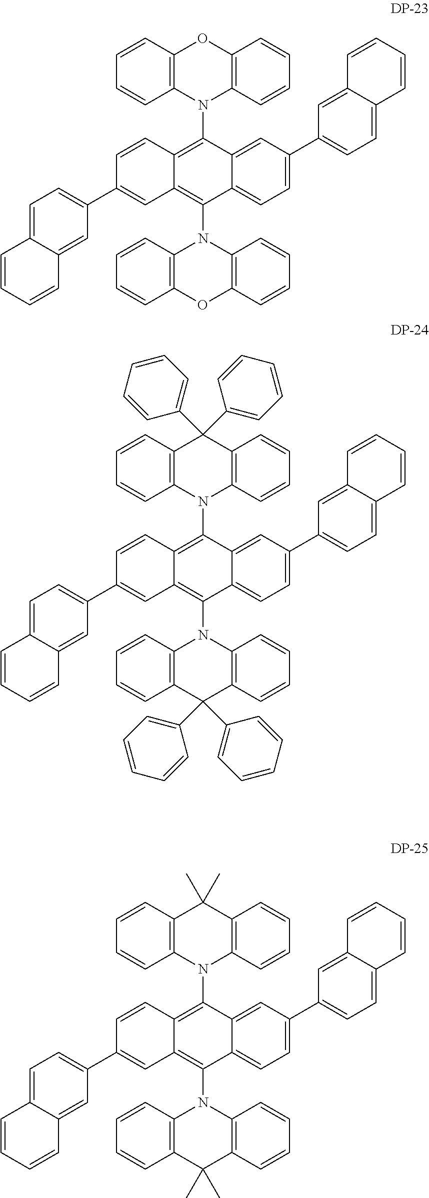 [SMILES: c1ccc2c(c1)Oc1ccccc1N2c1c2ccc(-c3ccc4ccccc4c3)cc2c(N2c3ccccc3Oc3ccccc32)c2ccc(-c3ccc4ccccc4c3)cc12 ; c1ccc(C2(c3ccccc3)c3ccccc3N(c3c4ccc(-c5ccc6ccccc6c5)cc4c(N4c5ccccc5C(c5ccccc5)(c5ccccc5)c5ccccc54)c4ccc(-c5ccc6ccccc6c5)cc34)c3ccccc32)cc1 ; CC1(C)c2ccccc2N(c2c3ccc(-c4ccc5ccccc5c4)cc3c(N3c4ccccc4C(C)(C)c4ccccc43)c3ccc(-c4ccc5ccccc5c4)cc23)c2ccccc21]

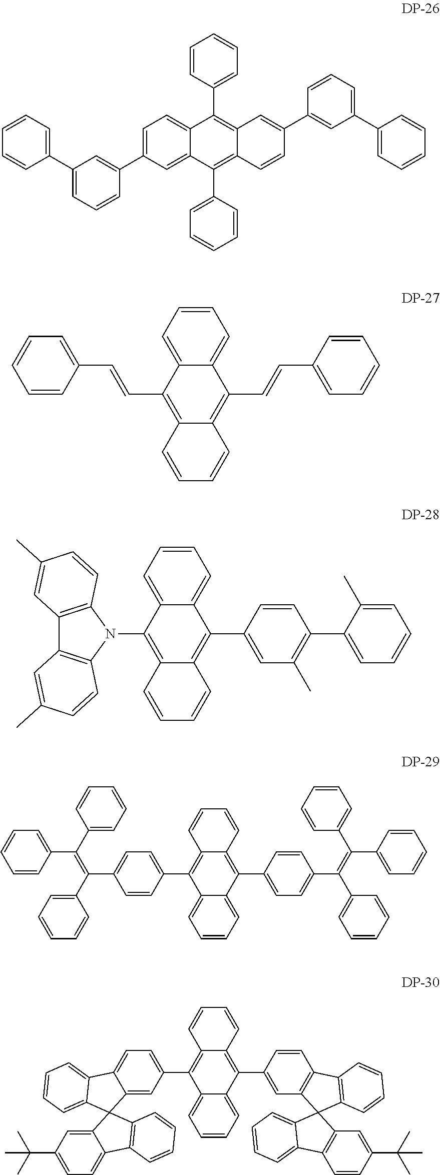

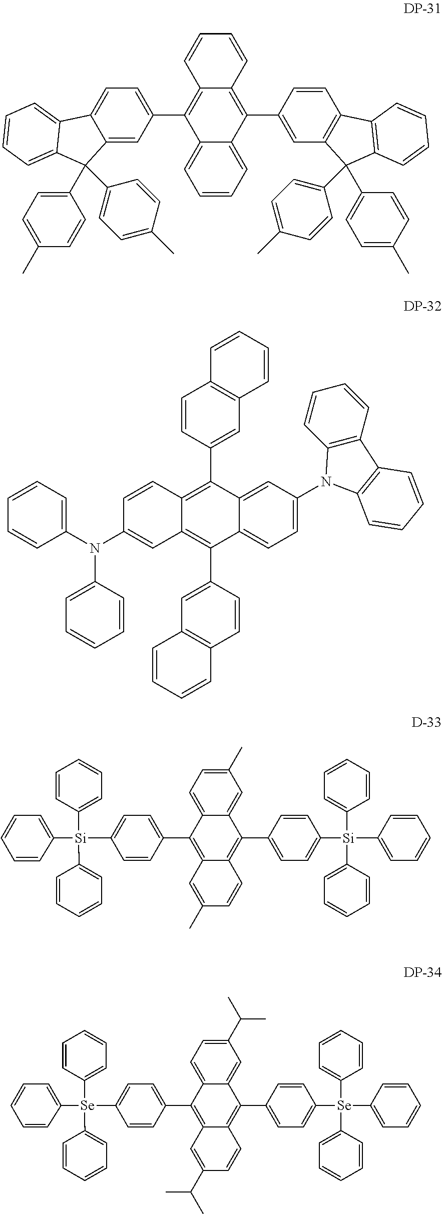

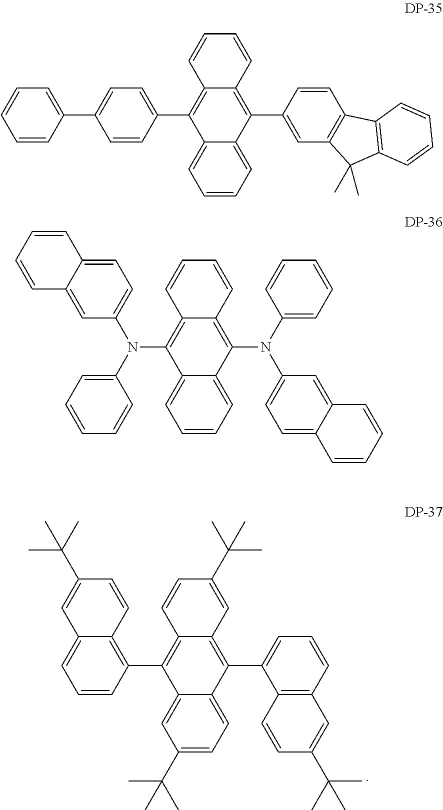

In an embodiment, the second host represented by Formula H-1 may include at least one selected from the compounds represented in Compound Group 2.

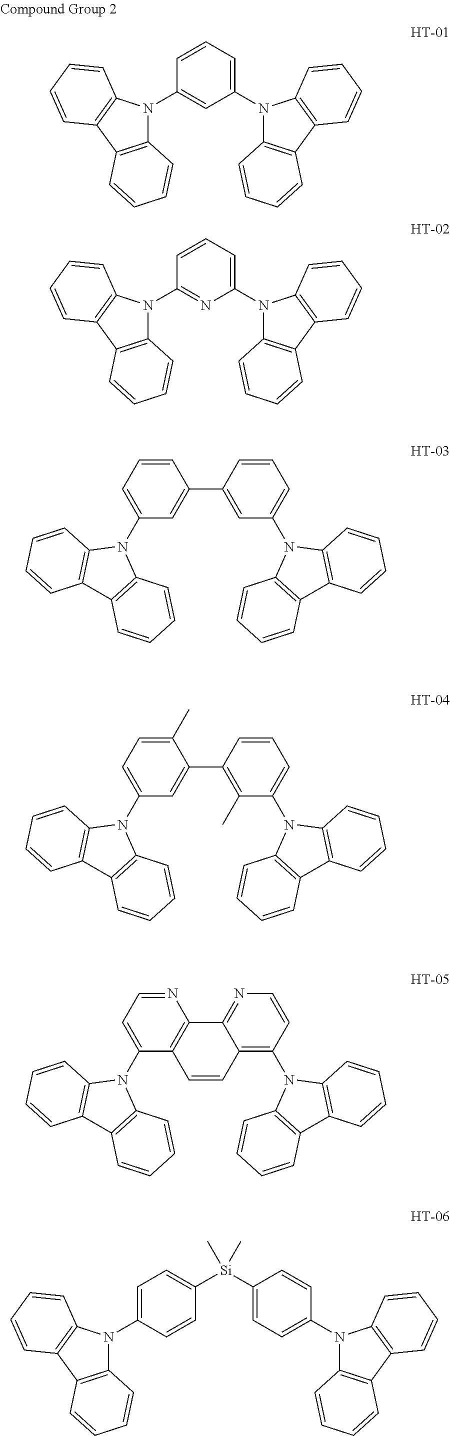 [SMILES: c1cc(-n2c3ccccc3c3ccccc32)cc(-n2c3ccccc3c3ccccc32)c1 ; c1cc(-n2c3ccccc3c3ccccc32)nc(-n2c3ccccc3c3ccccc32)c1 ; c1cc(-c2cccc(-n3c4ccccc4c4ccccc43)c2)cc(-n2c3ccccc3c3ccccc32)c1 ; Cc1ccc(-n2c3ccccc3c3ccccc32)cc1-c1cccc(-n2c3ccccc3c3ccccc32)c1C ; c1ccc2c(c1)c1ccccc1n2-c1ccnc2c1ccc1c(-n3c4ccccc4c4ccccc43)ccnc12 ; C[Si](C)(c1ccc(-n2c3ccccc3c3ccccc32)cc1)c1ccc(-n2c3ccccc3c3ccccc32)cc1]

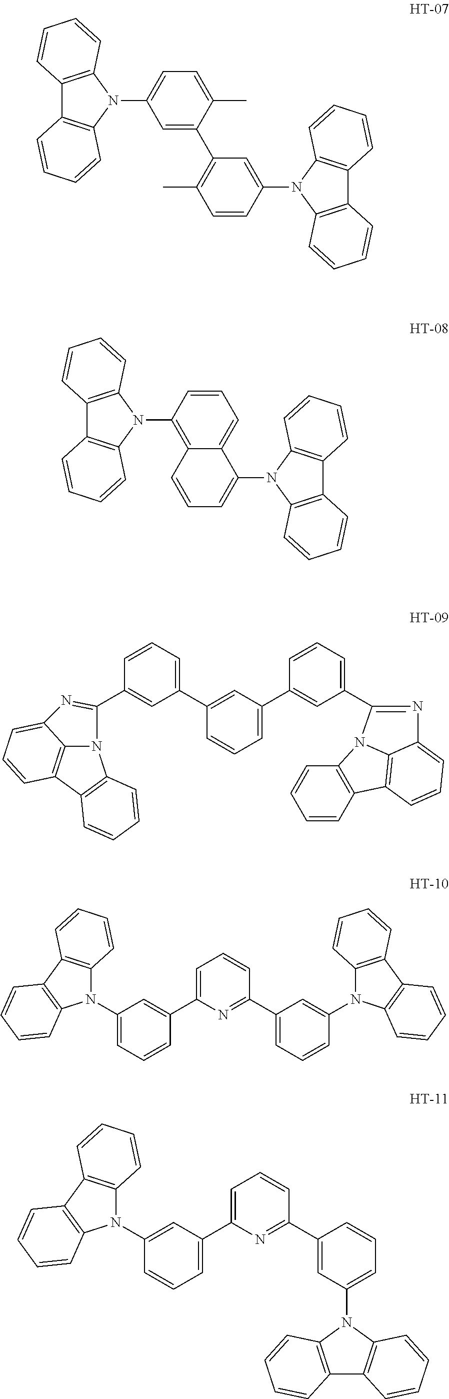 [SMILES: Cc1ccc(-n2c3ccccc3c3ccccc32)cc1-c1cc(-n2c3ccccc3c3ccccc32)ccc1C ; c1cc(-n2c3ccccc3c3ccccc32)c2cccc(-n3c4ccccc4c4ccccc43)c2c1 ; c1cc(-c2cccc(-c3nc4cccc5c6ccccc6n3c45)c2)cc(-c2cccc(-c3nc4cccc5c6ccccc6n3c45)c2)c1 ; c1cc(-c2cccc(-c3cccc(-n4c5ccccc5c5ccccc54)c3)n2)cc(-n2c3ccccc3c3ccccc32)c1 ; c1cc(-c2cccc(-c3cccc(-n4c5ccccc5c5ccccc54)c3)n2)cc(-n2c3ccccc3c3ccccc32)c1]

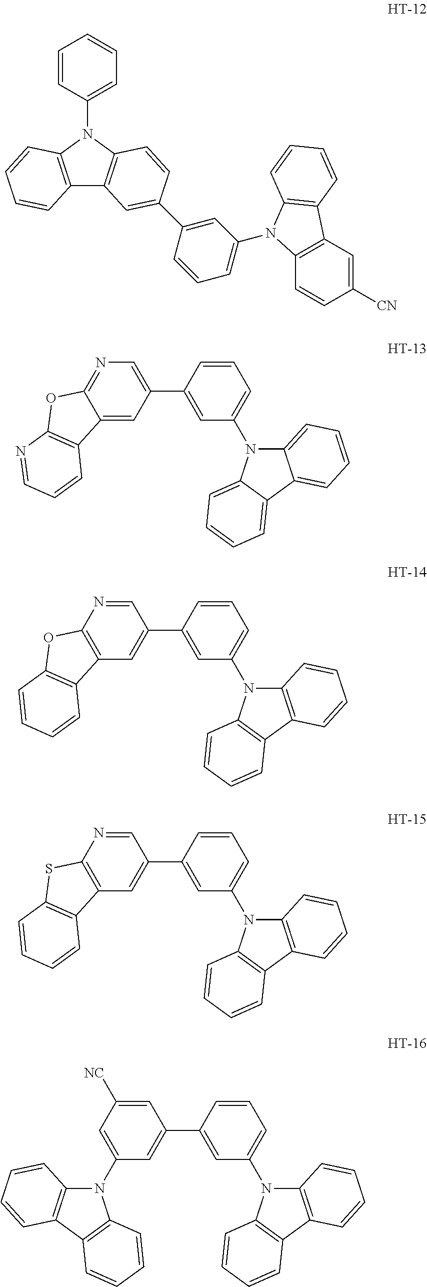 [SMILES: N#Cc1ccc2c(c1)c1ccccc1n2-c1cccc(-c2ccc3c(c2)c2ccccc2n3-c2ccccc2)c1 ; c1cc(-c2cnc3oc4ncccc4c3c2)cc(-n2c3ccccc3c3ccccc32)c1 ; c1cc(-c2cnc3oc4ccccc4c3c2)cc(-n2c3ccccc3c3ccccc32)c1 ; c1cc(-c2cnc3sc4ccccc4c3c2)cc(-n2c3ccccc3c3ccccc32)c1 ; N#Cc1cc(-c2cccc(-n3c4ccccc4c4ccccc43)c2)cc(-n2c3ccccc3c3ccccc32)c1]

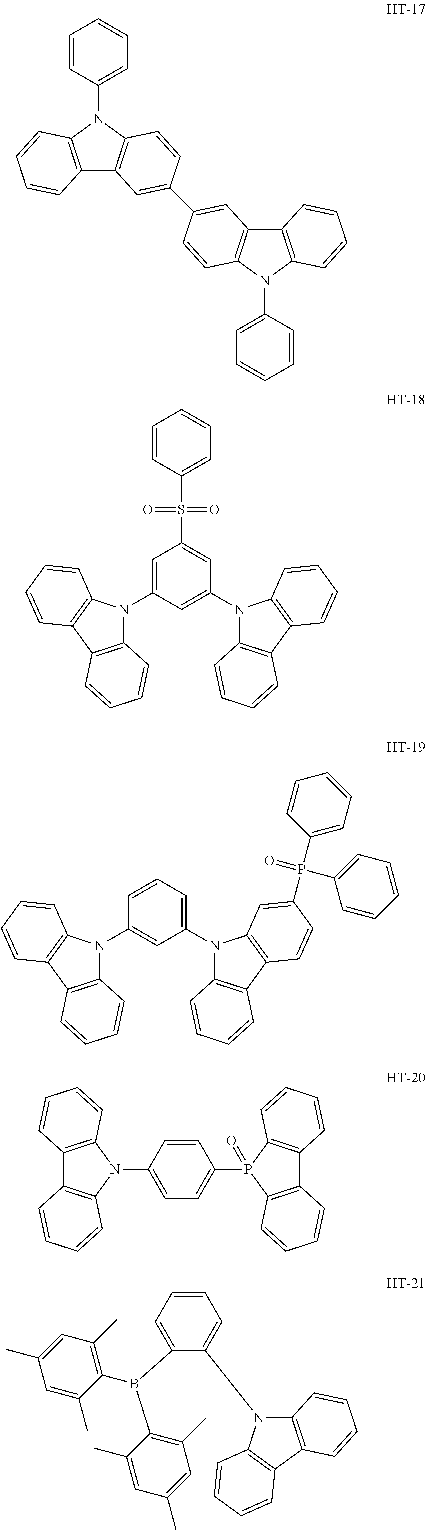

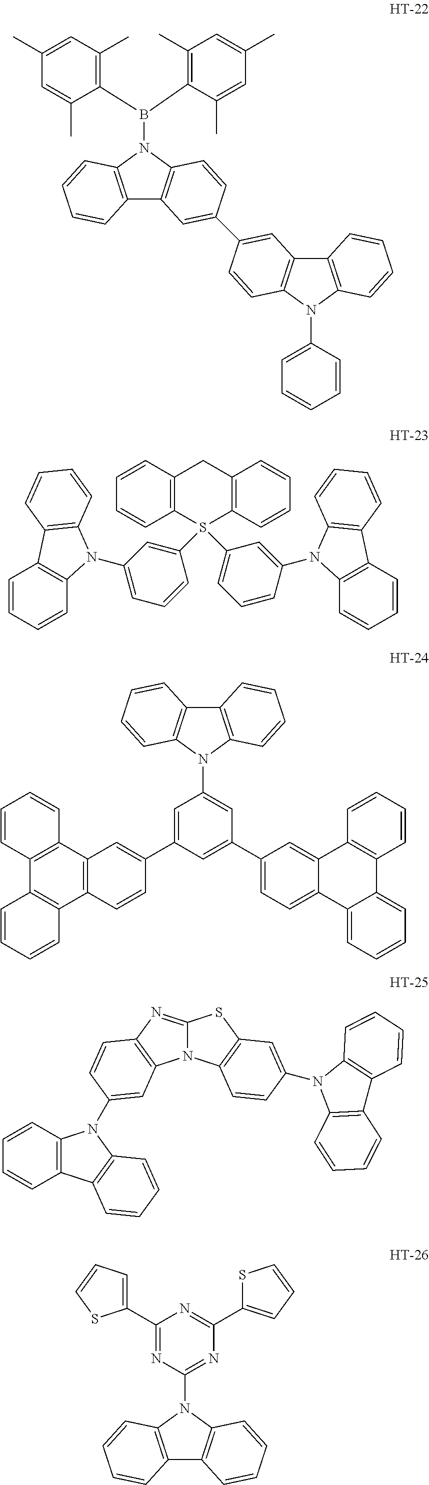 [SMILES: Cc1cc(C)c(B(c2c(C)cc(C)cc2C)n2c3ccccc3c3cc(-c4ccc5c(c4)c4ccccc4n5-c4ccccc4)ccc32)c(C)c1 ; c1cc(-n2c3ccccc3c3ccccc32)cc(S2(c3cccc(-n4c5ccccc5c5ccccc54)c3)c3ccccc3Cc3ccccc32)c1 ; c1ccc2c(c1)c1ccccc1c1cc(-c3cc(-c4ccc5c6ccccc6c6ccccc6c5c4)cc(-n4c5ccccc5c5ccccc54)c3)ccc21 ; c1ccc2c(c1)c1ccccc1n2-c1ccc2c(c1)sc1nc3ccc(-n4c5ccccc5c5ccccc54)cc3n12 ; c1csc(-c2nc(-c3cccs3)nc(-n3c4ccccc4c4ccccc43)n2)c1]

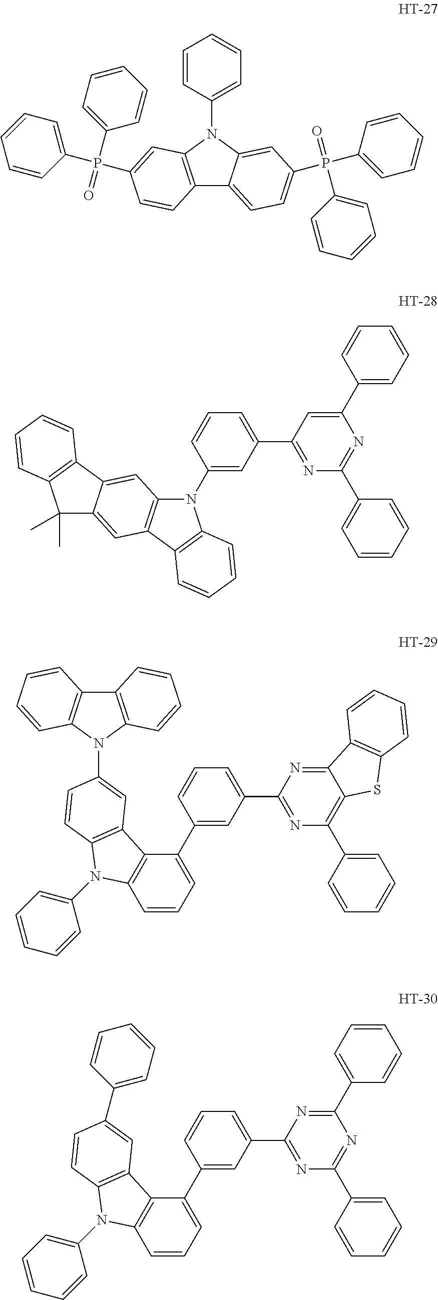 [SMILES: O=P(c1ccccc1)(c1ccccc1)c1ccc2c3ccc(P(=O)(c4ccccc4)c4ccccc4)cc3n(-c3ccccc3)c2c1 ; CC1(C)c2ccccc2-c2cc3c(cc21)c1ccccc1n3-c1cccc(-c2cc(-c3ccccc3)nc(-c3ccccc3)n2)c1 ; c1ccc(-c2nc(-c3cccc(-c4cccc5c4c4cc(-n6c7ccccc7c7ccccc76)ccc4n5-c4ccccc4)c3)nc3c2sc2ccccc23)cc1 ; c1ccc(-c2ccc3c(c2)c2c(-c4cccc(-c5nc(-c6ccccc6)nc(-c6ccccc6)n5)c4)cccc2n3-c2ccccc2)cc1]

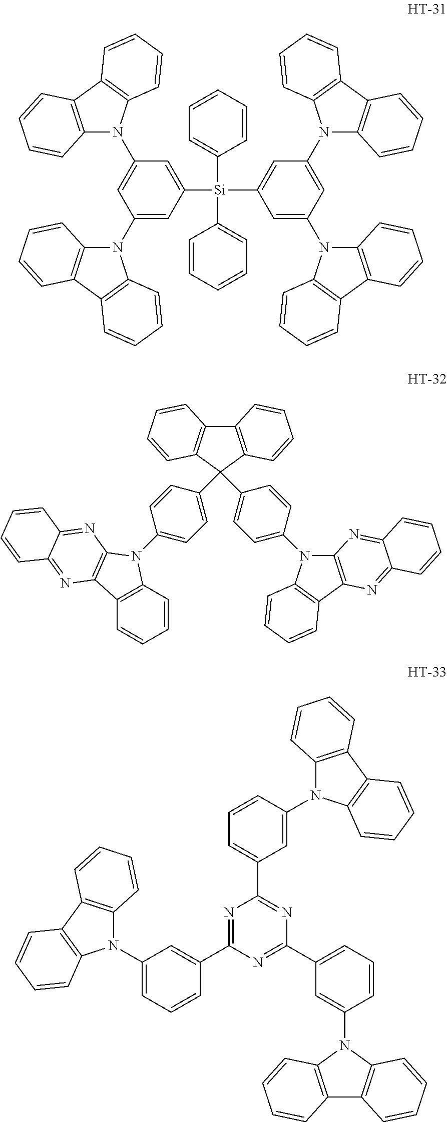 [SMILES: c1ccc([Si](c2ccccc2)(c2cc(-n3c4ccccc4c4ccccc43)cc(-n3c4ccccc4c4ccccc43)c2)c2cc(-n3c4ccccc4c4ccccc43)cc(-n3c4ccccc4c4ccccc43)c2)cc1 ; c1ccc2c(c1)-c1ccccc1C2(c1ccc(-n2c3ccccc3c3nc4ccccc4nc32)cc1)c1ccc(-n2c3ccccc3c3nc4ccccc4nc32)cc1 ; c1cc(-c2nc(-c3cccc(-n4c5ccccc5c5ccccc54)c3)nc(-c3cccc(-n4c5ccccc5c5ccccc54)c3)n2)cc(-n2c3ccccc3c3ccccc32)c1]

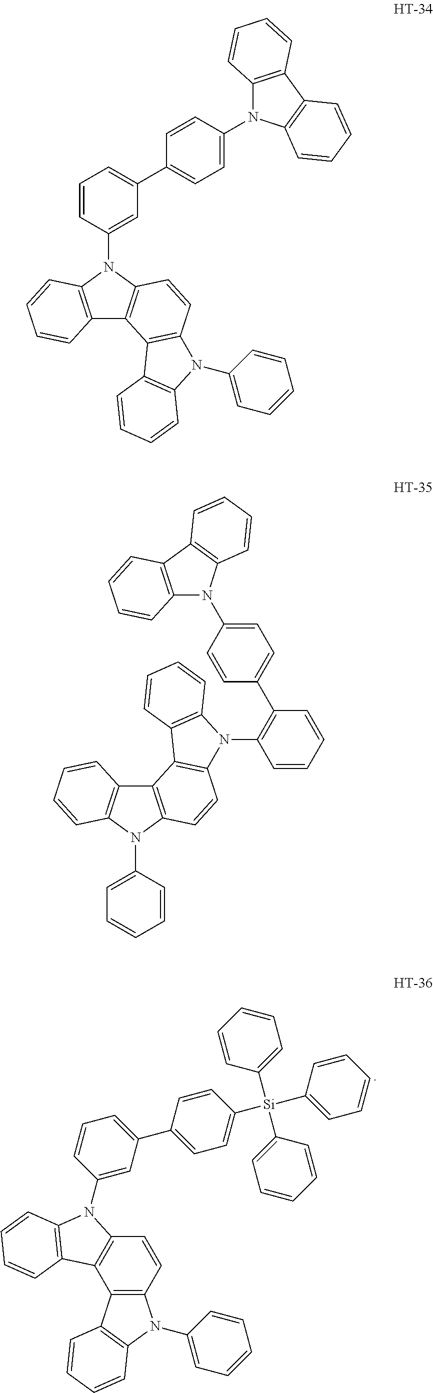 [SMILES: c1ccc(-n2c3ccccc3c3c4c5ccccc5n(-c5cccc(-c6ccc(-n7c8ccccc8c8ccccc87)cc6)c5)c4ccc32)cc1 ; c1ccc(-n2c3ccccc3c3c4c5ccccc5n(-c5ccccc5-c5ccc(-n6c7ccccc7c7ccccc76)cc5)c4ccc32)cc1 ; c1ccc(-n2c3ccccc3c3c4c5ccccc5n(-c5cccc(-c6ccc([Si](c7ccccc7)(c7ccccc7)c7ccccc7)cc6)c5)c4ccc32)cc1]

The organic electroluminescence device 10 of an embodiment may show excellent (or improved) emission efficiency and life characteristics by combining the first host used in the first emission layer EML1 and the second host used in the second emission layer EML2.

In the organic electroluminescence devices 10 of the embodiments shown in FIGS. 1A to 4, the electron transport region ETR is provided on the first emission layer EML1 and the second emission layer EML2. The electron transport region ETR may include at least one of a hole blocking layer HBL, an electron transport layer ETL, or an electron injection layer EIL. However, an embodiment of the present disclosure is not limited thereto.

The electron transport region ETR may have a single layer formed using a single material, a single layer formed using a plurality of different materials, or a multilayer structure having a plurality of layers formed using a plurality of different materials.

For example, the electron transport region ETR may have a single layer structure of an electron injection layer EIL or an electron transport layer ETL, or a single layer structure formed using an electron injection material and an electron transport material. In some embodiments, the electron transport region ETR may have a single layer structure having a plurality of different materials, or a structure laminated from the emission layers EML1 and EML2 of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed using one or more suitable methods such as a vacuum deposition method, a spin coating method, a cast method, a Langmuir-Blodgett (LB) method, an inkjet printing method, a laser printing method, and/or a laser induced thermal imaging (LITI) method.

If the electron transport region ETR includes an electron transport layer ETL, the electron transport region ETR may include an anthracene-based compound. In some embodiments, the electron transport region may include, for example, tris(8-hydroxyquinolinato)aluminum (Alq3), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1, O8)-(1,1′-biphenyl-4-olato)aluminum (BAlq), beryllium bis(benzoquinolin-10-olate (Bebq2), 9,10-di(naphthalene-2-yl)anthracene (ADN), 1,3-bis[3,5-di(pyridine-3-yl)phenyl]benzene (BmPyPhB), or a mixture thereof, without limitation. The thickness of the electron transport layer ETL may be from about 100 Å to about 1,000 Å and may be, for example, from about 150 Å to about 500 Å. When the thickness of the electron transport layer ETL satisfies the above-described range, satisfactory (or suitable) electron transport properties may be obtained without substantial increase of a driving voltage.

If the electron transport region ETR includes the electron injection layer EIL, the electron transport region ETR may include, for example, a metal halide (such as LiF, NaCl, CsF, RbCI, and/or Rbl), a metal in lanthanoides (such as Yb), a metal oxide (such as Li₂O and/or BaO), and/or lithium quinolate (LiQ). However, an embodiment of the present disclosure is not limited thereto. The electron injection layer EIL also may be formed using a mixture material of an electron transport material and an insulating organo metal salt. The organo metal salt may be a material having an energy band gap of about 4 eV or more. The organo metal salt may include, for example, metal acetates, metal benzoates, metal acetoacetates, metal acetylacetonates, and/or metal stearates. The thickness of the electron injection layer EIL may be from about 1 Å to about 100 Å, for example, from about 3 Å to about 90 Å. When the thickness of the electron injection layer EIL satisfies the above described range, satisfactory (or suitable) electron injection properties may be obtained without inducing a substantial increase of a driving voltage.

The electron transport region ETR may include a hole blocking layer HBL. The hole blocking layer HBL may include, for example, at least one of 2,9-dimethyl-4,7-diphenyl-1,10-phenanthroline (BCP), or 4,7-diphenyl-1,10-phenanthroline (Bphen).

However, an embodiment of the present disclosure is not limited thereto.

The second electrode EL2 may be provided on the electron transport region ETR. The second electrode EL2 may be a common electrode and/or a cathode. The second electrode EL2 may be a transmissive electrode, a transflective electrode, or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, a compound thereof, or a mixture thereof (for example, a mixture of Ag and Mg). The second electrode EL2 may have a multilayered structure including a reflective layer or a transflective layer formed using any of the above-described materials, and a transparent conductive layer formed using ITO, IZO, ZnO, ITZO, etc.

In some embodiments, the second electrode EL2 may be connected with an auxiliary electrode. When the second electrode EL2 is connected with the auxiliary electrode, the resistance of the second electrode EL2 may decrease.

In some embodiments, on the second electrode EL2 of the organic electroluminescence device 10 of an embodiment, a capping layer (CPL) may be further provided. The capping layer (CPL) may include, for example, α-NPD, NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), N, N′-bis(naphthalene-1-yl), etc.

The organic electroluminescence device 10 according to an embodiment of the present disclosure includes the combination of the first dopant of the first emission layer EML1 and the second host of the second emission layer EML2, thereby showing excellent (e.g., improved) emission efficiency and long-life characteristics. In addition, the organic electroluminescence device 10 of an embodiment may show high efficiency and long-life characteristics in a green wavelength region.

Hereinafter, the compounds according to embodiments of the present disclosure and the organic electroluminescence device of an embodiment of the present disclosure will be particularly explained referring to embodiments and comparative embodiments. The following embodiments are only illustrations to assist the understanding of the present disclosure, and the scope of the present disclosure is not limited thereto.

### EXAMPLES

### Manufacture of Organic Electroluminescence Device

The organic electroluminescence devices of the Examples and Comparative Examples were manufactured as follows. An ITO glass substrate was cut into a size of 50 mm×50 mm×0.5 mm, washed by ultrasonic waves using isopropyl alcohol and distilled water for 15 minutes, respectively, exposed to ultraviolet rays and ozone for about 30 minutes for washing, and installed in a vacuum deposition apparatus. Then, a hole injection layer was formed to a thickness of about 70 nm using HTM-01, and a hole transport layer was formed to a thickness of about 10 nm using TCTA. Then, the second host and the second dopant according to embodiments were co-deposited to form a second emission layer with a thickness of about 40 nm, and the first host and the first dopant were co-deposited to form a first emission layer with a thickness of about 5 nm.

An electron transport layer was formed using a compound ETM-01 (shown below) to a thickness of about 30 nm. An electron injection layer was formed using LiF to a thickness of about 1 nm, and a second electrode was formed using Al to a thickness of about 200 nm. All layers were formed by a vacuum deposition method.

Materials used in the layers for the manufacture of the organic electroluminescence devices are as follows:

### Compounds of Functional Layers

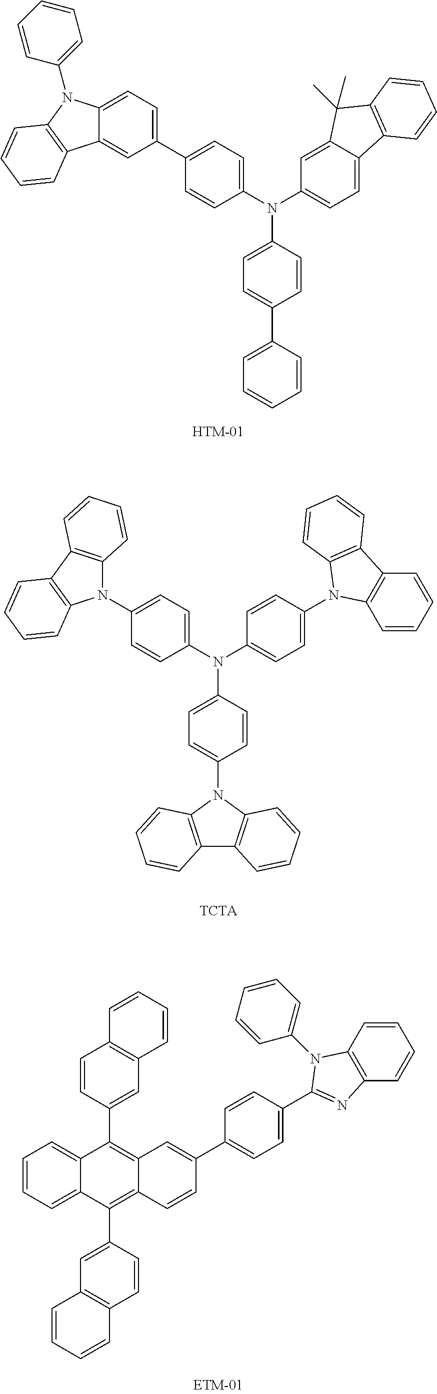

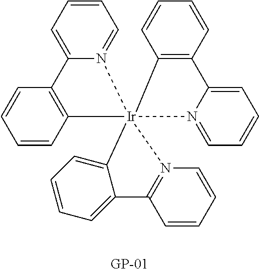

### Example Compounds

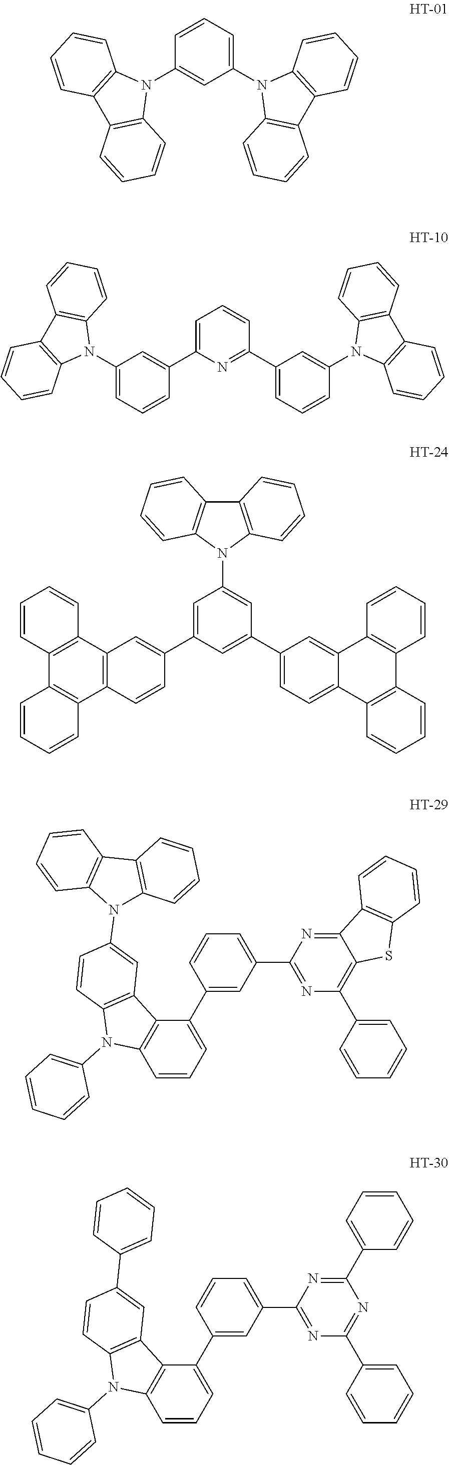 [SMILES: c1cc(-n2c3ccccc3c3ccccc32)cc(-n2c3ccccc3c3ccccc32)c1 ; c1cc(-c2cccc(-c3cccc(-n4c5ccccc5c5ccccc54)c3)n2)cc(-n2c3ccccc3c3ccccc32)c1 ; c1ccc2c(c1)c1ccccc1c1cc(-c3cc(-c4ccc5c6ccccc6c6ccccc6c5c4)cc(-n4c5ccccc5c5ccccc54)c3)ccc21 ; c1ccc(-c2nc(-c3cccc(-c4cccc5c4c4cc(-n6c7ccccc7c7ccccc76)ccc4n5-c4ccccc4)c3)nc3c2sc2ccccc23)cc1 ; c1ccc(-c2ccc3c(c2)c2c(-c4cccc(-c5nc(-c6ccccc6)nc(-c6ccccc6)n5)c4)cccc2n3-c2ccccc2)cc1]

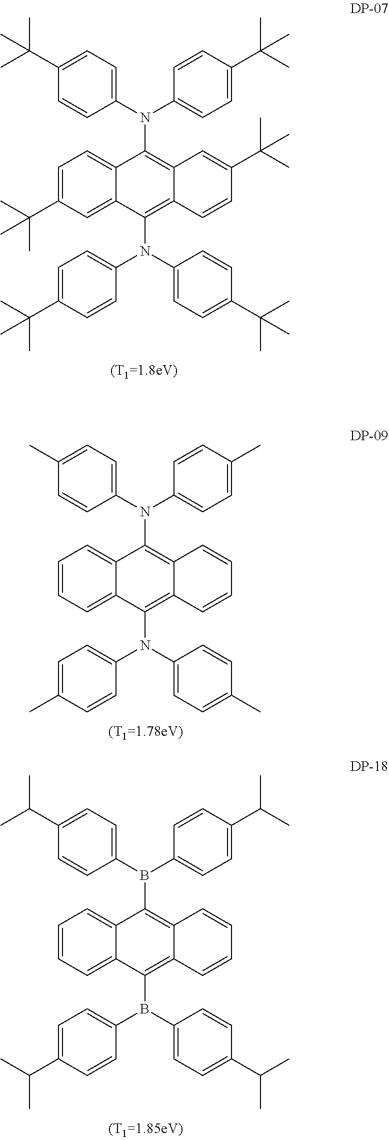

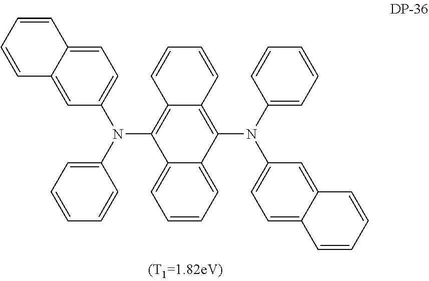 [SMILES: c1ccc(N(c2ccc3ccccc3c2)c2c3ccccc3c(N(c3ccccc3)c3ccc4ccccc4c3)c3ccccc23)cc1]

### Comparative Compound of First Dopant

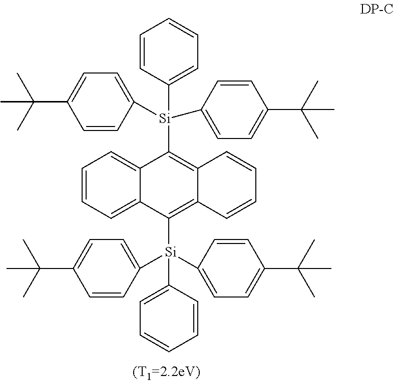 [SMILES: CC(C)(C)c1ccc([Si](c2ccccc2)(c2ccc(C(C)(C)C)cc2)c2c3ccccc3c([Si](c3ccccc3)(c3ccc(C(C)(C)C)cc3)c3ccc(C(C)(C)C)cc3)c3ccccc23)cc1]

The combination of the materials used in the Examples and the Comparative Examples are shown in Table 1 below.

TABLE 1

| Device | | | | |
|---|---|---|---|---|
| manufacturing | First | First | Second | Second |
| example | host | dopant | host | dopant |
| Example 1 | HT-01 | DP-07 | HT-24 | GP-01 |
| Example 2 | HT-01 | DP-09 | HT-24 | GP-01 |
| Example 3 | HT-01 | DP-18 | HT-24 | GP-01 |
| Example 4 | HT-01 | DP-36 | HT-24 | GP-01 |
| Example 5 | HT-10 | DP-07 | HT-29 | GP-01 |
| Example 6 | HT-10 | DP-09 | HT-29 | GP-01 |
| Example 7 | HT-10 | DP-18 | HT-29 | GP-01 |
| Example 8 | HT-10 | DP-36 | HT-29 | GP-01 |
| Example 9 | HT-10 | DP-07 | HT-30 | GP-01 |
| Example 10 | HT-10 | DP-09 | HT-30 | GP-01 |
| Example 11 | HT-10 | DP-18 | HT-30 | GP-01 |
| Example 12 | HT-10 | DP-36 | HT-30 | GP-01 |
| Comparative | — | — | HT-24 | GP-01 |
| Example 1 | | | | |
| Comparative | HT-01 | DP-07 | — | — |
| Example 2 | | | | |
| Comparative | HT-01 | DP-C | HT-24 | GP-01 |
| Example 3 | | | | |

### Evaluation of Properties of Organic Electroluminescence Device

The evaluation of the properties of the organic electroluminescence devices was conducted using a brightness light distribution characteristics measurement system. In order to evaluate the properties of the organic electroluminescence devices according to the Examples and the Comparative examples, a driving voltage, emission efficiency, and life were measured. In Table 2, emission efficiency (%) at a current density of about 10 mA/cm² and a luminance of about 13,500 cd/m² for the organic electroluminescence devices thus manufactured are shown. Also, the device life, which is a time period required for decreasing the luminance from a reference value of 13,500 cd/m² to a 95% degree, is shown. The device life was measured by continuously driving the device at a current density of about 10 mA/cm². In addition, the luminance spectrum of the Examples and the Comparative Examples was measured by a spectroradiometer. From the spectrum thus measured, emission peak, which was the maximum emission wavelength, was measured.

TABLE 2

| Device | | | |
|---|---|---|---|
| manufacturing | Device | Emission | Driving |
| example | life (%) | efficiency (%) | voltage (V) |
| Example 1 | 120 | 110 | 4.7 |
| Example 2 | 112 | 105 | 4.5 |
| Example 3 | 100 | 103 | 4.8 |
| Example 4 | 109 | 108 | 4.5 |
| Example 5 | 121 | 101 | 4.4 |
| Example 6 | 115 | 100 | 4.4 |
| Example 7 | 106 | 112 | 4.3 |
| Example 8 | 107 | 115 | 4.5 |
| Example 9 | 111 | 103 | 4.6 |
| Example 10 | 112 | 105 | 4.7 |
| Example 11 | 109 | 109 | 4.7 |
| Example 12 | 119 | 120 | 4.8 |
| Comparative | 100 | 100 | 5.0 |
| Example 1 | | | |
| Comparative | 70 | 50 | 5.3 |
| Example 2 | | | |
| Comparative | 90 | 95 | 5.1 |
| Example 3 | | | |

Referring to the results of Table 2, it is believed that according to the combination of the first host, the second host, the first dopant and the second dopant according to embodiments, the device emission efficiency and device life were improved, and the low driving voltage was achieved. Referring to the results of Examples 1 to 12 and Comparative Examples 1 to 3, it could be found that the devices of Examples showed excellent emission efficiency and long-life characteristics. Referring to the results of Example 1 and Comparative Examples 1 and 2, Example 1 showed improved emission efficiency, device life and driving voltage when compared with Comparative Examples 1 and 2. Thus, it is believed that better device properties were shown for a device including a plurality of emission layers when compared with a device including only one emission layer. In the organic electroluminescence device 10 of an embodiment, including a plurality of emission layers, the deterioration of the device may be prevented or reduced by controlling the concentration of excitons in the first emission layer EML1, and the device life and efficiency may be improved due to the efficient emission of phosphorescence in the second emission layer EML2.

Referring to the results of Examples 1 to 12 and Comparative Example 3, it could be confirmed that the Examples showed better device properties including the emission efficiency, device life and driving voltage, when compared with the Comparative Example 3. Without being bound by any particular theory, it is believed that where the lowest triplet excitation energy level (T₁ level) of the first dopant is about 2.0 eV or less, the energy of excitons produced in the emission layers EML1 and EML2 moves to the lowest triplet excitation energy level (T₁ level) of the first dopant, and the concentration of the excitons emitting light may be substantially controlled, thereby improving both device life and driving voltage.

The organic electroluminescence device 10 of an embodiment includes the first emission layer EML1 and the second emission layer EML2 and may show excellent (e.g., improved) emission efficiency and improved life characteristics by combining the first host and the first dopant of the first emission layer EML1 and the second host and the second dopant of the second emission layer EML2. In addition, the organic electroluminescence device 10 of an embodiment includes the first dopant having the lowest triplet excitation energy level (T₁ level) of about 2.0 eV or less so as to substantially control the concentration of the excitons of the device, and thus achieve high emission efficiency and long-life characteristics.

The organic electroluminescence device of an embodiment includes two emission layers and may show high efficiency and long-life characteristics.

As used herein, the terms “use,” “using,” and “used” may be considered synonymous with the terms “utilize,” “utilizing,” and “utilized,” respectively.

In addition, the terms “substantially,” “about,” and similar terms are used as terms of approximation and not as terms of degree, and are intended to account for the inherent deviations in measured or calculated values that would be recognized by those of ordinary skill in the art.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

Although the example embodiments of the present disclosure have been described, it is understood that the present disclosure should not be limited to these example embodiments but various changes and modifications can be made by one ordinary skilled in the art within the spirit and scope of the present disclosure as hereinafter claimed by the following claims and their equivalents.

What is claimed is:

1. An organic electroluminescence device, comprising:
a first electrode;
a second electrode on the first electrode; and
a first emission layer and a second emission layer, both between the first electrode and the second electrode,
wherein the first emission layer comprises a first host and a first dopant, the first dopant comprising an anthracene-based compound,
the second emission layer comprises a second host represented by Formula H-1 and a second dopant, the second dopant being different from the first dopant and comprising an organometal compound, and
the first emission layer and the second emission layer are adjacent to each other: 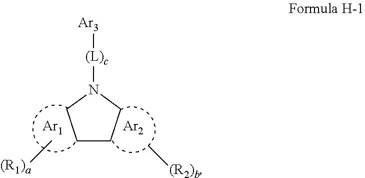
wherein, in Formula H-1,
Ar₁ to Ar₃ are each independently a substituted or unsubstituted aryl group of 6 to 60 carbon atoms for forming a ring, or a substituted or unsubstituted heteroaryl group of 2 to 60 carbon atoms for forming a ring,
L is a direct linkage, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring,
R₁ and R₂ are each independently a hydrogen atom, a deuterium atom, a substituted or unsubstituted silyl group, a substituted or unsubstituted phosphine oxide group, a substituted or unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring, and any of R₁ and R₂ are optionally combined with an adjacent group to form a ring, and
a to c are each independently an integer of 0 to 2.

2. The organic electroluminescence device of claim 1, wherein the second host is represented by Formula H-1a: 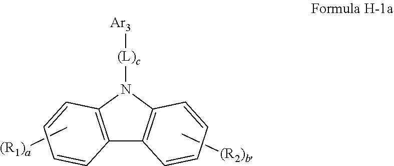
and
wherein, in Formula H-1a, Ar₃, R₁, R₂, L and a to c are the same as defined in Formula H-1.

3. The organic electroluminescence device of claim 1, wherein the first dopant is represented by Formula D-1: 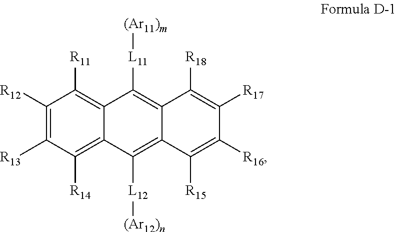
wherein, in Formula D-1,
R₁₁ to R₁₈ are each independently a hydrogen atom, a deuterium atom, a substituted or unsubstituted amine group, a substituted or unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring,
L₁₁ and L₁₂ are each independently a direct linkage, a substituted or unsubstituted amine group, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring,
Ar₁₁ and Ar₁₂ are each independently a substituted or unsubstituted alkenyl group of 2 to 30 carbon atoms, a substituted or unsubstituted silyl group, a substituted or unsubstituted selenium group, a substituted or unsubstituted amine group, a substituted or unsubstituted aryl group of 6 to 60 carbon atoms for forming a ring, or a substituted or unsubstituted heteroaryl group of 2 to 60 carbon atoms for forming a ring, and
m and n are each independently an integer of 0 to 3.

4. The organic electroluminescence device of claim 1, wherein the first dopant is represented by any one of Formulae D-1a, D-1b or D-1c: 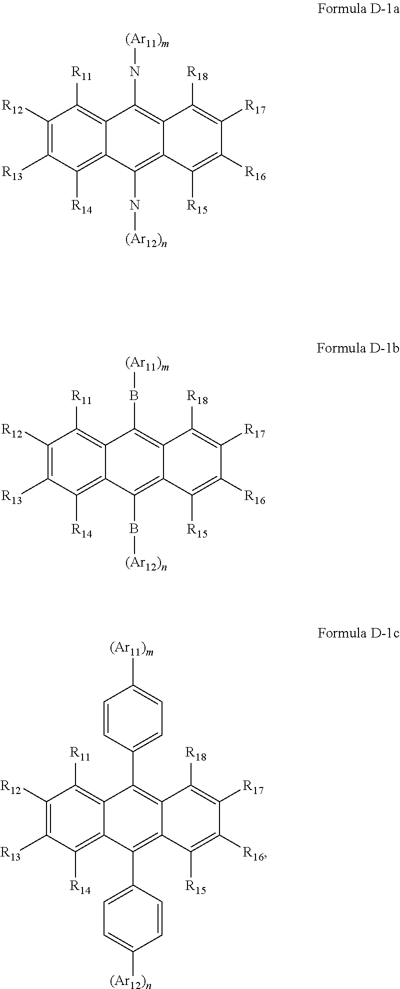
and
wherein, in Formulae D-1a, D-1b and D-1c, Ar₁₁, Ar₁₂, R₁₁ to R₁₈, m and n are the same as defined in Formula D-1.

5. The organic electroluminescence device of claim 1, wherein the second dopant comprises iridium (Ir), platinum (Pt), palladium (Pd), or gold (Au).

6. The organic electroluminescence device of claim 1, wherein a lowest triplet excitation energy level (T₁ level) of the first dopant is about 2.0 eV or less.

7. The organic electroluminescence device of claim 1, wherein a thickness of the first emission layer is from about 1 nm to about 10 nm.

8. The organic electroluminescence device of claim 1, wherein the second emission layer is between the first emission layer and the first electrode.

9. The organic electroluminescence device of claim 1, wherein the first emission layer contacts the second emission layer.

10. The organic electroluminescence device of claim 1, wherein the first dopant comprises at least one selected from compounds represented in Compound Group 1:

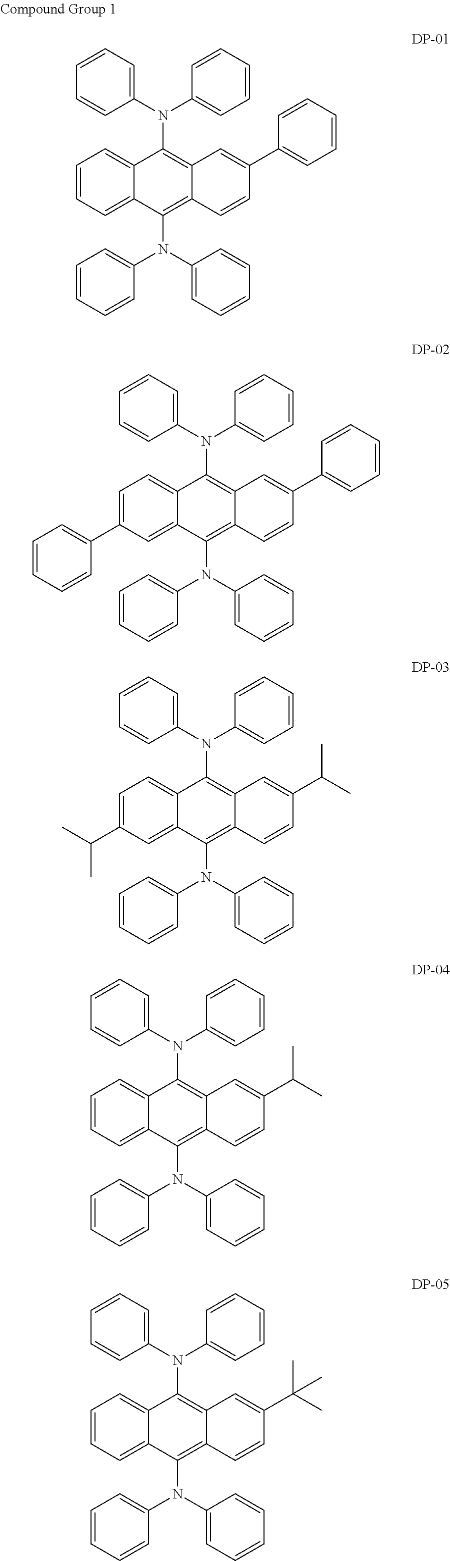

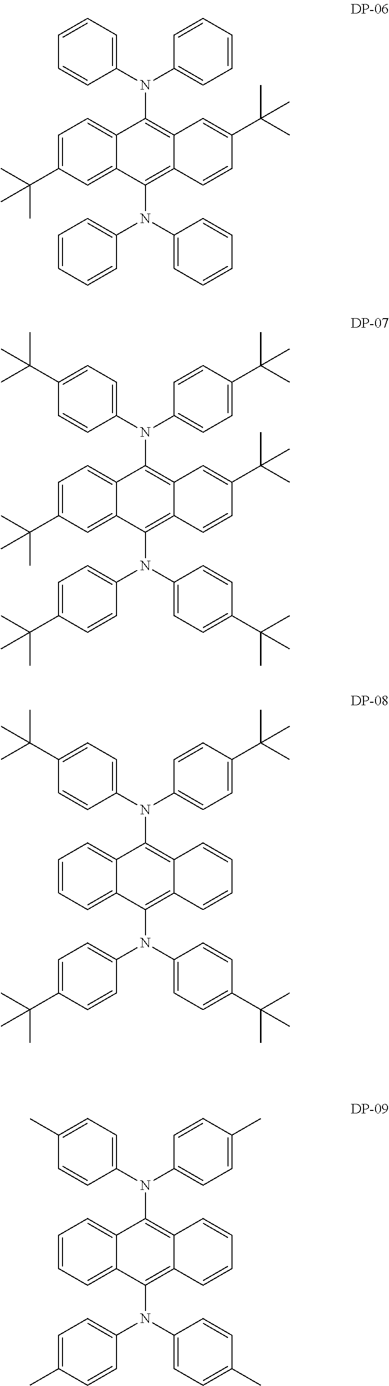

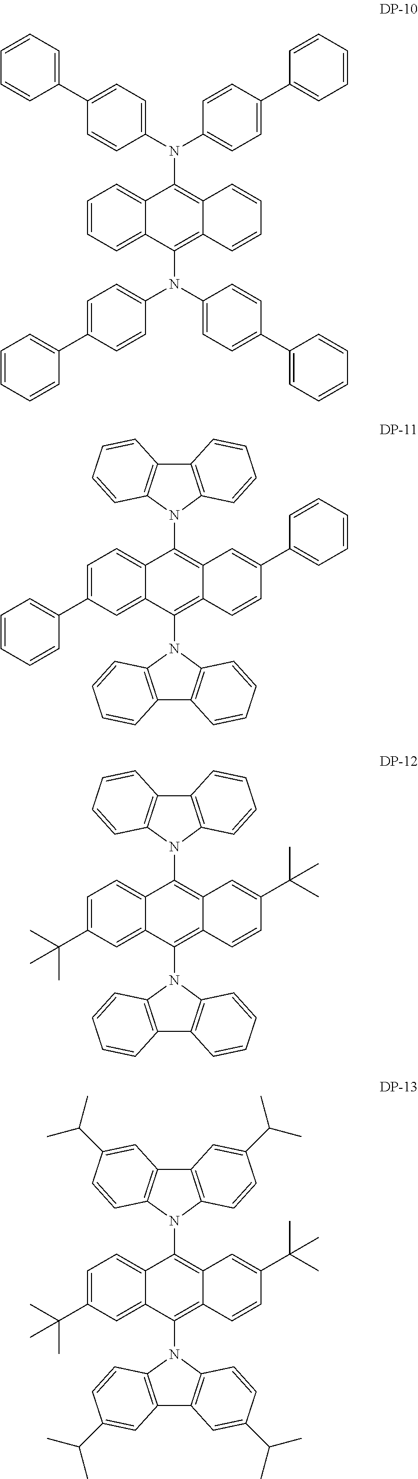

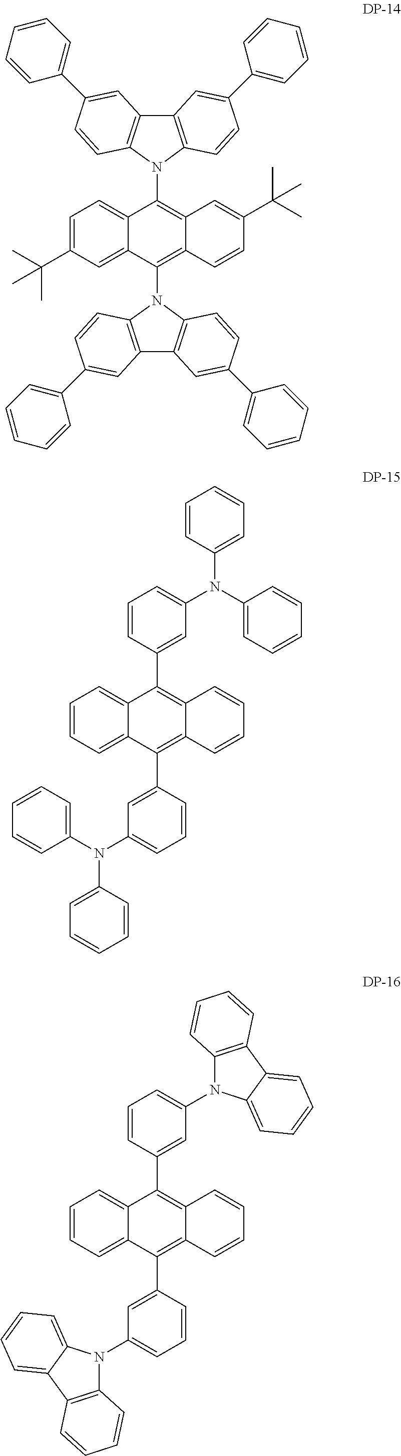 [SMILES: CC(C)(C)c1ccc2c(-n3c4ccc(-c5ccccc5)cc4c4cc(-c5ccccc5)ccc43)c3cc(C(C)(C)C)ccc3c(-n3c4ccc(-c5ccccc5)cc4c4cc(-c5ccccc5)ccc43)c2c1 ; c1ccc(N(c2ccccc2)c2cccc(-c3c4ccccc4c(-c4cccc(N(c5ccccc5)c5ccccc5)c4)c4ccccc34)c2)cc1 ; c1cc(-c2c3ccccc3c(-c3cccc(-n4c5ccccc5c5ccccc54)c3)c3ccccc23)cc(-n2c3ccccc3c3ccccc32)c1]

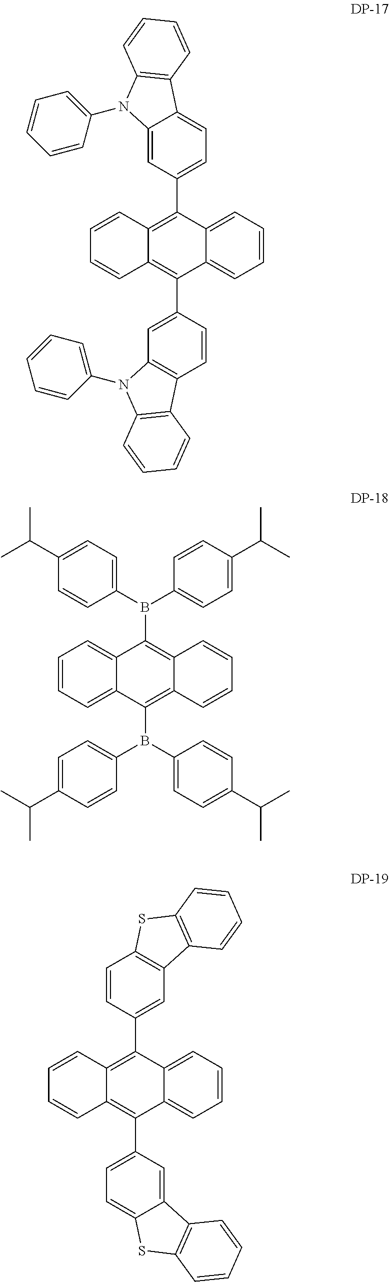 [SMILES: c1ccc(-n2c3ccccc3c3ccc(-c4c5ccccc5c(-c5ccc6c7ccccc7n(-c7ccccc7)c6c5)c5ccccc45)cc32)cc1 ; CC(C)c1ccc(B(c2ccc(C(C)C)cc2)c2c3ccccc3c(B(c3ccc(C(C)C)cc3)c3ccc(C(C)C)cc3)c3ccccc23)cc1 ; c1ccc2c(c1)sc1ccc(-c3c4ccccc4c(-c4ccc5sc6ccccc6c5c4)c4ccccc34)cc12]

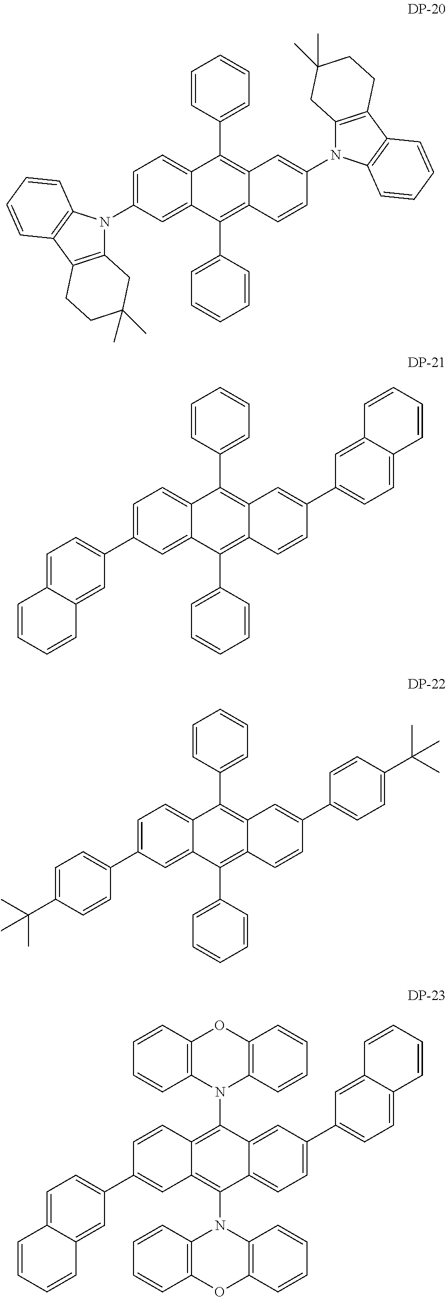

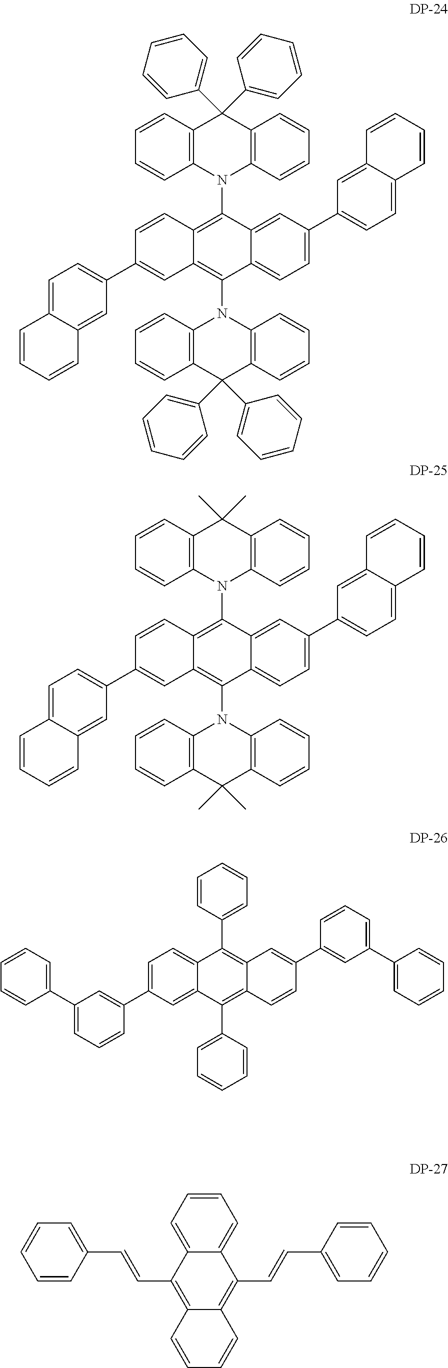

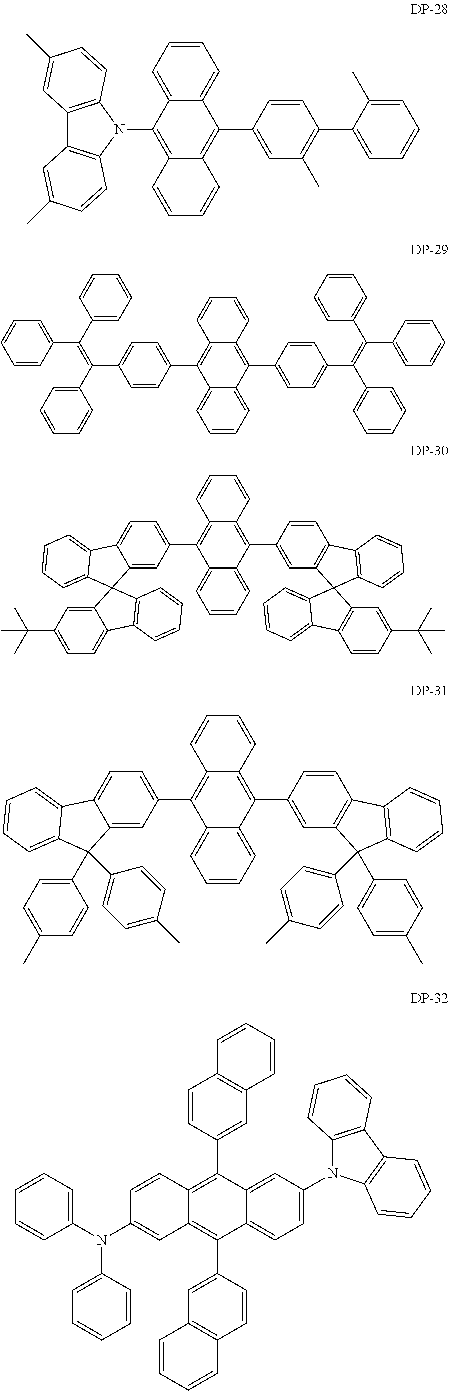

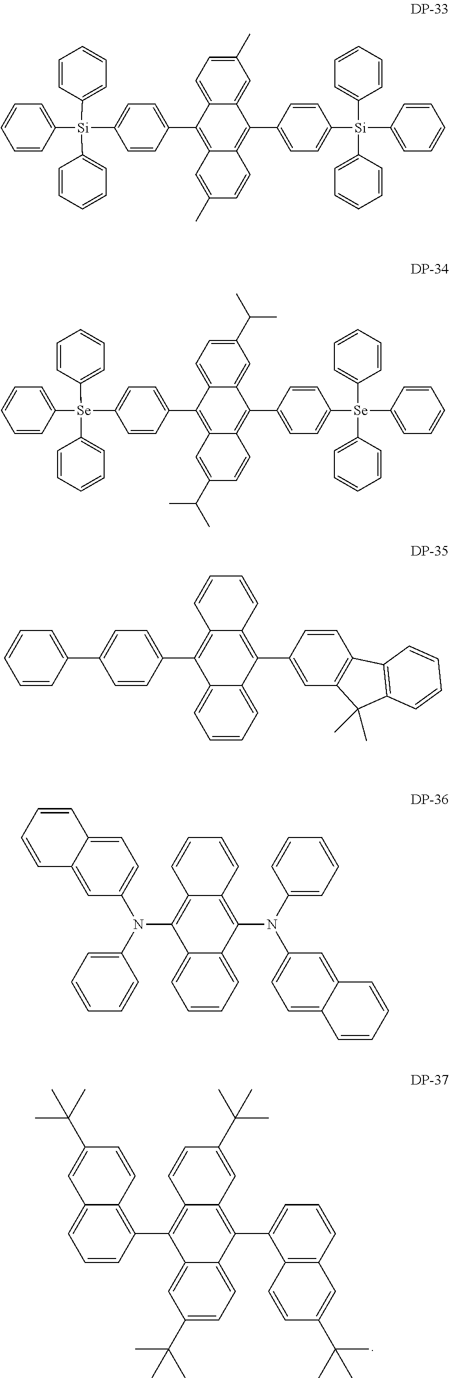

11. The organic electroluminescence device of claim 1, wherein the second host comprises at least one selected from compounds represented in Compound Group 2:

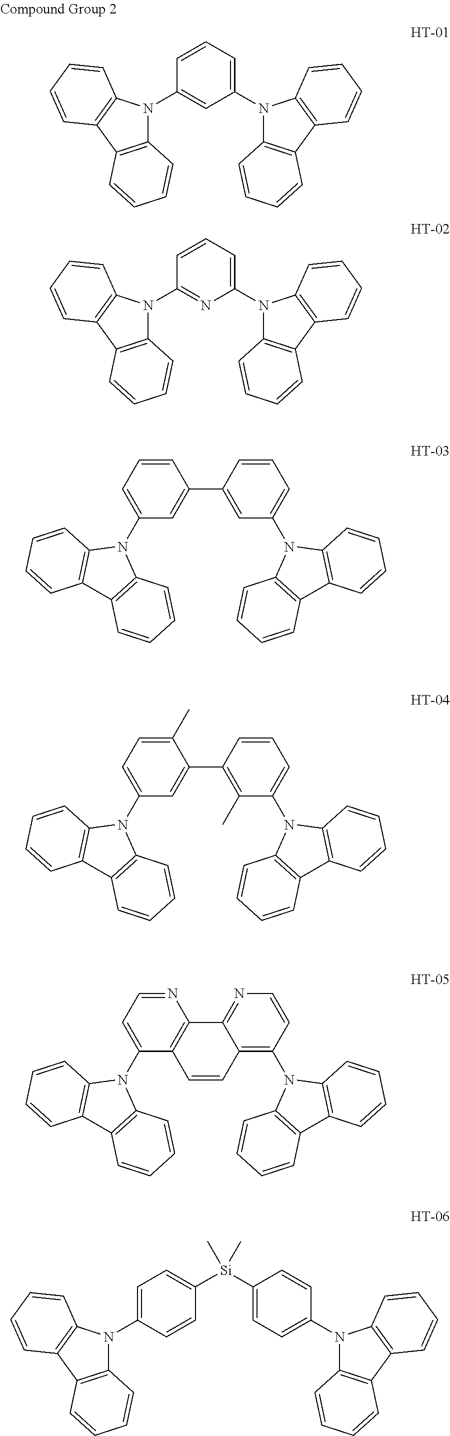 [SMILES: c1cc(-n2c3ccccc3c3ccccc32)cc(-n2c3ccccc3c3ccccc32)c1 ; c1cc(-n2c3ccccc3c3ccccc32)nc(-n2c3ccccc3c3ccccc32)c1 ; c1cc(-c2cccc(-n3c4ccccc4c4ccccc43)c2)cc(-n2c3ccccc3c3ccccc32)c1 ; Cc1ccc(-n2c3ccccc3c3ccccc32)cc1-c1cccc(-n2c3ccccc3c3ccccc32)c1C ; c1ccc2c(c1)c1ccccc1n2-c1ccnc2c1ccc1c(-n3c4ccccc4c4ccccc43)ccnc12 ; C[Si](C)(c1ccc(-n2c3ccccc3c3ccccc32)cc1)c1ccc(-n2c3ccccc3c3ccccc32)cc1]

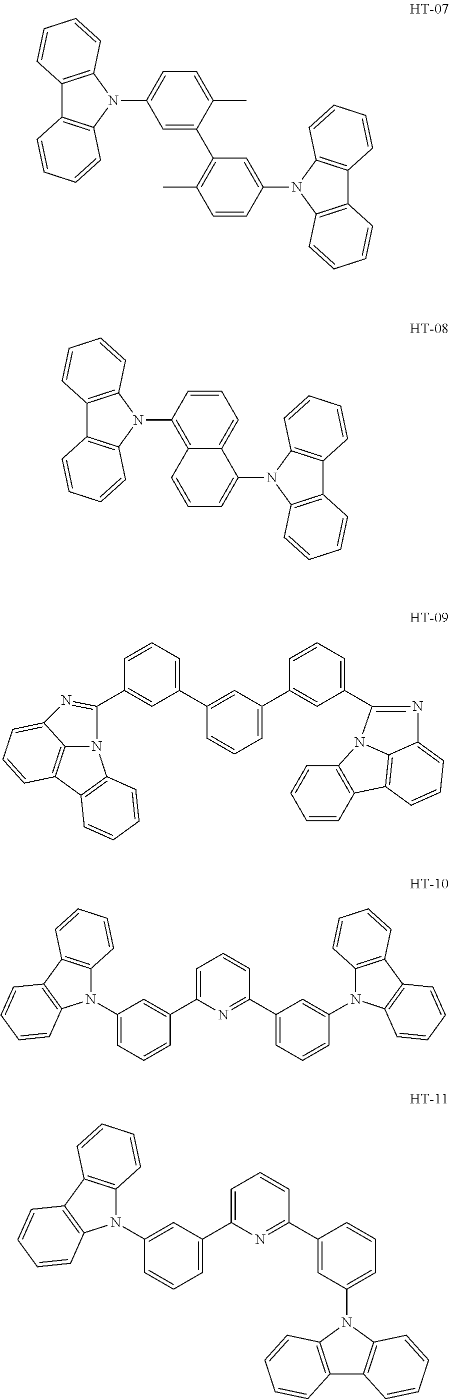 [SMILES: Cc1ccc(-n2c3ccccc3c3ccccc32)cc1-c1cc(-n2c3ccccc3c3ccccc32)ccc1C ; c1cc(-n2c3ccccc3c3ccccc32)c2cccc(-n3c4ccccc4c4ccccc43)c2c1 ; c1cc(-c2cccc(-c3nc4cccc5c6ccccc6n3c45)c2)cc(-c2cccc(-c3nc4cccc5c6ccccc6n3c45)c2)c1 ; c1cc(-c2cccc(-c3cccc(-n4c5ccccc5c5ccccc54)c3)n2)cc(-n2c3ccccc3c3ccccc32)c1 ; c1cc(-c2cccc(-c3cccc(-n4c5ccccc5c5ccccc54)c3)n2)cc(-n2c3ccccc3c3ccccc32)c1]

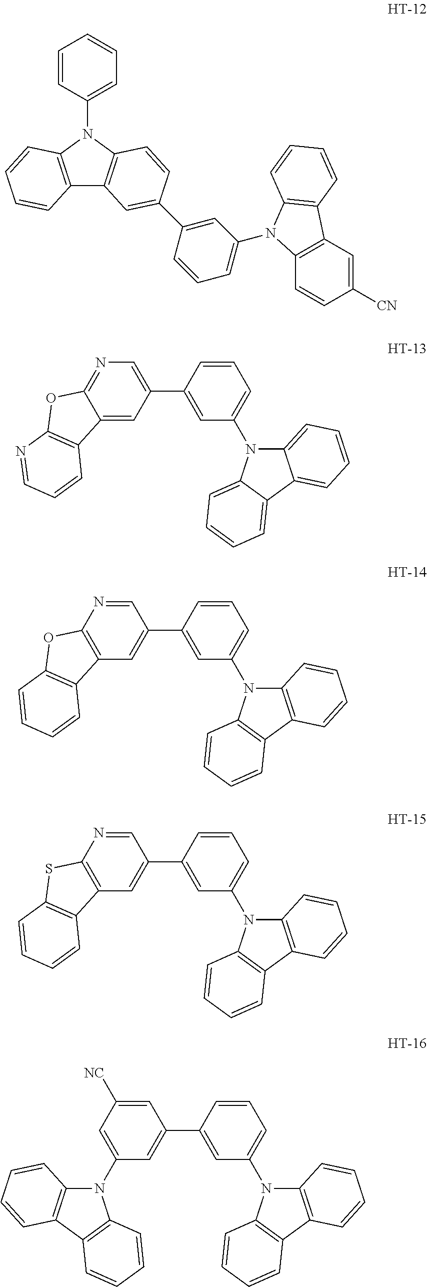 [SMILES: N#Cc1ccc2c(c1)c1ccccc1n2-c1cccc(-c2ccc3c(c2)c2ccccc2n3-c2ccccc2)c1 ; c1cc(-c2cnc3oc4ncccc4c3c2)cc(-n2c3ccccc3c3ccccc32)c1 ; c1cc(-c2cnc3oc4ccccc4c3c2)cc(-n2c3ccccc3c3ccccc32)c1 ; c1cc(-c2cnc3sc4ccccc4c3c2)cc(-n2c3ccccc3c3ccccc32)c1 ; N#Cc1cc(-c2cccc(-n3c4ccccc4c4ccccc43)c2)cc(-n2c3ccccc3c3ccccc32)c1]

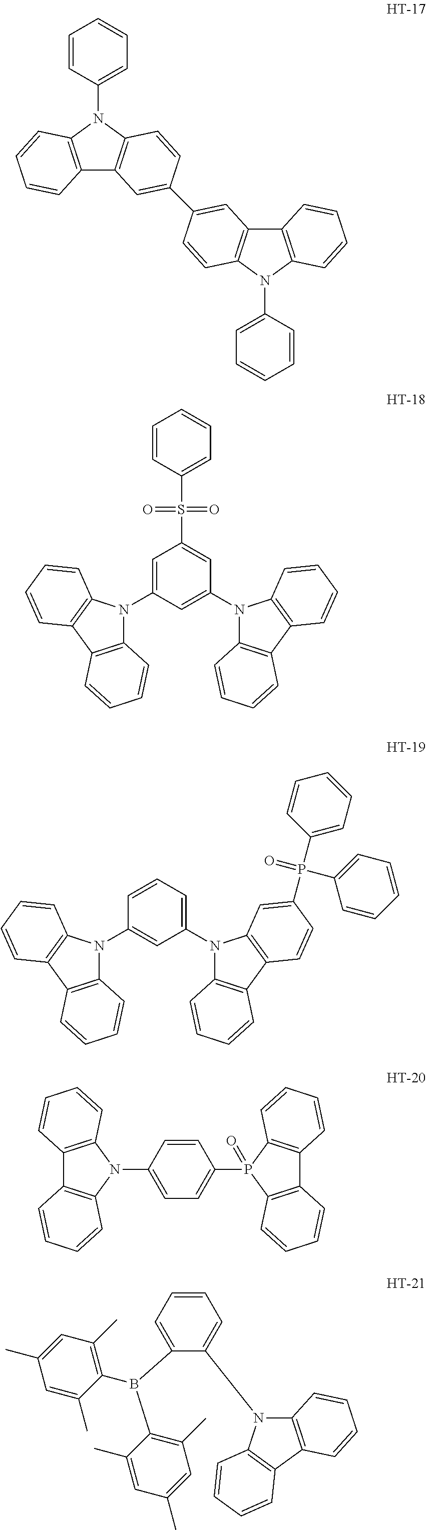

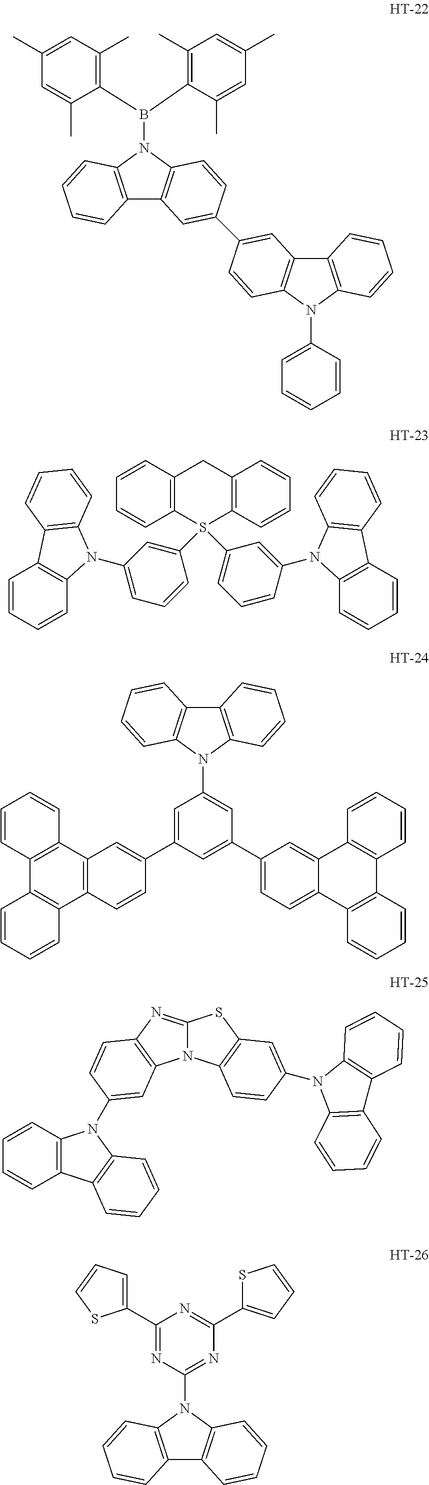 [SMILES: Cc1cc(C)c(B(c2c(C)cc(C)cc2C)n2c3ccccc3c3cc(-c4ccc5c(c4)c4ccccc4n5-c4ccccc4)ccc32)c(C)c1 ; c1cc(-n2c3ccccc3c3ccccc32)cc(S2(c3cccc(-n4c5ccccc5c5ccccc54)c3)c3ccccc3Cc3ccccc32)c1 ; c1ccc2c(c1)c1ccccc1c1cc(-c3cc(-c4ccc5c6ccccc6c6ccccc6c5c4)cc(-n4c5ccccc5c5ccccc54)c3)ccc21 ; c1ccc2c(c1)c1ccccc1n2-c1ccc2c(c1)sc1nc3ccc(-n4c5ccccc5c5ccccc54)cc3n12 ; c1csc(-c2nc(-c3cccs3)nc(-n3c4ccccc4c4ccccc43)n2)c1]

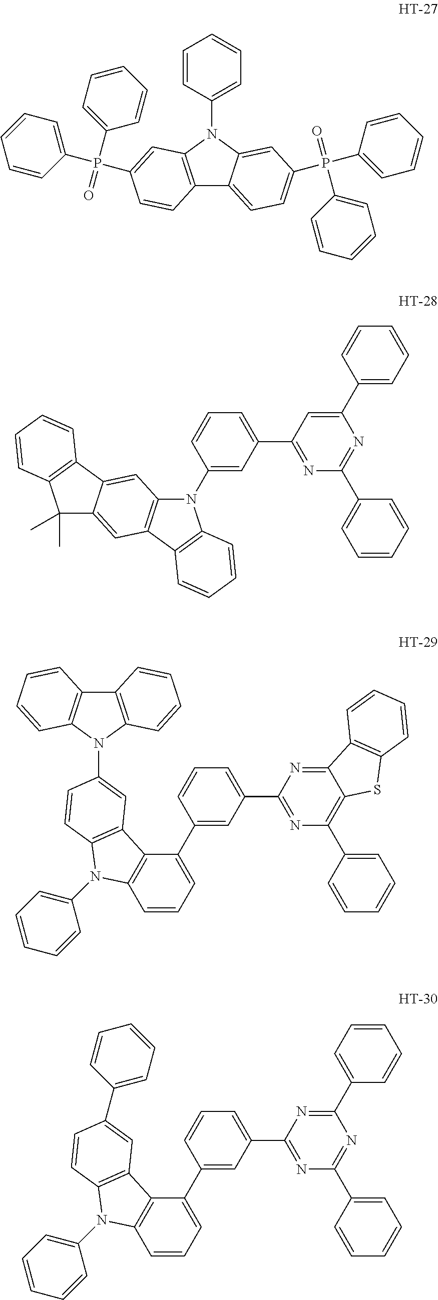 [SMILES: O=P(c1ccccc1)(c1ccccc1)c1ccc2c3ccc(P(=O)(c4ccccc4)c4ccccc4)cc3n(-c3ccccc3)c2c1 ; CC1(C)c2ccccc2-c2cc3c(cc21)c1ccccc1n3-c1cccc(-c2cc(-c3ccccc3)nc(-c3ccccc3)n2)c1 ; c1ccc(-c2nc(-c3cccc(-c4cccc5c4c4cc(-n6c7ccccc7c7ccccc76)ccc4n5-c4ccccc4)c3)nc3c2sc2ccccc23)cc1 ; c1ccc(-c2ccc3c(c2)c2c(-c4cccc(-c5nc(-c6ccccc6)nc(-c6ccccc6)n5)c4)cccc2n3-c2ccccc2)cc1]

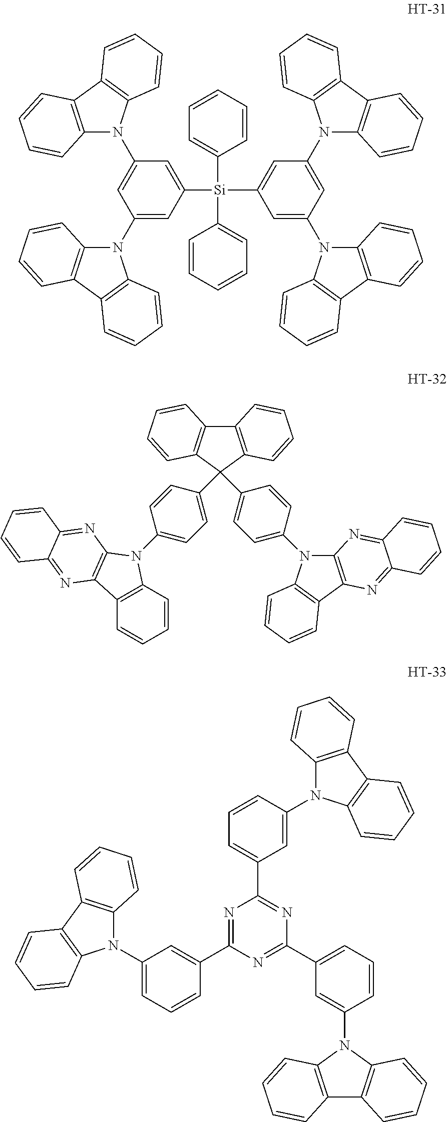 [SMILES: c1ccc([Si](c2ccccc2)(c2cc(-n3c4ccccc4c4ccccc43)cc(-n3c4ccccc4c4ccccc43)c2)c2cc(-n3c4ccccc4c4ccccc43)cc(-n3c4ccccc4c4ccccc43)c2)cc1 ; c1ccc2c(c1)-c1ccccc1C2(c1ccc(-n2c3ccccc3c3nc4ccccc4nc32)cc1)c1ccc(-n2c3ccccc3c3nc4ccccc4nc32)cc1 ; c1cc(-c2nc(-c3cccc(-n4c5ccccc5c5ccccc54)c3)nc(-c3cccc(-n4c5ccccc5c5ccccc54)c3)n2)cc(-n2c3ccccc3c3ccccc32)c1]

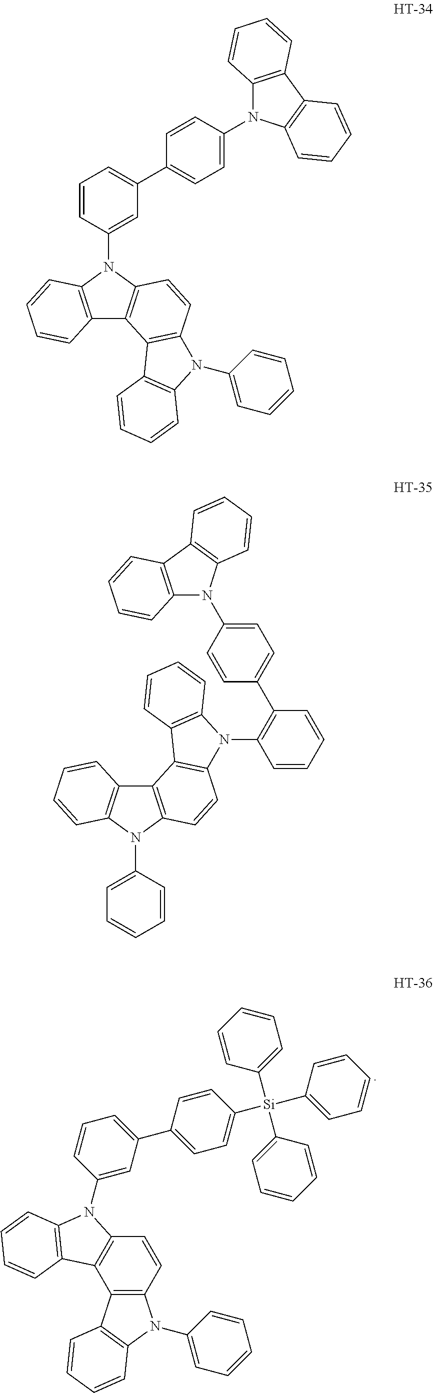 [SMILES: c1ccc(-n2c3ccccc3c3c4c5ccccc5n(-c5cccc(-c6ccc(-n7c8ccccc8c8ccccc87)cc6)c5)c4ccc32)cc1 ; c1ccc(-n2c3ccccc3c3c4c5ccccc5n(-c5ccccc5-c5ccc(-n6c7ccccc7c7ccccc76)cc5)c4ccc32)cc1 ; c1ccc(-n2c3ccccc3c3c4c5ccccc5n(-c5cccc(-c6ccc([Si](c7ccccc7)(c7ccccc7)c7ccccc7)cc6)c5)c4ccc32)cc1]

12. An organic electroluminescence device, comprising:
a first electrode;
a second electrode on the first electrode; and
a first emission layer and a second emission layer, both between the first electrode and the second electrode,
wherein the first emission layer comprises a first host and a first dopant represented by Formula D-1, and
the second emission layer comprises a second host represented by Formula H-1 and a second dopant that is different from the first dopant: 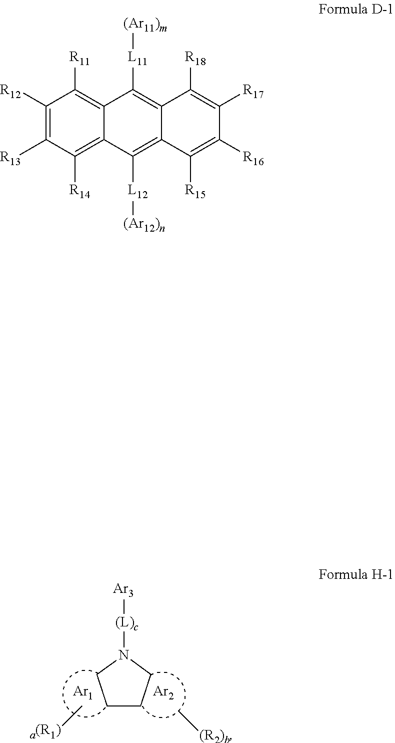
wherein, in Formula D-1,
R₁₁ to R₁₈ are each independently a hydrogen atom, a deuterium atom, a substituted or unsubstituted amine group, a substituted or unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring,
L₁₁ and L₁₂ are each independently a direct linkage, a substituted or unsubstituted amine group, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring,
Ar₁₁ and Ar₁₂ are each independently a substituted or unsubstituted alkenyl group of 2 to 30 carbon atoms, a substituted or unsubstituted silyl group, a substituted or unsubstituted selenium group, a substituted or unsubstituted amine group, a substituted or unsubstituted aryl group of 6 to 60 carbon atoms for forming a ring, or a substituted or unsubstituted heteroaryl group of 2 to 60 carbon atoms for forming a ring, and
m and n are each independently an integer of 0 to 3, and
in Formula H-1,
Ar₁ to Ar₃ are each independently a substituted or unsubstituted aryl group of 6 to 30 carbon atoms for forming a ring, or a substituted or unsubstituted heteroaryl group of 2 to 60 carbon atoms for forming a ring,
L is a direct linkage, a substituted or unsubstituted silyl group, a substituted or unsubstituted boryl group, a substituted or unsubstituted alkylene group of 1 to 30 carbon atoms, a substituted or unsubstituted arylene group of 6 to 60 carbon atoms for forming a ring, or a substituted or unsubstituted heteroarylene group of 2 to 60 carbon atoms for forming a ring,
R₁ and R₂ are each independently a hydrogen atom, a deuterium atom, a substituted or unsubstituted silyl group, a substituted or unsubstituted phosphine oxide group, a substituted or unsubstituted alkyl group of 1 to 30 carbon atoms, a substituted or unsubstituted aryl group of 6 to 60 carbon atoms for forming a ring, or a substituted or unsubstituted heteroaryl group of 2 to 60 carbon atoms for forming a ring, and any of R₁ and R₂ are optionally combined with an adjacent group to form a ring, and
a to c are each independently an integer of 0 to 2.

13. The organic electroluminescence device of claim 12, wherein the first dopant is represented by any one of Formulae D-1a, D-1b or D-1c: 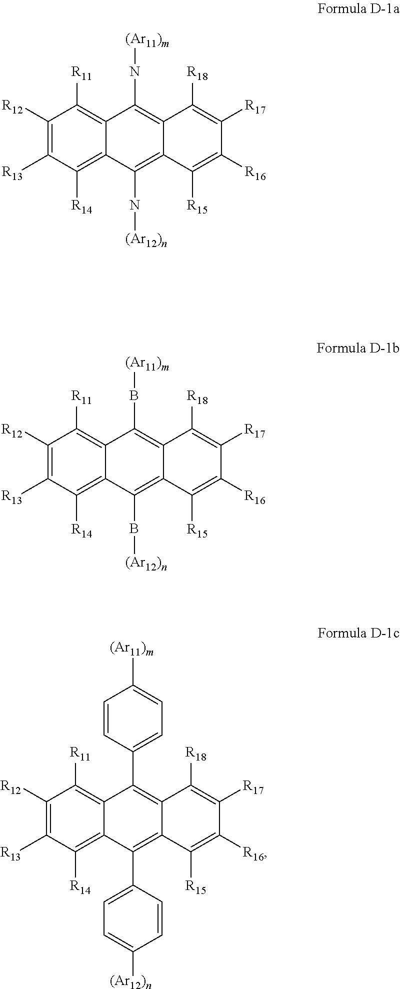
and
wherein, in Formulae D-1a, D-1b and D-1c, Ar₁₁, Ar₁₂, R₁₁ to R₁₈, m and n are the same as defined in Formula D-1.

14. The organic electroluminescence device of claim 12, wherein the second host is represented by Formula H-1a: 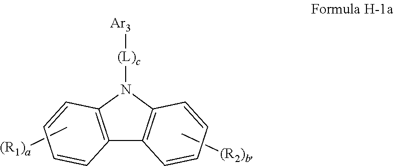
and
wherein, in Formula H-1a, Ar₃, R₁, R₂, L and a to c are the same as defined in Formula H-1.

15. The organic electroluminescence device of claim 12, wherein the second dopant comprises iridium (Ir), platinum (Pt), palladium (Pd), or gold (Au).

16. The organic electroluminescence device of claim 12, wherein a lowest triplet excitation energy level (T₁ level) of the first dopant is about 2.0 eV or less.

17. The organic electroluminescence device of claim 12, wherein a thickness of the first emission layer is from about 1 nm to about 10 nm.

18. The organic electroluminescence device of claim 12, wherein the second emission layer is between the first emission layer and the first electrode.

19. The organic electroluminescence device of claim 12, wherein the first dopant comprises at least one selected from compounds represented in Compound Group 1:

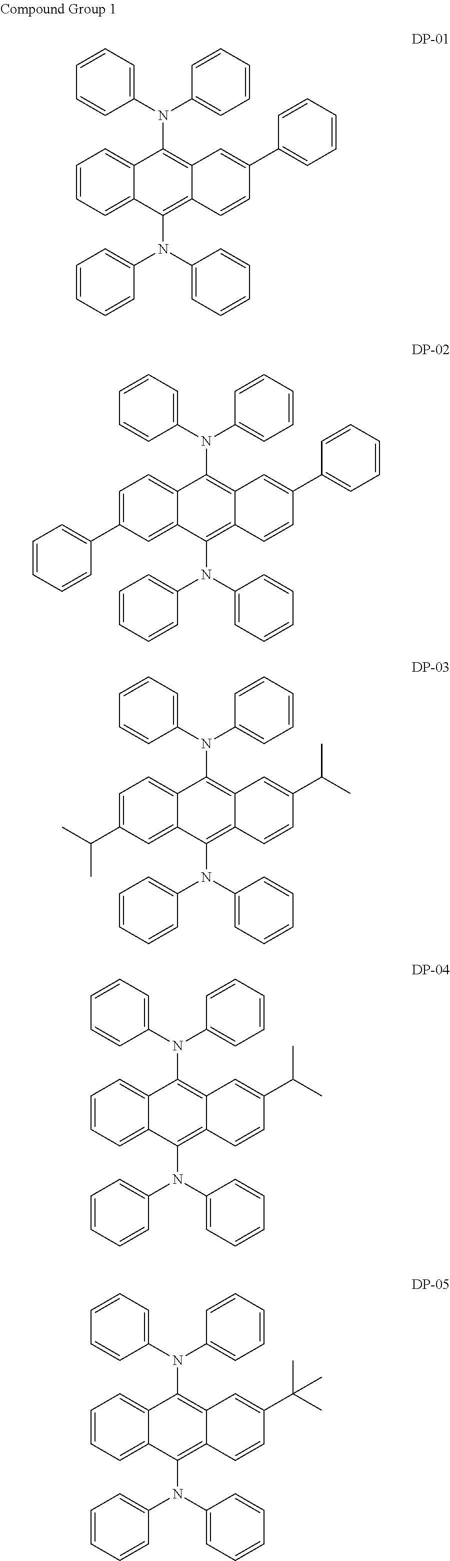

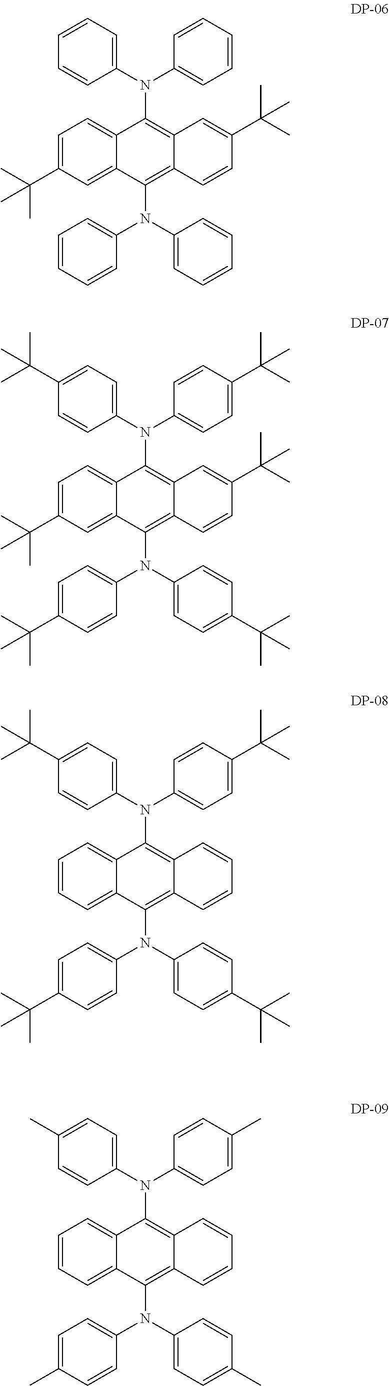

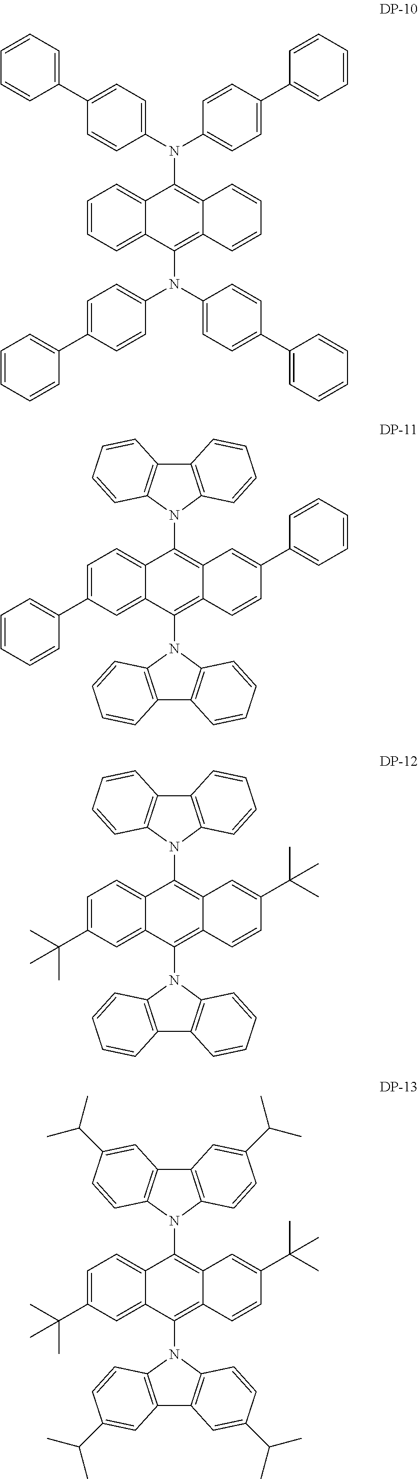

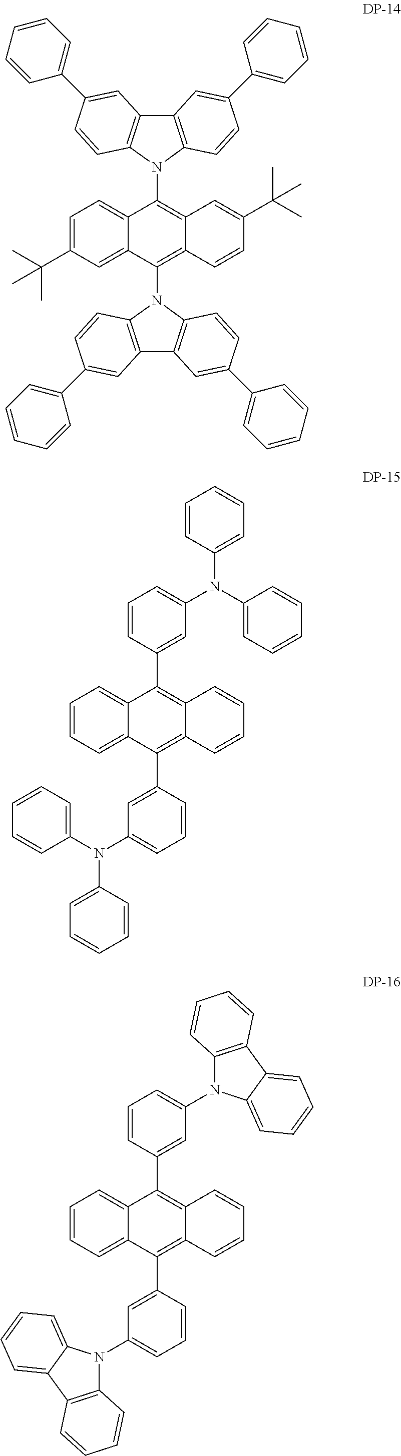 [SMILES: CC(C)(C)c1ccc2c(-n3c4ccc(-c5ccccc5)cc4c4cc(-c5ccccc5)ccc43)c3cc(C(C)(C)C)ccc3c(-n3c4ccc(-c5ccccc5)cc4c4cc(-c5ccccc5)ccc43)c2c1 ; c1ccc(N(c2ccccc2)c2cccc(-c3c4ccccc4c(-c4cccc(N(c5ccccc5)c5ccccc5)c4)c4ccccc34)c2)cc1 ; c1cc(-c2c3ccccc3c(-c3cccc(-n4c5ccccc5c5ccccc54)c3)c3ccccc23)cc(-n2c3ccccc3c3ccccc32)c1]

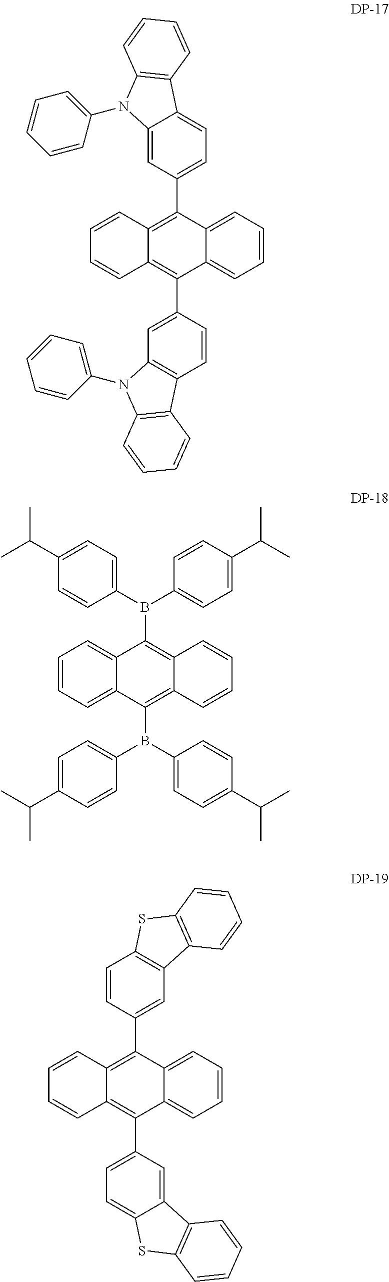 [SMILES: c1ccc(-n2c3ccccc3c3ccc(-c4c5ccccc5c(-c5ccc6c7ccccc7n(-c7ccccc7)c6c5)c5ccccc45)cc32)cc1 ; CC(C)c1ccc(B(c2ccc(C(C)C)cc2)c2c3ccccc3c(B(c3ccc(C(C)C)cc3)c3ccc(C(C)C)cc3)c3ccccc23)cc1 ; c1ccc2c(c1)sc1ccc(-c3c4ccccc4c(-c4ccc5sc6ccccc6c5c4)c4ccccc34)cc12]

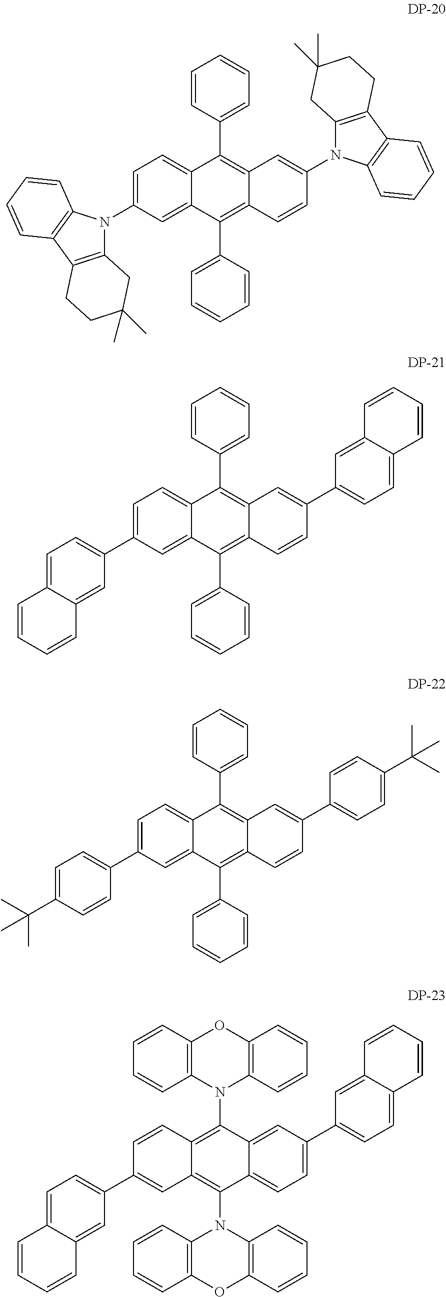

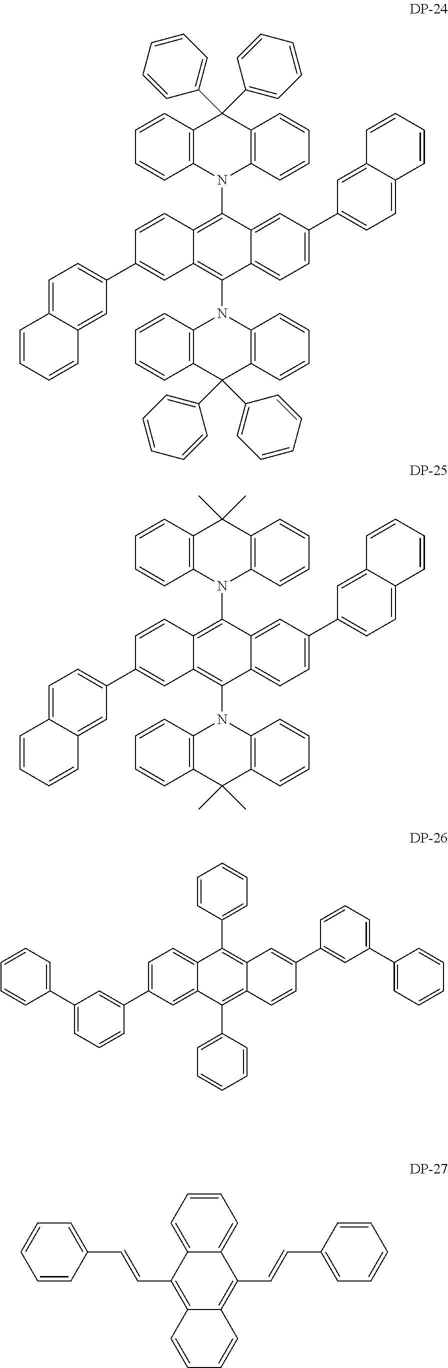

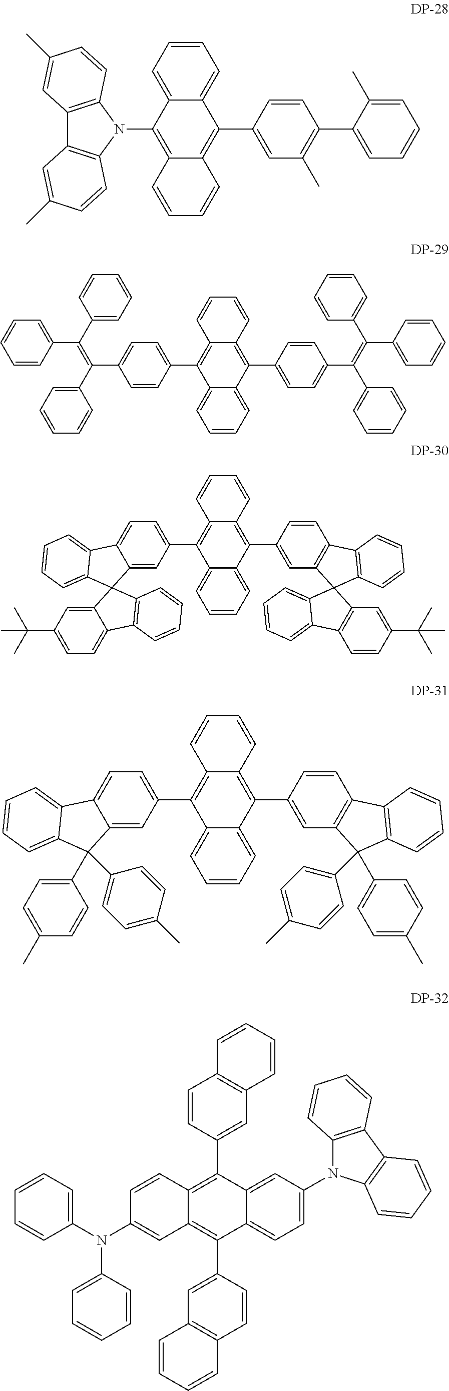

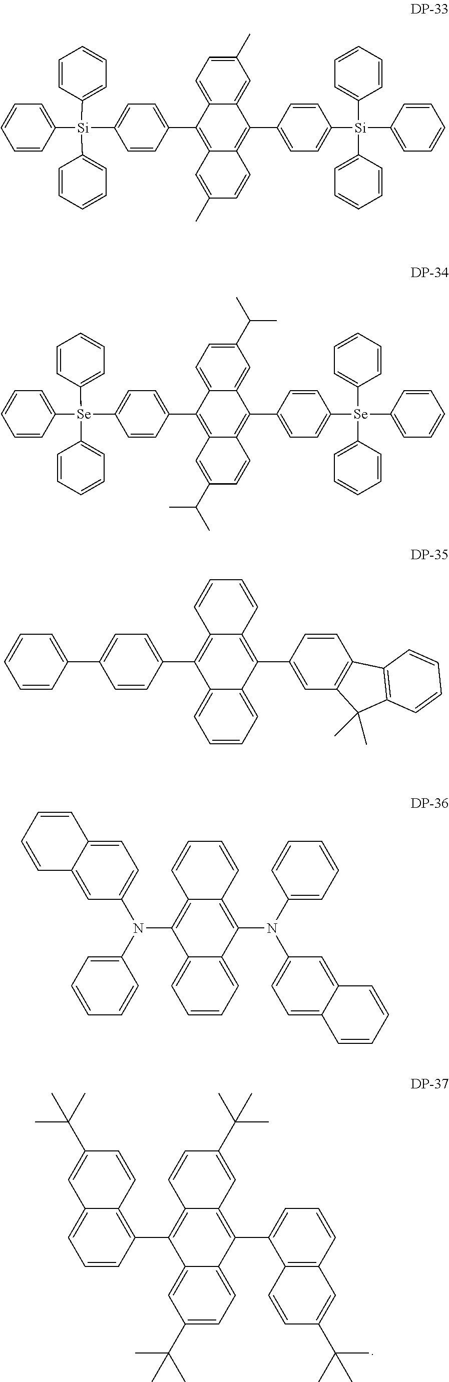

20. The organic electroluminescence device of claim 12, wherein the second host comprises at least one selected from compounds represented in Compound Group 2: 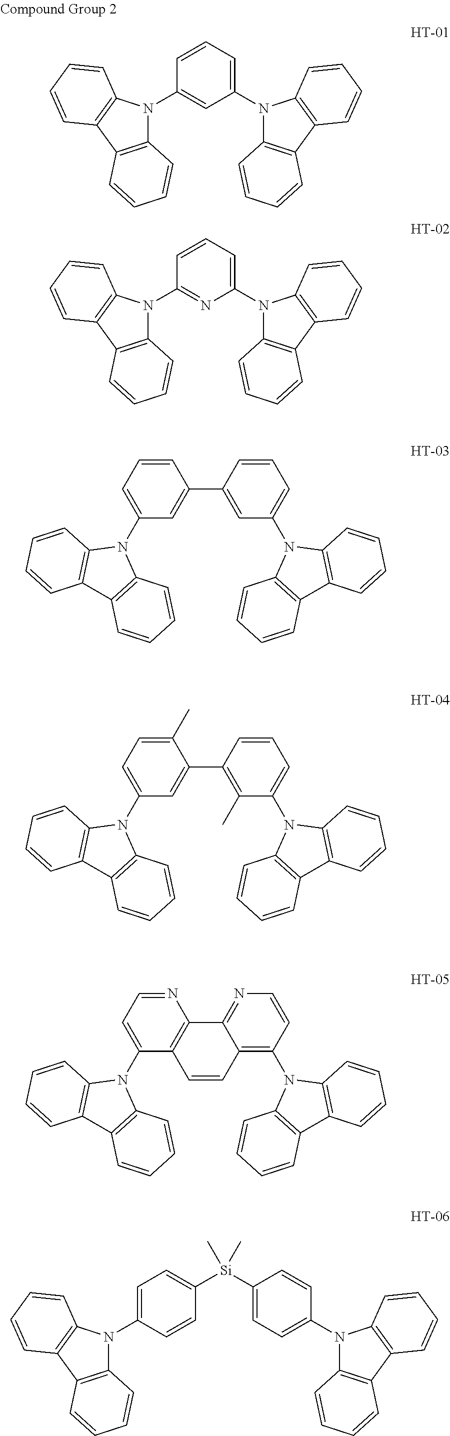 [SMILES: c1cc(-n2c3ccccc3c3ccccc32)cc(-n2c3ccccc3c3ccccc32)c1 ; c1cc(-n2c3ccccc3c3ccccc32)nc(-n2c3ccccc3c3ccccc32)c1 ; c1cc(-c2cccc(-n3c4ccccc4c4ccccc43)c2)cc(-n2c3ccccc3c3ccccc32)c1 ; Cc1ccc(-n2c3ccccc3c3ccccc32)cc1-c1cccc(-n2c3ccccc3c3ccccc32)c1C ; c1ccc2c(c1)c1ccccc1n2-c1ccnc2c1ccc1c(-n3c4ccccc4c4ccccc43)ccnc12 ; C[Si](C)(c1ccc(-n2c3ccccc3c3ccccc32)cc1)c1ccc(-n2c3ccccc3c3ccccc32)cc1] 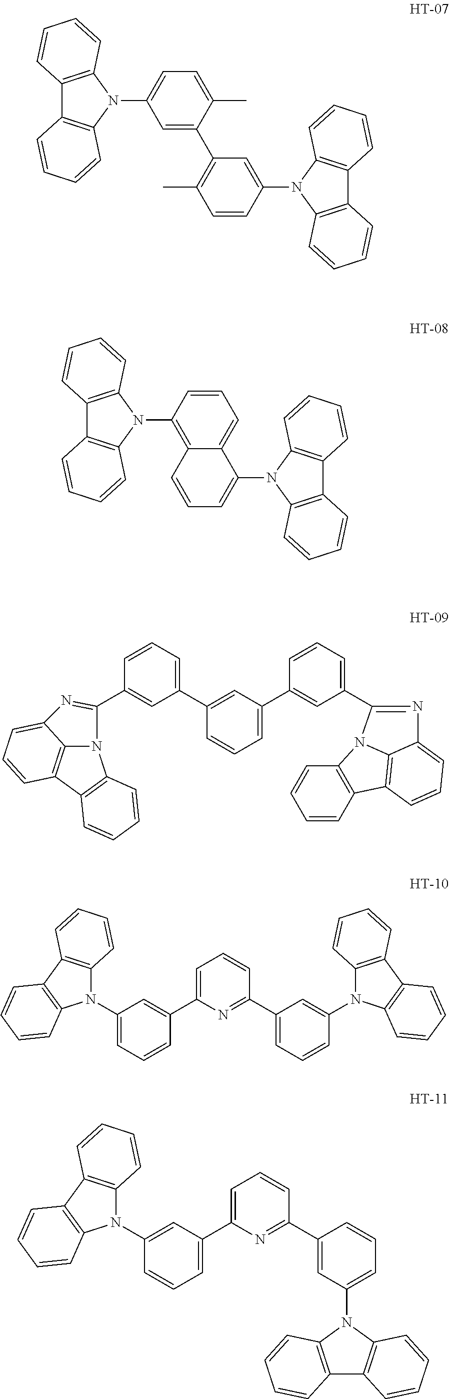 [SMILES: Cc1ccc(-n2c3ccccc3c3ccccc32)cc1-c1cc(-n2c3ccccc3c3ccccc32)ccc1C ; c1cc(-n2c3ccccc3c3ccccc32)c2cccc(-n3c4ccccc4c4ccccc43)c2c1 ; c1cc(-c2cccc(-c3nc4cccc5c6ccccc6n3c45)c2)cc(-c2cccc(-c3nc4cccc5c6ccccc6n3c45)c2)c1 ; c1cc(-c2cccc(-c3cccc(-n4c5ccccc5c5ccccc54)c3)n2)cc(-n2c3ccccc3c3ccccc32)c1 ; c1cc(-c2cccc(-c3cccc(-n4c5ccccc5c5ccccc54)c3)n2)cc(-n2c3ccccc3c3ccccc32)c1] 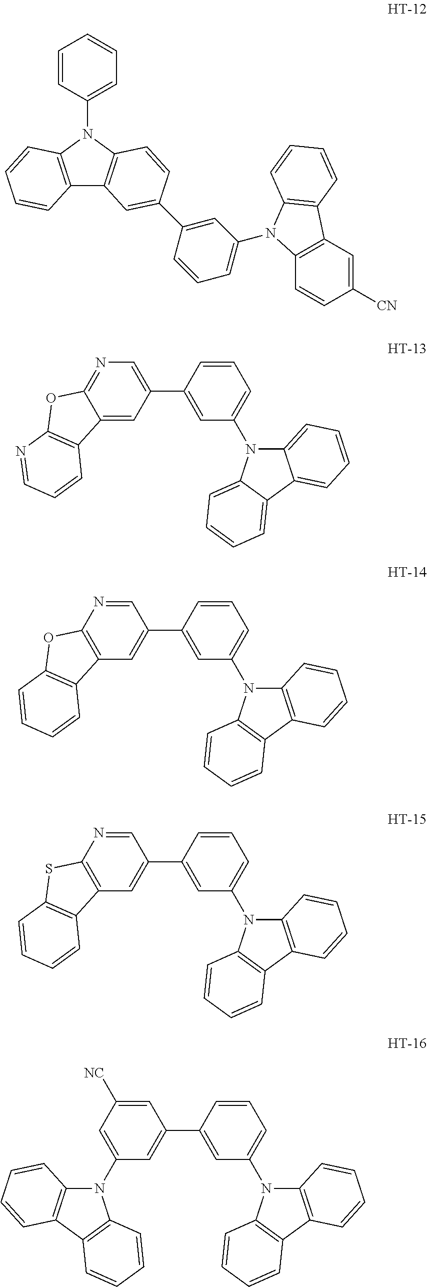 [SMILES: N#Cc1ccc2c(c1)c1ccccc1n2-c1cccc(-c2ccc3c(c2)c2ccccc2n3-c2ccccc2)c1 ; c1cc(-c2cnc3oc4ncccc4c3c2)cc(-n2c3ccccc3c3ccccc32)c1 ; c1cc(-c2cnc3oc4ccccc4c3c2)cc(-n2c3ccccc3c3ccccc32)c1 ; c1cc(-c2cnc3sc4ccccc4c3c2)cc(-n2c3ccccc3c3ccccc32)c1 ; N#Cc1cc(-c2cccc(-n3c4ccccc4c4ccccc43)c2)cc(-n2c3ccccc3c3ccccc32)c1] 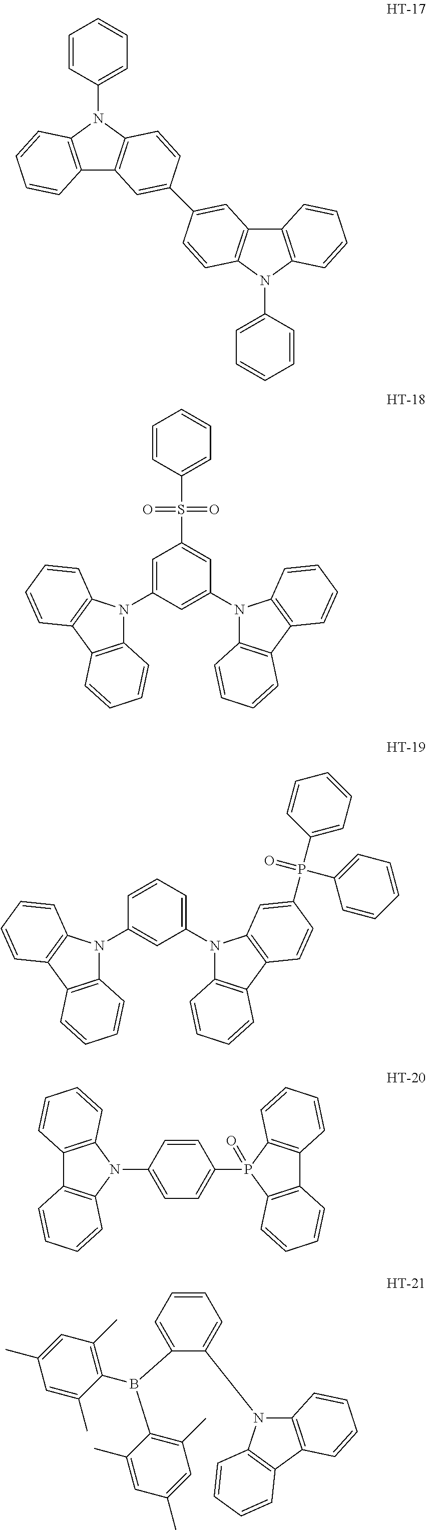 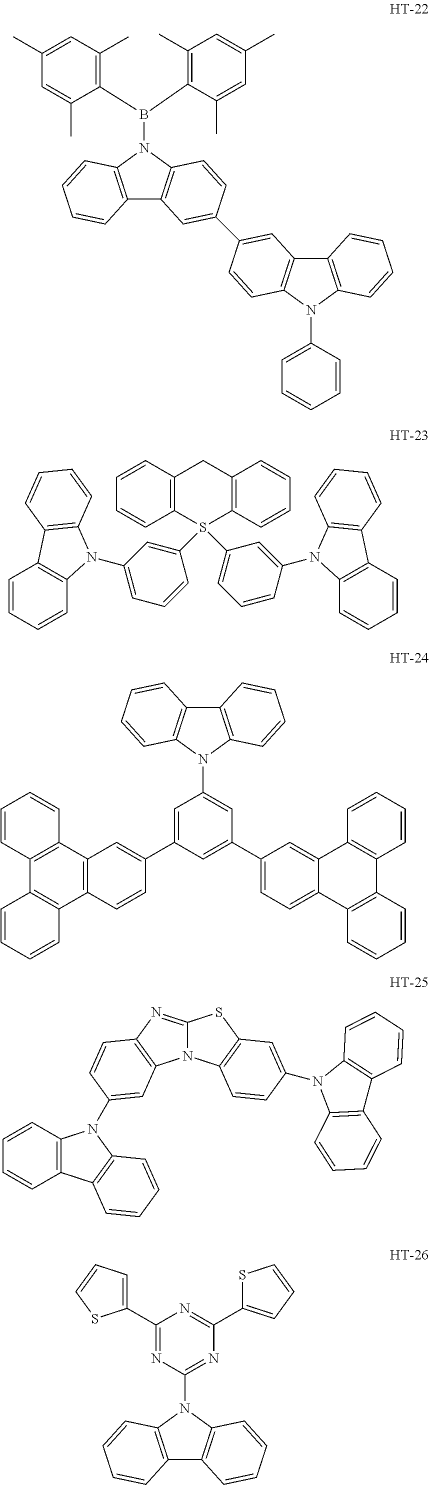 [SMILES: Cc1cc(C)c(B(c2c(C)cc(C)cc2C)n2c3ccccc3c3cc(-c4ccc5c(c4)c4ccccc4n5-c4ccccc4)ccc32)c(C)c1 ; c1cc(-n2c3ccccc3c3ccccc32)cc(S2(c3cccc(-n4c5ccccc5c5ccccc54)c3)c3ccccc3Cc3ccccc32)c1 ; c1ccc2c(c1)c1ccccc1c1cc(-c3cc(-c4ccc5c6ccccc6c6ccccc6c5c4)cc(-n4c5ccccc5c5ccccc54)c3)ccc21 ; c1ccc2c(c1)c1ccccc1n2-c1ccc2c(c1)sc1nc3ccc(-n4c5ccccc5c5ccccc54)cc3n12 ; c1csc(-c2nc(-c3cccs3)nc(-n3c4ccccc4c4ccccc43)n2)c1] 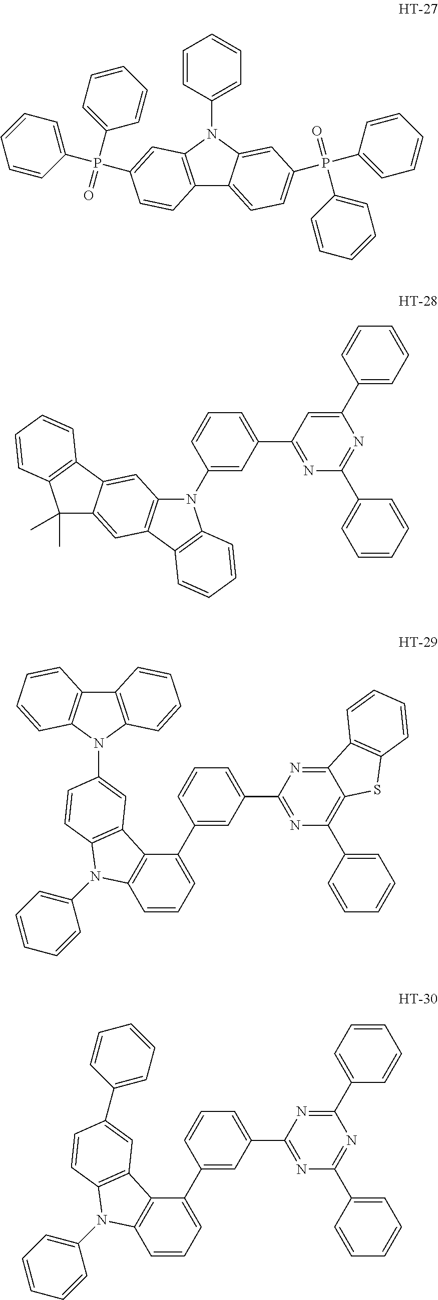 [SMILES: O=P(c1ccccc1)(c1ccccc1)c1ccc2c3ccc(P(=O)(c4ccccc4)c4ccccc4)cc3n(-c3ccccc3)c2c1 ; CC1(C)c2ccccc2-c2cc3c(cc21)c1ccccc1n3-c1cccc(-c2cc(-c3ccccc3)nc(-c3ccccc3)n2)c1 ; c1ccc(-c2nc(-c3cccc(-c4cccc5c4c4cc(-n6c7ccccc7c7ccccc76)ccc4n5-c4ccccc4)c3)nc3c2sc2ccccc23)cc1 ; c1ccc(-c2ccc3c(c2)c2c(-c4cccc(-c5nc(-c6ccccc6)nc(-c6ccccc6)n5)c4)cccc2n3-c2ccccc2)cc1] 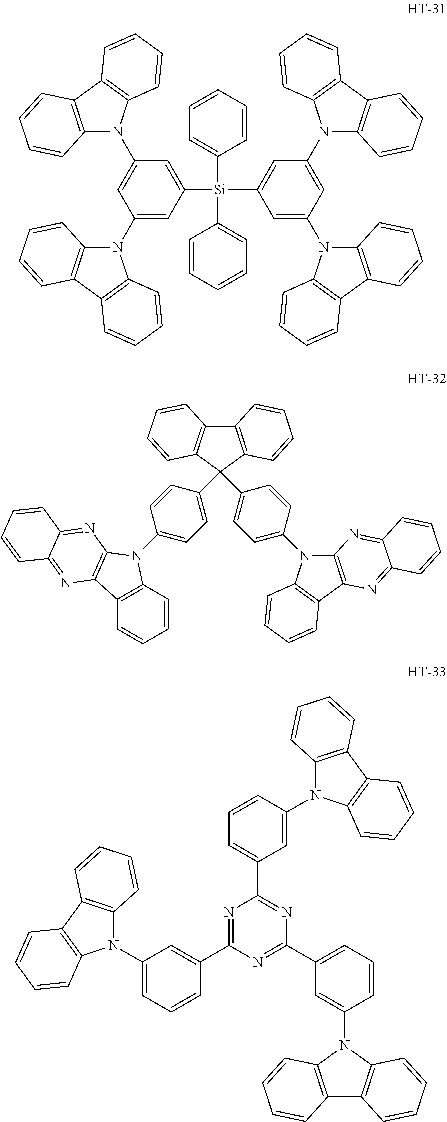 [SMILES: c1ccc([Si](c2ccccc2)(c2cc(-n3c4ccccc4c4ccccc43)cc(-n3c4ccccc4c4ccccc43)c2)c2cc(-n3c4ccccc4c4ccccc43)cc(-n3c4ccccc4c4ccccc43)c2)cc1 ; c1ccc2c(c1)-c1ccccc1C2(c1ccc(-n2c3ccccc3c3nc4ccccc4nc32)cc1)c1ccc(-n2c3ccccc3c3nc4ccccc4nc32)cc1 ; c1cc(-c2nc(-c3cccc(-n4c5ccccc5c5ccccc54)c3)nc(-c3cccc(-n4c5ccccc5c5ccccc54)c3)n2)cc(-n2c3ccccc3c3ccccc32)c1] 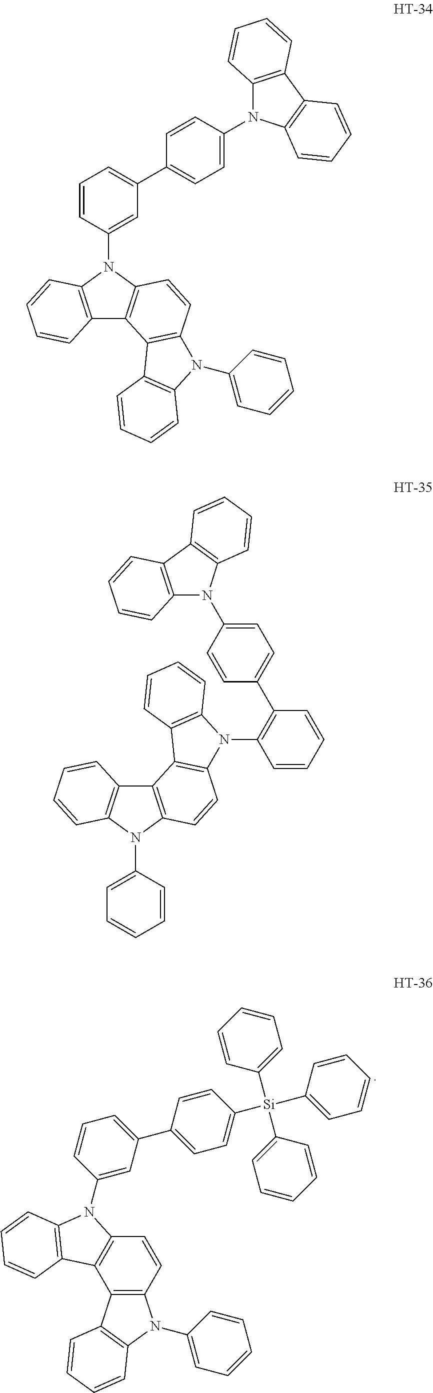 [SMILES: c1ccc(-n2c3ccccc3c3c4c5ccccc5n(-c5cccc(-c6ccc(-n7c8ccccc8c8ccccc87)cc6)c5)c4ccc32)cc1 ; c1ccc(-n2c3ccccc3c3c4c5ccccc5n(-c5ccccc5-c5ccc(-n6c7ccccc7c7ccccc76)cc5)c4ccc32)cc1 ; c1ccc(-n2c3ccccc3c3c4c5ccccc5n(-c5cccc(-c6ccc([Si](c7ccccc7)(c7ccccc7)c7ccccc7)cc6)c5)c4ccc32)cc1]
